(19) United States
(12) Patent Application Publication
(10) Pub. No.: US 2023/0106185 A1
(43) Pub. Date: Apr. 6, 2023

(54) CHEMICALLY AMPLIFIED POSITIVE-TYPE PHOTOSENSITIVE COMPOSITION, PHOTOSENSITIVE DRY FILM, METHOD OF MANUFACTURING PHOTOSENSITIVE DRY FILM, METHOD OF MANUFACTURING PATTERNED RESIST FILM, AND ACID DIFFUSION SUPPRESSING AGENT

(71) Applicant: TOKYO OHKA KOGYO CO., LTD., Kawasaki-shi (JP)

(72) Inventors: Yasuo MASUDA, Kawasaki-shi (JP); Akiya KAWAUE, Kawasaki-shi (JP); Kazuaki EBISAWA, Kawasaki-shi (JP)

(21) Appl. No.: 17/757,542

(22) PCT Filed: Dec. 1, 2020
(86) PCT No.: PCT/JP2020/044610

§ 371 Date: Jun. 16, 2022

(30) Foreign Application Priority Data
Dec. 27, 2019 (JP) 2019-238539

(51) Int. Cl. G03F 7/004; G03F 7/039; G03F 7/40; G03F 7/20

(52) U.S. Cl. CPC G03F 7/0045; G03F 7/0392; G03F 7/40; G03F 7/20

(57) ABSTRACT

A chemically amplified positive-type photosensitive composition which easily forms a resist pattern having a high resolution, high dimensional controllability and satisfactory cross-sectional rectangularity; a photosensitive dry film which has a photosensitive layer including the chemically amplified positive-type photosensitive composition; a method of manufacturing the photosensitive dry film; a method of manufacturing a patterned resist film using the chemically amplified positive-type photosensitive composition; and an acid diffusion suppressing agent which is to be mixed with the chemically amplified positive-type photosensitive composition. An acid diffusion inhibitor having a specific structure is mixed in the chemically amplified positive photosensitive composition which includes: an acid generator that generates acid due to irradiation with active light rays or radiation; and a resin that has a solubility for alkali that increases as a result of the action of the acid.

### TECHNICAL FIELD

The present invention relates to a chemically amplified positive-type photosensitive composition, a photosensitive dry film having a photosensitive layer including the chemically amplified positive-type photosensitive composition, a method of manufacturing the photosensitive dry film, a method of manufacturing a patterned resist film using the chemically amplified positive-type photosensitive composition and an acid diffusion suppressing agent.

### BACKGROUND ART

Photofabrication is now a mainstream microfabrication technique. Photofabrication is a generic term describing the technology used for manufacturing a wide variety of precision components such as semiconductor packages. The manufacturing is carried out by applying a photoresist composition to the surface of a processing target to form a photoresist layer, patterning this photoresist layer using photolithographic techniques and then conducting chemical etching, electrolytic etching or electroforming based mainly on electroplating, using the patterned photoresist layer (photoresist pattern) as a mask.

In recent years, high density packaging technologies have progressed in semiconductor packages along with downsizing electronics devices, and the increase in package density has been developed on the basis of mounting multi-pin thin film in packages, miniaturizing of package size, two-dimensional packaging technologies in flip-tip systems, or three-dimensional packaging technologies. In these types of high density packaging techniques, connection terminals, for example, protruding electrodes (mounting terminals) known as bumps that protrude above the package or metal posts that extend from peripheral terminals on the wafer and connect rewiring with the mounting terminals, are disposed on the surface of the substrate with high precision.

In the photofabrication as described above, a photoresist composition is used, and chemically amplified photosensitive compositions containing an acid generating agent have been known as such a photoresist composition (see Patent Documents 1, 2, and the like). According to the chemically amplified photosensitive composition, an acid is generated from the acid generating agent by irradiation with radiation (exposure) and diffusion of the acid promoted through heat treatment, to cause an acid catalytic reaction with a base resin, and the like in the composition resulting in a change to the alkali-solubility of the same.

Such chemically amplified photosensitive compositions are used, for example, in formation of plated articles such as bumps, metal posts, and Cu-rewiring by a plating process, in addition to patterned insulating film or formation of etching masks. Specifically, a photoresist layer having a desired film thickness is formed on a support such as a metal substrate using a chemically amplified photosensitive composition, and the photoresist layer is exposed through a predetermined mask pattern and is developed. Thereby, a photoresist pattern used as a template is formed in which portions for forming plated articles have been selectively removed (stripped). Then, bumps or metal posts, and Cu rewiring can be formed by embedding a conductor such as copper into the removed portions (non-resist portions) using plating, and then removing the surrounding photoresist pattern.
Patent Document 1: Japanese Unexamined Patent Application, Publication No. H9-176112
Patent Document 2: Japanese Unexamined Patent Application, Publication No. H11-52562

### DISCLOSURE OF THE INVENTION

### Problems to be Solved by the Invention

As the density of a semiconductor package is further increased, the density and precision of a protruding electrode, a metal post, and the like are further required to be increased. In order to realize further increases in the density and precision of the protruding electrode, the metal post, and the like, a chemically amplified photosensitive composition is desired that can form a resist pattern having a high resolution, high dimensional controllability, and satisfactory cross-sectional rectangularity.

However, when the conventionally known chemically amplified resist compositions as disclosed in Patent Documents 1, 2, and the like are used, the resolution and the dimensional controllability thereof are not sufficient, and it is often difficult to form a resist pattern having satisfactory cross-sectional rectangularity. For example, when the conventionally known chemically amplified resist composition is used, around a contact surface (interface) between a substrate surface and a resist pattern, a footing shape (skirt-like shape) in which a resist portion may extend over the non-resist portion or a biting shape (erosion shape) opposite to the footing shape may be formed, or the cross-sectional verticality is poor in some cases, with the result that it is likely that a resist pattern having a rectangular cross-sectional shape cannot be obtained.

The present invention is made in view of the problems described above, and an object thereof is to provide: a chemically amplified positive-type photosensitive composition which easily forms a resist pattern having a high resolution, high dimensional controllability and satisfactory cross-sectional rectangularity; a photosensitive dry film which has a photosensitive layer including the chemically amplified positive-type photosensitive composition; a method of manufacturing the photosensitive dry film; a method of manufacturing a patterned resist film using the chemically amplified positive-type photosensitive composition; and an acid diffusion suppressing agent which is to be mixed with the chemically amplified positive-type photosensitive composition.

### Means for Solving the Problems

In order to achieve the object described above, the present inventors have conducted a thorough study to find that the problems described above can be solved by mixing an acid diffusion suppressing agent (C) of a specific structure with a chemically amplified positive-type photosensitive composition including an acid generating agent (A) to generate an acid by irradiation with an active ray or radiation and a resin (B) having alkali solubility that increases under action of acid, with the result that the present invention has been completed. Specifically, the present invention provides the following.

A first aspect of the present invention is a chemically amplified positive-type photosensitive composition containing: an acid generating agent (A) to generate an acid by irradiation with an active ray or radiation; a resin (B) having alkali solubility that increases under action of acid; and an acid diffusion suppressing agent (C), and

the acid diffusion suppressing agent (C) includes a compound represented by a formula (C1) below:

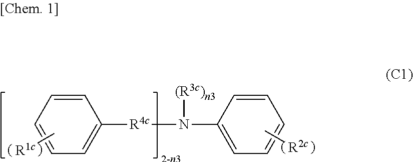

(in the formula (C1),
R^{1c} is an alkyl group or an aralkyl group,
R^{2c} is an alkyl group or an aralkyl group,
R^{3c} is a hydrogen atom or an alkyl group,
R^{4c} is a single bond or an alkylene group,
n1 is an integer of 0 or more and 5 or less,
n2 is an integer of 0 or more and 5 or less,
n3 is 0 or 1 and
when n3 is 1, n1 and n2 are not simultaneously 0).

A second aspect of the present invention is a photosensitive dry film including: a base material film; and a photosensitive layer formed on a surface of the substrate film, and the photosensitive layer includes the chemically amplified positive-type photosensitive composition according to the first aspect.

A third aspect of the present invention is a method of manufacturing a photosensitive dry film, and the method includes: applying, on a base material film, the chemically amplified positive-type photosensitive composition according to the first aspect to form a photosensitive layer.

A fourth aspect of the present invention is a method of manufacturing a patterned resist film, and the method includes:

laminating a photosensitive layer on a substrate, the photosensitive layer including the chemically amplified positive-type photosensitive composition according to the first aspect; and
exposing the photosensitive layer through irradiation with an active ray or radiation in a position-selective manner; and developing the exposed photosensitive layer.

A fifth aspect of the present invention is an acid diffusion suppressing agent to be mixed with a chemically amplified positive-type photosensitive composition including an acid generating agent (A) to generate an acid by irradiation with an active ray or radiation and a resin (B) having alkali solubility that increases under action of acid, and

the acid diffusion suppressing agent (C) includes a compound represented by a formula (C1) below:

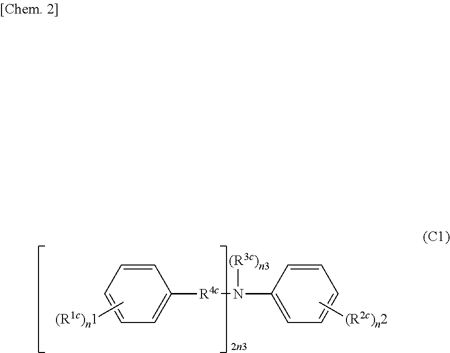

(in the formula (C1),
R^{1c} is an alkyl group or an aralkyl group,
R^{2c} is an alkyl group or an aralkyl group,
R^{3c} is a hydrogen atom or an alkyl group,
R^{4c} is a single bond or an alkylene group,
n1 is an integer of 0 or more and 5 or less,
n2 is an integer of 0 or more and 5 or less,
n3 is 0 or 1 and
when n3 is 1, n1 and n2 are not simultaneously 0).

### Effects of the Invention

According to the present invention, it is possible to provide: a chemically amplified positive-type photosensitive composition which easily forms a resist pattern having a high resolution, high dimensional controllability and satisfactory cross-sectional rectangularity; a photosensitive dry film which has a photosensitive layer including the chemically amplified positive-type photosensitive composition; a method of manufacturing the photosensitive dry film; a method of manufacturing a patterned resist film using the chemically amplified positive-type photosensitive composition; and an acid diffusion suppressing agent which is to be mixed with the chemically amplified positive-type photosensitive composition.

### PREFERRED MODE FOR CARRYING OUT THE INVENTION

### <<Chemically Amplified Positive-Type Photosensitive Composition>>

A chemically amplified positive-type photosensitive composition (hereinafter also referred to as the photosensitive composition) contains: an acid generating agent (A) (hereinafter also referred to as the acid generating agent (A)) which generates an acid by irradiation with an active ray or radiation; a resin (B) (hereinafter also referred to as the resin (B)) having alkali solubility that increases under action of acid; an acid diffusion suppressing agent (C). The acid diffusion suppressing agent (C) has a specific structure as described later. The photosensitive composition may include, as necessary, an alkali soluble resin (D), a sulfur-containing compound (E), an organic solvent (S), and the like.

### <Acid Generating Agent (A)>

The acid generating agent (A) is a compound for generating an acid by irradiation with active rays or radiation, and is not particularly limited as long as it is a compound which directly or indirectly generates an acid under action of light. As the acid generating agent (A), any one of the acid generating agents of the first to fifth aspects which will be described below is preferable. Hereinafter, preferred acid generating agents (A) among the acid generating agents (A) suitably used in the photosensitive composition, will be described as the first to fifth aspects.

As the first aspect of the acid generating agent (A), a compound represented by the following formula (a1) is mentioned.

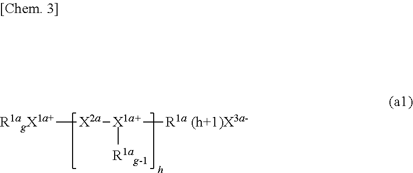

In the formula (a1), X^{1a} represents a sulfur atom or an iodine atom having a valence of g, and g represents 1 or 2. h represents the number of repeating units of a structure in parentheses. R^{1a} represents an organic group which is bonded to X^{1a}, and represents an aryl group having 6 or more and 30 or less carbon atoms, a heterocyclic group having 4 or more and 30 or less carbon atoms, an alkyl group having 1 or more and 30 or less carbon atoms, an alkenyl group having 2 or more and 30 or less carbon atoms or an alkynyl group having 2 or more and 30 or less carbon atoms, and R^{1a} may be substituted with at least one type selected from the group consisting of an alkyl group, a hydroxyl group, an alkoxy group, an alkylcarbonyl group, an arylcarbonyl group, an alkoxycarbonyl group, an aryloxycarbonyl group, an arylthiocarbonyl group, an acyloxy group, an arylthio group, an alkylthio group, an aryl group, a heterocyclic group, an aryloxy group, an alkylsulfinyl group, an arylsulfinyl group, an alkylsulfonyl group, an arylsulfonyl group, an alkyleneoxy group, an amino group, a cyano group, a nitro group and halogen atoms. The number of R^{1a}s is g+h(g−1)+1, and the R^{1a}s may be identical to or different from each other. Furthermore, two or more Rias may be bonded to each other directly or through —O—, —S—, —SO—, —SO₂—, —NH—, —NR^{2a}—, —CO—, —COO—, —CONH—, an alkylene group having 1 or more and 3 or less carbon atoms or a phenylene group, and may form a ring structure including X^{1a}. R^{2a} represents an alkyl group having 1 or more and 5 or less carbon atoms or an aryl group having 6 or more and 10 or less carbon atoms.

X^{2a} represents a structure represented by the following formula (a2).

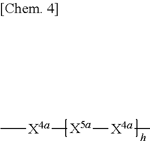

In the above formula (a2), X^{4a} represents an alkylene group having 1 or more and 8 or less carbon atoms, an arylene group having 6 or more and 20 or less carbon atoms or a divalent group of a heterocyclic compound having 8 or more and 20 or less carbon atoms, and X^{4a} may be substituted with at least one type selected from the group consisting of an alkyl group having 1 or more and 8 or less carbon atoms, an alkoxy group having 1 or more and 8 or less carbon atoms, an aryl group having 6 or more and 10 or less carbon atoms, a hydroxyl group, a cyano group, a nitro group and halogen atoms. X^{5a} represents —O—, —S—, —SO—, —SO₂—, —NH—, —NR^{2a}—, —CO—, —COO—, —CONH—, an alkylene group having 1 or more and 3 or less carbon atoms or a phenylene group. h represents the number of repeating units of a structure in parentheses. X^{4a}s in the number of h+1 and X^{5a}s in the number of h may be identical to or different from each other. R^{2a} has the same definition as described above.

X^{3a-} represents a counterion of an onium, and examples thereof include a fluorinated alkylfluorophosphoric acid anion represented by the following formula (a17) or a borate anion represented by the following formula (a18).

[Chem. 5]

[(R^{3a})ⱼPF₆₋ⱼ]⁻ (a17)

In the formula (a17), R^{3a} represents an alkyl group having 80% or more of the hydrogen atoms substituted with fluorine atoms. j represents the number of R^{3a}s and is an integer of 1 or more and 5 or less. R^{3a}s in the number of j may be identical to or different from each other.

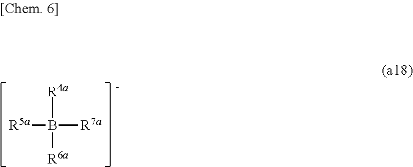

In the formula (a18), R^{4a} to R^{7a} each independently represent a fluorine atom or a phenyl group, and a part or all of the hydrogen atoms of the phenyl group may be substituted with at least one type selected from the group consisting of a fluorine atom and a trifluoromethyl group.

Examples of the onium ion in the compound represented by the above formula (a1) include triphenylsulfonium, tri-p-tolylsulfonium, 4-(phenylthio)phenyldiphenylsulfonium, bis[4-(diphenylsulfonio)phenyl] sulfide, bis[4-{bis[4-(2-hydroxyethoxy)phenyl]sulfonio}phenyl] sulfide, bis{4-[bis(4-fluorophenyl)sulfonio]phenyl} sulfide, 4-(4-benzoyl-2-chlorophenylthio)phenylbis(4-fluorophenyl)sulfonium, 7-isopropyl-9-oxo-10-thia-9,10-dihydroanthracen-2-yldi-p-tolylsulfonium, 7-isopropyl-9-oxo-10-thia-9,10-dihydroanthracen-2-yldiphenylsulfonium, 2-[(diphenyl)sulfonio]thioxanthone, 4-[4-(4-tert-butylbenzoyl)phenylthio]phenyldi-p-tolylsulfonium, 4-(4-benzoylphenylthio)phenyldiphenylsulfonium, diphenylphenacylsulfonium, 4-hydroxyphenylmethylbenzylsulfonium, 2-naphthylmethyl(1-ethoxycarbonyl)ethylsulfonium, 4-hydroxyphenylmethylphenacylsulfonium, phenyl[4-(4-biphenylthio)phenyl]-4-biphenylsulfonium, phenyl[4-(4-biphenylthio)phenyl]3-biphenylsulfonium, [4-(4-acetophenylthio)phenyl]diphenylsulfonium, octadecylmethylphenacylsulfonium, diphenyliodonium, di-p-tolyliodonium, bis(4-dodecylphenyl)iodonium, bis(4-methoxyphenyl)iodonium, (4-octyloxyphenyl)phenyliodonium, bis(4-decyloxy)phenyliodonium, 4-(2-hydroxytetradecyloxy)phenylphenyliodonium, 4-isopropylphenyl(p-tolyl)iodonium, 4-isobutylphenyl(p-tolyl)iodonium, and the like.

Among the onium ions in the compound represented by the above formula (a1), as a preferred onium ion, a sulfonium ion represented by the following formula (a19) is mentioned.

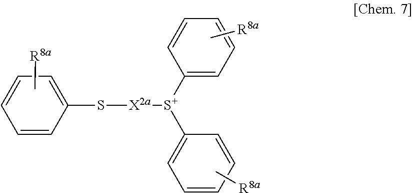

In the above formula (a19), R^{8a}s each independently represent a hydrogen atom or a group selected from the group consisting of alkyl, hydroxyl, alkoxy, alkylcarbonyl, alkylcarbonyloxy, alkyloxycarbonyl, a halogen atom, an aryl, which may be substituted, and arylcarbonyl. X^{2a} has the same meaning as X^{2a} in the above formula (a1).

Specific examples of the sulfonium ion represented by the above formula (a19) include 4-(phenylthio)phenyldiphenylsulfonium, 4-(4-benzoyl-2-chlorophenylthio)phenylbis(4-fluorophenyl)sulfonium, 4-(4-benzoylphenylthio)phenyldiphenylsulfonium, phenyl[4-(4-biphenylthio)phenyl]-4-biphenylsulfonium, phenyl[4-(4-biphenylthio)phenyl]-3-biphenylsulfonium, [4-(4-acetophenylthio)phenyl]diphenylsulfonium and diphenyl[4-(p-terphenylthio)phenyl]diphenylsulfonium.

In the fluorinated alkylfluorophosphoric acid anion represented by the above formula (a17), R^{3a} represents an alkyl group substituted with a fluorine atom, a preferred number of carbon atoms is 1 or more and 8 or less and a more preferred number of carbon atoms is 1 or more and 4 or less. Specific examples of the alkyl group include: linear alkyl groups such as methyl, ethyl, propyl, butyl, pentyl and octyl; branched alkyl groups such as isopropyl, isobutyl, sec-butyl and tert-butyl; and cycloalkyl groups such as cyclopropyl, cyclobutyl, cyclopentyl and cyclohexyl. The proportion of hydrogen atoms substituted with fluorine atoms in the alkyl groups is usually 80% or more, preferably 90% or more, and further preferably 100%. When the substitution ratio of fluorine atoms is less than 80%, the acid strength of the onium fluorinated alkylfluorophosphate represented by the above formula (a1) decreases.

A particularly preferred example of R^{3a} is a linear or branched perfluoroalkyl group having 1 or more and 4 or less carbon atoms and a substitution ratio of fluorine atoms of 100%. Specific examples thereof include CF₃, CF₃CF₂, (CF₃)₂CF, CF₃CF₂CF₂, CF₃CF₂CF₂CF₂, (CF₃)₂CFCF₂, CF₃CF₂ (CF₃)CF and (CF₃)₃C. j, which is the number of R^{3a}s, represents an integer of 1 or more and 5 or less, and is preferably 2 or more and 4 or less and particularly preferably 2 or 3.

Preferred specific examples of the fluorinated alkylfluorophosphoric acid anion include [(CF₃CF₂)₂PF₄]⁻, [(CF₃CF₂)₃PF₃]⁻, [((CF₃)₂CF)₂PF₄]⁻, [((CF₃)₂CF)₃PF₃]⁻, [(CF₃CF₂CF₂)₂PF₄]⁻, [(CF₃CF₂CF₂)₃PF₃]⁻, [((CF₃)₂CFCF₂)₂PF₄]⁻, [((CF₃)₂CFCF₂)₃PF₃]⁻, [(CF₃CF₂CF₂CF₂)₂PF₄]⁻ and [(CF₃CF₂CF₂)₃PF₃]⁻. Among these, [(CF₃CF₂)₃PF₃]⁻, [(CF₃CF₂CF₂)₃PF₃]⁻, [((CF₃) CF)₃PF₃]⁻, [((CF₃)₂CF)₂PF₄]⁻, [((CF₃)₂CFCF₂)₃PF₃]⁻ and [((CF₃)₂CFCF₂)₂PF₄]⁻ are particularly preferred.

Preferred specific examples of the borate anion represented by the above formula (a18) include tetrakis(pentafluorophenyl)borate ([B(C₆F₅)₄]⁻), tetrakis[(trifluoromethyl)phenyl]borate ([B(C₆H₄CF₃)₄]⁻), difluorobis(pentafluorophenyl)borate ([(C₆F₅)₂BF₂]⁻), trifluoro(pentafluorophenyl)borate ([(C₆F₅)BF₃]⁻), tetrakis(difluorophenyl)borate ([B(C₆H₃F₂)₄]⁻), and the like. Among these, tetrakis(pentafluorophenyl)borate ([B(C₆F₅)₄]⁻) is particularly preferred.

The second aspect of the acid generating agent (A) include halogen-containing triazine compounds such as 2,4-bis(trichloromethyl)-6-piperonyl-1,3,5-triazine, 2,4-bis(trichloromethyl)-6-[2-(2-furyl)ethenyl]-s-triazine, 2,4-bis(trichloromethyl)-6-[2-(5-methyl-2-furyl)ethenyl]-s-triazine, 2,4-bis(trichloromethyl)-6-[2-(5-ethyl-2-furyl)ethenyl]-s-triazine, 2,4-bis(trichloromethyl)-6-[2-(5-propyl-2-furyl)ethenyl]-s-triazine, 2,4-bis(trichloromethyl)-6-[2-(3,5-dimethoxyphenyl)ethenyl]-s-triazine, 2,4-bis(trichloromethyl)-6-[2-(3,5-diethoxyphenyl)ethenyl]-s-triazine, 2,4-bis(trichloromethyl)-6-[2-(3,5-dipropoxyphenyl)ethenyl]-s-triazine, 2,4-bis(trichloromethyl)-6-[2-(3-methoxy-5-ethoxyphenyl)ethenyl]-s-triazine, 2,4-bis(trichloromethyl)-6-[2-(3-methoxy-5-propoxyphenyl)ethenyl]-s-triazine, 2,4-bis(trichloromethyl)-6-[2-(3,4-methylenedioxyphenyl)ethenyl]-s-triazine, 2,4-bis(trichloromethyl)-6-(3,4-methylenedioxyphenyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(2-bromo-4-methoxy)styrylphenyl-s-triazine, 2,4-bis-trichloromethyl-6-(3-bromo-4-methoxy)styrylphenyl-s-triazine, 2-(4-methoxyphenyl)-4,6-bis(trichloromethyl)-1,3,5-triazine, 2-(4-methoxynaphthyl)-4,6-bis(trichloromethyl)-1,3,5-triazine, 2-[2-(2-furyl)ethenyl]-4,6-bis(trichloromethyl)-1,3,5-triazine, 2-[2-(5-methyl-2-furyl)ethenyl]-4,6-bis(trichloromethyl)-1,3,5-triazine, 2-[2-(3,5-dimethoxyphenyl)ethenyl]-4,6-bis(trichloromethyl)-1,3,5-triazine, 2-[2-(3,4-dimethoxyphenyl)ethenyl]-4,6-bis(trichloromethyl)-1,3,5-triazine, 2-(3,4-methylenedioxyphenyl)-4,6-bis(trichloromethyl)-1,3,5-triazine, tris(1,3-dibromopropyl)-1,3,5-triazine and tris(2,3-dibromopropyl)-1,3,5-triazine, and halogen-containing triazine compounds represented by the following formula (a3) such as tris(2,3-dibromopropyl)isocyanurate.

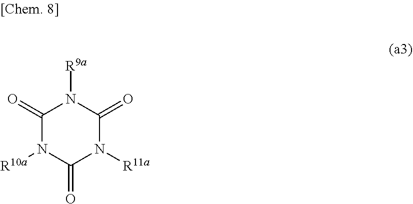

In the above formula (a3), R^{9a}, R^{10a} and R^{11a} each independently represent a halogenated alkyl group.

Examples of the third aspect of the acid generating agent (A) include α-(p-toluenesulfonyloxyimino)-phenylacetonitrile, α-(benzenesulfonyloxyimino)-2,4-dichlorophenylacetonitrile, α-(benzenesulfonyloxyimino)-2,6-dichlorophenylacetonitrile, α-(2-chlorobenzenesulfonyloxyimino)-4-methoxyphenylacetonitrile and α-(ethylsulfonyloxyimino)-1-cyclopentenylacetonitrile and compounds represented by the following formula (a4) having an oximesulfonate group.

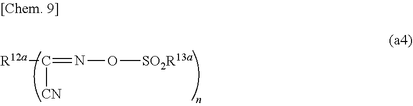

In the above formula (a4), R^{12a} represents a monovalent, bivalent or trivalent organic group, R^{13a} represents a substituted or unsubstituted saturated hydrocarbon group, or an unsaturated hydrocarbon group or an aromatic group, and n represents the number of repeating units of a structure in the parentheses.

In the formula (a4), examples of the aromatic group include aryl groups such as a phenyl group and a naphthyl group and heteroaryl groups such as a furyl group and a thienyl group. These may have one or more appropriate substituents such as halogen atoms, alkyl groups, alkoxy groups and nitro groups on the rings. It is particularly preferable that R^{13a} is an alkyl group having 1 or more and 6 or less carbon atoms such as a methyl group, an ethyl group, a propyl group or a butyl group. In particular, a compound is preferable in which R^{12a} represents an aromatic group and R^{13a} represents an alkyl group having 1 or more and 4 or less carbon atoms.

Examples of the acid generating agent represented by the above formula (a4) include compounds in which R^{12a} is any one of a phenyl group, a methylphenyl group and a methoxyphenyl group, and R^{13a} is a methyl group when n is 1, and specific examples thereof include α-(methylsulfonyloxyimino)-1-phenylacetonitrile, α-(methylsulfonyloxyimino)-1-(p-methylphenyl)acetonitrile, α-(methylsulfonyloxyimino)-1-(p-methoxyphenyl)acetonitrile, [2-(propylsulfonyloxyimino)-2,3-dihydroxythiophene-3-ylidene] (o-tolyl)acetonitrile, and the like. When n is 2, the acid generating agent represented by the above formula (a4) is specifically an acid generating agent represented by the following formulae.

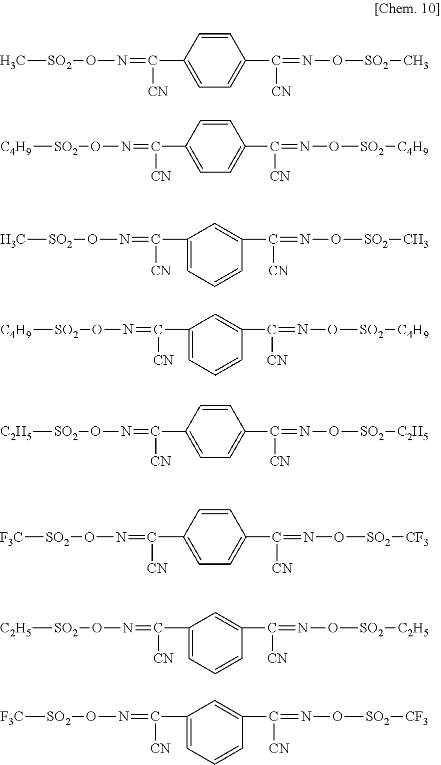

In addition, the fourth aspect of the acid generating agent (A) includes an onium salt that has a naphthalene ring at its cation moiety. The expression “has a naphthalene ring” means having a structure derived from naphthalene and also means at least two ring structures, and their aromatic properties are maintained. The naphthalene ring may have a substituent such as a linear or branched alkyl group having 1 or more and 6 or less carbon atoms, a hydroxyl group, a linear or branched alkoxy group having 1 or more and 6 or less carbon atoms or the like. The structure derived from the naphthalene ring, which may be of a monovalent group (one free valance) or of a bivalent group (two free valences), is desirably of a monovalent group (in this case, the number of free valances is counted except the portions bonded to the substituents described above). The number of naphthalene rings is preferably 1 or more and 3 or less.

For the cation moiety of the onium salt having a naphthalene ring at the cation moiety as described above, a structure represented by the following formula (a5) is preferable.

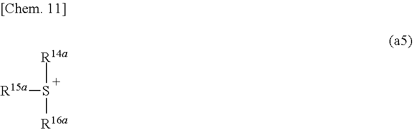

In the above formula (a5), at least one of R^{14a}, R^{15a} and R^{16a} represents a group represented by the following formula (a6), and the remaining represents a linear or branched alkyl group having 1 or more and 6 or less carbon atoms, a phenyl group optionally having a substituent, a hydroxyl group or a linear or branched alkoxy group having 1 or more and 6 or less carbon atoms. Alternatively, one of R^{14a}, R^{15a} and R^{16a} is a group represented by the following formula (a6), and the remaining two are each independently a linear or branched alkylene group having 1 or more and 6 or less carbon atoms, and these terminals may be bonded to form a ring structure.

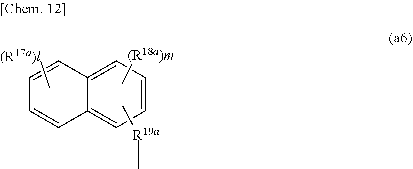

In the formula (a6), R^{17a} and R^{18a} each independently represent a hydroxyl group, a linear or branched alkoxy group having 1 or more and 6 or less carbon atoms or a linear or branched alkyl group having 1 or more and 6 or less carbon atoms, and R^{19a} represents a single bond or a linear or branched alkylene group having 1 or more and 6 or less carbon atoms that may have a substituent. l and m each independently represent an integer of 0 or more and 2 or less, and l+m is 3 or less. However, when there exists a plurality of R^{17a}s, they may be identical to or different from each other. Furthermore, when there exists a plurality of R^{18a}s, they may be identical to or different from each other.

Among R^{14a}, R^{15a} and R^{16a} described above, the number of groups represented by the above formula (a6) is preferably one in terms of the stability of the compound, the remaining are linear or branched alkylene groups having 1 or more and 6 or less carbon atoms and the terminals thereof may be bonded to form a ring. In this case, the two alkylene groups described above form a 3 to 9 membered ring including a sulfur atom. The number of atoms which form the ring (including a sulfur atom) is preferably 5 or more and 6 or less.

Examples of the substituent, which the alkylene group may have, include an oxygen atom (in this case, a carbonyl group is formed together with a carbon atom that constitutes the alkylene group), a hydroxyl group, and the like.

Furthermore, examples of the substituent which the phenyl group may have include a hydroxyl group, a linear or branched alkoxy group having 1 or more and 6 or less carbon atoms, a linear or branched alkyl group having 1 or more and 6 or less carbon atoms, and the like.

Preferred examples of cations for the cation moiety include cations represented by the following formulae (a7) and (a8), and a structure represented by the following formula (a8) is particularly preferable.

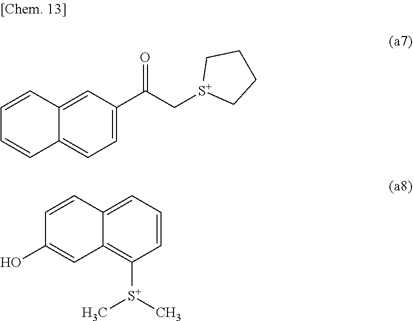 [SMILES: O=C(C[S+]1CCCC1)c1ccc2ccccc2c1 ; C[S+](C)c1cccc2ccc(O)cc12]

The cation moieties, which may be of an iodonium salt or a sulfonium salt, are desirably of a sulfonium salt in terms of acid-generating efficiency.

It is, therefore, desirable that the preferred anions for the anion moiety of the onium salt having a naphthalene ring at the cation moiety is an anion capable of forming a sulfonium salt.

The anion moiety of the acid generating agent is exemplified by fluoroalkylsulfonic acid ions or aryl sulfonic acid ions in which part or all of the hydrogen atoms are fluorinated.

The alkyl group of the fluoroalkylsulfonic acid ion may be linear, branched or cyclic and have 1 or more and 20 or less carbon atoms. Preferably, the number of carbon atoms is 1 or more and 10 or less in terms of the bulkiness and diffusion distance of the generated acid. In particular, branched or cyclic alkyl groups are preferable because the diffusion distance is short. Methyl, ethyl, propyl, butyl and octyl groups, and the like are preferable because they can be inexpensively synthesized.

The aryl group of the aryl sulfonic acid ion may be an aryl group having 6 or more and 20 or less carbon atoms, and is exemplified by a phenyl group or a naphthyl group that may be unsubstituted or substituted with an alkyl group or a halogen atom. In particular, an aryl group having 6 or more and 10 or less carbon atoms is preferable because it can be inexpensively synthesized. Specific examples of preferable aryl group include phenyl, toluenesulfonyl, ethylphenyl, naphthyl, methylnaphthyl groups, and the like.

When part or all of the hydrogen atoms in the fluoroalkylsulfonic acid ion or the aryl sulfonic acid ion described above are fluorinated, the fluorination rate thereof is preferably 10% or more and 100% or less, and more preferably 50% or more and 100% or less, and it is particularly preferable that all hydrogen atoms are each substituted with fluorine atoms because the acid strength thereof is increased. Specific examples thereof include trifluoromethane sulfonate, perfluorobutane sulfonate, perfluorooctane sulfonate, perfluorobenzene sulfonate, and the like.

Among these, a preferable anion moiety is exemplified by those represented by the following formula (a9).

[Chem. 14]

R^{20a}SO₃⁻ (a9)

In the above formula (a9), R^{20a} represents groups represented by the following formulae (a10), (a11) and (a12).

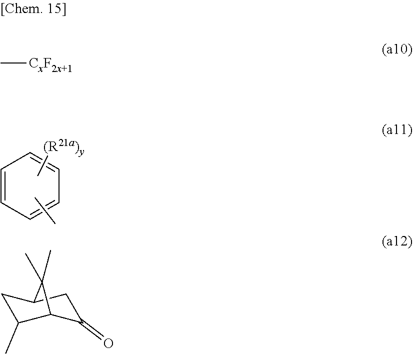

In the above formula (a10), x represents an integer of 1 or more and 4 or less. In the above formula (a11), R^{21a} represents a hydrogen atom, a hydroxyl group, a linear or branched alkyl group having 1 or more and 6 or less carbon atoms or a linear or branched alkoxy group having 1 or more and 6 or less carbon atoms, and y represents an integer of 1 or more and 3 or less. Of these, trifluoromethane sulfonate and perfluorobutane sulfonate are preferable in terms of safety.

A nitrogen-containing moiety represented by the following formulae (a13) and (a14) can also be used for the anion moiety.

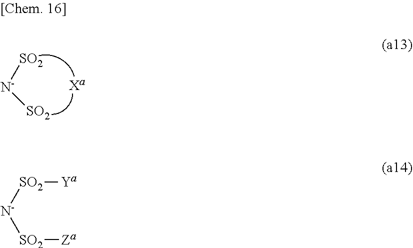

In the formulae (a13) and (a14), X^{a} represents a linear or branched alkylene group in which at least one hydrogen atom is substituted with a fluorine atom, the number of carbon atoms in the alkylene group is 2 or more and 6 or less, preferably 3 or more and 5 or less and most preferably 3. Y^{a} and Z^{a} each independently represent a linear or branched alkyl group in which at least one hydrogen atom is substituted with a fluorine atom, the number of carbon atoms in the alkyl group is 1 or more and 10 or less, preferably 1 or more and 7 or less and more preferably 1 or more and 3 or less.

The smaller number of carbon atoms in the alkylene group of X^{a} or in the alkyl group of Y^{a} or Z^{a} is preferable because the solubility in organic solvent is satisfactory.

A larger number of hydrogen atoms each substituted with a fluorine atom in the alkylene group of X^{a} or in the alkyl group of Y^{a} or Z^{a} is preferable because the acid strength is increased. The percentage of fluorine atoms in the alkylene group or alkyl group, that is, the fluorination rate is preferably 70% or more and 100% or less and more preferably 90% or more and 100% or less, and a perfluoroalkylene group or a perfluoroalkyl group in which all of the hydrogen atoms each are substituted with a fluorine atom is most preferable.

Examples of the preferable compound for an onium salt having a naphthalene ring at its cation moiety include compounds represented by the following formulae (a15) and (a16).

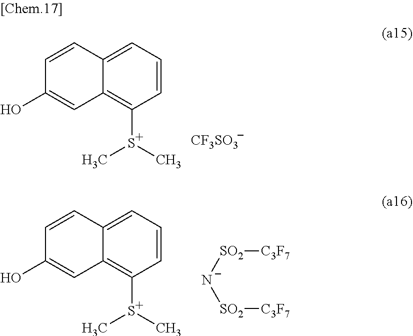

The fifth aspect of the acid generating agent (A) include bissulfonyldiazomethanes such as bis(p-toluenesulfonyl)diazomethane, bis(1,1-dimethyl ethylsulfonyl)diazomethane, bis(cyclohexylsulfonyl)diazomethane and bis(2,4-dimethylphenylsulfonyl)diazomethane; nitrobenzyl derivatives such as 2-nitrobenzyl p-toluenesulfonate, 2,6-dinitrobenzyl p-toluenesulfonate, nitrobenzyl tosylate, dinitrobenzyl tosylate, nitrobenzyl sulfonate, nitrobenzyl carbonate and dinitrobenzyl carbonate; sulfonates such as pyrogalloltrimesylate, pyrogalloltritosylate, benzyltosylate, benzylsulfonate, N-methylsulfonyloxysuccinimide, N-trichloromethylsulfonyloxysuccinimide, N-phenylsulfonyloxymaleimide and N-methylsulfonyloxyphthalimide; trifluoromethane sulfonates such as N-(trifluoromethylsulfonyloxy)phthalimide, N-(trifluoromethylsulfonyloxy)-1,8-naphthalimide and N-(trifluoromethylsulfonyloxy)-4-butyl-1,8-naphthalimide; onium salts such as diphenyliodonium hexafluorophosphate, (4-methoxyphenyl)phenyliodonium trifluoromethanesulfonate, bis(p-tert-butylphenyl)iodonium trifluoromethanesulfonate, triphenylsulfonium hexafluorophosphate, (4-methoxyphenyl)diphenylsulfonium trifluoromethanesulfonate and (p-tert-butylphenyl)diphenylsulfonium trifluoromethanesulfonate; benzointosylates such as benzointosylate and α-methylbenzointosylate; other diphenyliodonium salts, triphenylsulfonium salts, phenyldiazonium salts, benzylcarbonates, and the like.

As the acid generating agent (A), a naphthalic acid derivative represented by the following formula (a21) is also preferable:

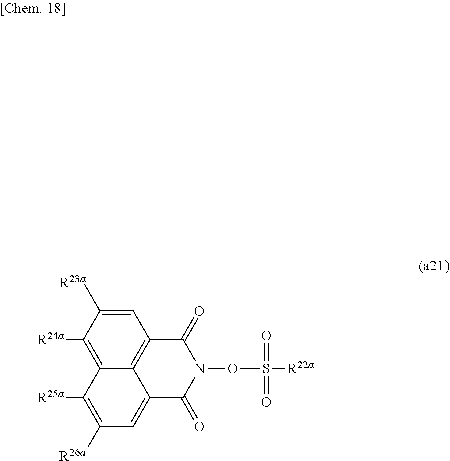

(in the formula (a21), R^{22a} represents a monovalent organic group, R^{23a}, R^{24a}, R^{25a} and R^{26a} each independently represent a hydrogen atom or a monovalent organic group and R^{23a} and R^{24a}, R^{24a} and R^{25a} or R^{25a} and R^{26a} may be bonded to each other to form a ring).

The organic group serving as R^{22a} is not particularly limited as long as the object of the present invention is not impaired. The organic group described above may be a hydrocarbon group and may include heteroatoms such as O, N, S, P and a halogen atom. The structure of the organic group may be linear, branched, cyclic or a combination of the structures thereof.

Preferred examples of the organic group serving as R^{22a} include an aliphatic hydrocarbon group having 1 or more and 18 or less carbon atoms which may be substituted with a halogen atom and/or an alkylthio group, an aryl group having 6 or more and 20 or less carbon atoms which may have a substituent, an aralkyl group having 7 or more and 20 or less carbon atoms which may have a substituent, an alkyl aryl group having 7 or more and 20 or less carbon atoms which may have a substituent, a camphor-10-il group and a group represented by the following formula (a21a):

—R^{27a}—(O)ₐ—R^{28a}—(O)_{b}—Y¹—R^{29a} (a21a)

(in the formula (a21a), Y¹ represents a single bond or an alkanediyl group having 1 or more and 4 or less carbon atoms, R^{27a} and R^{28a} each represent an alkanediyl group having 2 or more and 6 or less carbon atoms which may be substituted with a halogen atom, or an arylene group having 6 or more and 20 or less carbon atoms which may be substituted with a halogen atom. R^{29a} represents an alkyl group having 1 or more and 18 or less carbon atoms which may be substituted with a halogen atom, an alicyclic hydrocarbon group having 3 or more and 12 or less carbon atoms, an aryl group having 6 or more and 20 or less carbon atoms which may be substituted with a halogen atom or an aralkyl group having 7 or more and 20 or less carbon atoms which may be substituted with a halogen atom. Each of a and b is 0 or 1 and at least one of a and b is 1).

When the organic group serving as R^{22a} has a halogen atom, examples of the halogen atom include a chlorine atom, a bromine atom, an iodine atom and a fluorine atom.

When the organic group serving as R^{22a} is an alkyl group having 1 or more and 18 or less carbon atoms substituted with an alkylthio group, the number of carbon atoms in the alkylthio group is preferably 1 or more and 18 or less. Examples of the alkylthio group having 1 or more and 18 or less carbon atoms include a methylthio group, an ethylthio group, an n-propylthio group, an isopropylthio group, an n-butylthio group, a sec-butylthio group, a tert-butylthio group, an isobutylthio group, an n-pentylthio group, an isopentylthio group, a tert-pentylthio group, an n-hexylthio group, an n-heptylthio group, an isoheptylthio group, a tert-heptylthio group, an n-octylthio group, an isooctylthio group, a tert-octylthio group, a 2-ethylhexylthio group, an n-nonylthio group, an n-decylthio group, an n-undecylthio group, an n-dodecylthio group, an n-tridecylthio group, an n-tetradecylthio group, an n-pentadecylthio group, an n-hexadecylthio group, an n-heptadecylthio group and an n-octadecylthio group.

When the organic group serving as R^{22a} is an aliphatic hydrocarbon group having 1 or more and 18 or less carbon atoms which may be substituted with a halogen atom and/or an alkylthio group, the aliphatic hydrocarbon group may include an unsaturated double bond. The structure of the aliphatic hydrocarbon group is not particularly limited and may be linear, branched, cyclic or a combination of the structures thereof.

Preferred examples when the organic group serving as R^{22a} is an alkenyl group include an aryl group and a 2-methyl-2-propenyl group.

Preferred examples when the organic group serving as R^{22a} is an alkyl group include a methyl group, an ethyl group, an n-propyl group, an isopropyl group, an n-butyl group, a sec-butyl group, a tert-butyl group, an isobutyl group, an n-pentyl group, an isopentyl group, a tert-pentyl group, an n-hexyl group, an n-hexane-2-yl group, an n-hexane-3-yl group, an n-heptyl group, an n-heptane-2-yl group, an n-heptane-3-yl group, an isoheptyl group, a tert-heptyl group, an n-octyl group, an isooctyl group, a tert-octyl group, a 2-ethylhexyl group, an n-nonyl group, an isononyl group, an n-decyl group, an n-undecyl group, an n-dodecyl group, an n-tridecyl group, an n-tetradecyl group, an n-pentadecyl group, an n-hexadecyl group, an n-heptadecyl group and an n-octadecyl group.

When the organic group serving as R^{22a} is an alicyclic hydrocarbon group, examples of an alicyclic hydrocarbon constituting the main skeleton of the alicyclic hydrocarbon group include cyclopropane, cyclobutane, cyclopentane, cyclohexane, cycloheptane, cyclooctane, cyclodecane, bicyclo[2.1.1] hexane, bicyclo[2.2.1] heptane, bicyclo[3.2.1] octane, bicyclo[2.2.2] octane and adamantane. As the alicyclic hydrocarbon group, groups obtained by removing one hydrogen atom from these alicyclic hydrocarbons are preferable.

Preferred examples when the organic group serving as R^{22a} is an aliphatic hydrocarbon group which is substituted with a halogen atom include a trifluoromethyl group, a pentafluoroethyl group, a 2-chloroethyl group, a 2-bromoethyl group, a heptafluoro-n-propyl group, a 3-bromopropyl group, a nonafluoro-n-butyl group, a tridecafluoro-n-hexyl group, a heptadecafluoro-n-octyl group, a 2,2,2-trifluoroethyl group, a 1,1-difluoroethyl group, a 1,1-difluoro-n-propyl group, a 1,1,2,2-tetrafluoro-n-propyl group, a 3,3,3-trifluoro-n-propyl group, a 2,2,3,3,3-pentafluoro-n-propyl group, a 2-norbornyl-1,1-difluoroethyl group, a 2-norbornyl tetrafluoroethyl group and a 3-adamantyl-1,1,2,2-tetrafluoropropyl.

Preferred examples when the organic group serving as R^{22a} is an aliphatic hydrocarbon group which is substituted with an alkylthio group include a 2-methylthioethyl group, a 4-methylthio-n-butyl group and a 2-n-butylthioethyl group.

Preferred examples when the organic group serving as R^{22a} is an aliphatic hydrocarbon group which is substituted with a halogen atom and an alkylthio group include a 3-methylthio-1,1,2,2-tetrafluoro-n-propyl group.

Preferred examples when the organic group serving as R^{22a} is an aryl group include a phenyl group, a naphthyl group and a biphenylyl group.

Preferred examples when the organic group serving as R^{22a} is an aryl group which is substituted with a halogen atom include a pentafluorophenyl group, a chlorophenyl group, a dichlorophenyl group and a trichlorophenyl group.

Preferred examples when the organic group serving as R^{22a} is an aryl group which is substituted with an alkylthio group include a 4-methylthiophenyl group, a 4-n-butylthiophenyl group, a 4-n-octylthiophenyl group and a 4-n-dodecylthiophenyl group.

Preferred examples when the organic group serving as R^{22a} is an aryl group which is substituted with a halogen atom or an alkylthio group include a 1,2,5,6-tetrafluoro-4-methylthiophenyl group, a 1,2,5,6-tetrafluoro-4-n-butylthiophenyl group and a 1,2,5,6-tetrafluoro-4-n-dodecylthiophenyl group.

Preferred examples when the organic group serving as R^{22a} is an aralkyl group include a benzyl group, a phenethyl group, a 2-phenylpropane-2-yl group, a diphenylmethyl group and a triphenylmethyl group.

Preferred examples when the organic group serving as R^{22a} is an aralkyl group which is substituted with a halogen atom include a pentafluorophenylmethyl group, a phenyldifluoromethyl group, a 2-phenyltetrafluoroethyl group and a 2-(pentafluorophenyl) ethyl group.

Preferred examples when the organic group serving as R^{22a} is an aralkyl group which is substituted with an alkylthio group include a p-methylthiobenzyl group.

Preferred examples when the organic group serving as R^{22a} is an aralkyl group which is substituted with a halogen atom and an alkylthio group include a 2-(2,3,5,6-tetrafluoro-4-methylthiophenyl) ethyl group.

Preferred examples when the organic group serving as R^{22a} is an alkyl aryl group include a 2-methylphenyl group, a 3-methylphenyl group, a 4-methylphenyl group, a 3-isopropylphenyl group, a 4-isopropylphenyl group, a 4-n-butylphenyl group, a 4-isobutylphenyl group, a 4-tert-butylphenyl group, a 4-n-hexylphenyl group, a 4-cyclohexylphenyl group, a 4-n-octylphenyl group, a 4-(2-ethyl-n-hexyl) phenyl group, a 2,3-dimethylphenyl group, a 2,4-dimethylphenyl group, a 2,5-dimethylphenyl group, a 2,6-dimethylphenyl group, a 3,4-dimethylphenyl group, a 3,5-dimethylphenyl group, a 2,4-di-tert-butylphenyl group, a 2,5-di-tert-butylphenyl group, a 2,6-di-tert-butylphenyl group, a 2,4-di-tert-pentylphenyl group, a 2,5-di-tert-pentylphenyl group, a 2,5-di-tert-octylphenyl group, a 2-cyclohexylphenyl group, a 3-cyclohexylphenyl group, a 4-cyclohexylphenyl group, a 2,4,5-trimethylphenyl group, a 2,4,6-trimethylphenyl group and a 2,4,6-triisopropylphenyl group.

The group represented by the formula (a21a) is an ether group-containing group. In the formula (a21a), examples of an alkanediyl group represented by Y¹ and having 1 or more and 4 or less carbon atoms include a methylene group, an ethane-1,2-diyl group, an ethane-1,1-diyl group, a propane-1,3-diyl group, a propane-1,2-diyl group, a butane-1,4-diyl group, a butane-1,3-diyl group, a butane-2,3-diyl group and a butane-1,2-diyl group. In the formula (a21a), examples of an alkanediyl group represented by R^{27a} or R^{28a} and having 2 or more and 6 or less carbon atoms include an etan-1,2-diyl group, a propane-1,3-diyl group, a propane-1,2-diyl group, a butane-1,4-diyl group, a butane-1,3-diyl group, a butane-2,3-diyl group, a butane-1,2-diyl group, a pentane-1,5-diyl group, a pentane-1,3-diyl group, a pentane-1,4-diyl group, a pentane-2,3-diyl group, a hexane-1,6-diyl group, a hexane-1,2-diyl group, a hexane-1,3-diyl group, a hexane-1,4-diyl group, a hexane-2,5-diyl group, a hexane-2,4-diyl group and a hexane-3,4-diyl group.

In the formula (a21a), when R^{27a} or R^{28a} is an alkanediyl group having 2 or more and 6 or less carbon atoms which is substituted with a halogen atom, examples of the halogen atom include a chlorine atom, a bromine atom, an iodine atom and a fluorine atom. Examples of the alkanediyl group substituted with a halogen atom include a tetrafluoroethane-1,2-diyl group, a 1,1-difluoroethane-1,2-diyl group, a 1-fluoroethane-1,2-diyl group, a 1,2-difluoroethane-1,2-diyl group, a hexafluoropropane-1,3-diyl group, a 1,1,2,2-tetrafluoropropane-1,3-diyl group and a 1,1,2,2-tetrafluoropentane-1,5-diyl group.

In the formula (a21a), examples when R^{27a} or R^{28a} is an arylene group include a 1,2-phenylene group, a 1,3-phenylene group, a 1,4-phenylene group, a 2,5-dimethyl-1,4-phenylene group, a biphenyl-4,4′-diyl group, a diphenylmethane-4,4′-diyl group, a 2,2-diphenylpropane-4,4′-diyl group, a naphthalene-1,2-diyl group, a naphthalene-1,3-diyl group, a naphthalene-1,4-diyl group, a naphthalene-1,5-diyl group, a naphthalene-1,6-diyl group, a naphthalene-1,7-diyl group, a naphthalene-1,8-diyl group, a naphthalene-2,3-diyl group, a naphthalene-2,6-diyl group and a naphthalene-2,7-diyl group.

In the formula (a21a), when R^{27a} or R^{28a} is an arylene group which is substituted with a halogen atom, examples of the halogen atom include a chlorine atom, a bromine atom, an iodine atom and a fluorine atom. Examples of the arylene group substituted with a halogen atom include a 2,3,5,6-tetrafluoro-1,4-phenylene group.

In the formula (a21a), examples of an alkyl group having 1 or more and 18 or less carbon atoms which is represented by R^{29a} and may branch include a methyl group, an ethyl group, an n-propyl group, an isopropyl group, an n-butyl group, a sec-butyl group, a tert-butyl group, an isobutyl group, an n-pentyl group, an isopentyl group, a tert-pentyl group, an n-hexyl group, an n-hexane-2-yl group, an n-hexane-3-yl group, an n-heptyl group, an n-heptane-2-yl group, an n-heptane-3-yl group, an isoheptyl group, a tert-heptyl group, an n-octyl group, an isooctyl group, a tert-octyl group, a 2-ethylhexyl group, an n-nonyl group, an isononyl group, an n-decyl group, an n-undecyl group, an n-dodecyl group, an n-tridecyl group, an n-tetradecyl group, an n-pentadecyl group, an n-hexadecyl group, an n-heptadecyl group and an n-octadecyl group.

In the formula (a21a), when R^{29a} is an alkyl group having 1 or more and 18 or less carbon atoms which is substituted with a halogen atom, examples of the halogen atom include a chlorine atom, a bromine atom, an iodine atom and a fluorine atom. Examples of the alkyl group substituted with a halogen atom include a trifluoromethyl group, a pentafluoroethyl group, a heptafluoro-n-propyl group, a nonafluoro-n-butyl group, a tridecafluoro-n-hexyl group, a heptadecafluoro-n-octyl group, a 2,2,2-tri fluoroethyl group, a 1,1-difluoroethyl group, a 1,1-difluoro-n-propyl group, a 1,1,2,2-tetrafluoro-n-propyl group, a 3,3,3-trifluoro-n-propyl group, a 2,2,3,3,3-pentafluoro-n-propyl group and a 1,1,2,2-tetrafluorotetradecyl group.

In the formula (a21a), when R^{29a} is an alicyclic hydrocarbon group having 3 or more and 12 or less carbon atoms, examples of an alicyclic hydrocarbon constituting the main skeleton of the alicyclic hydrocarbon group include cyclopropane, cyclobutane, cyclopentane, cyclohexane, cycloheptane, cyclooctane, cyclodecane, bicyclo[2.1.1] hexane, bicyclo[2.2.1] heptane, bicyclo[3.2.1] octane, bicyclo[2.2.2] octane and adamantane. As the alicyclic hydrocarbon group, groups obtained by removing one hydrogen atom from these alicyclic hydrocarbons are preferable.

In the formula (a21a), when R^{29a} is an aryl group, an aryl halide group, an aralkyl group and a halogenated aralkyl group, preferred examples of these groups are the same as those when R^{22a} is these groups.

A preferred group among groups represented by the formula (a21a) is a group among groups represented by R^{27a} in which a carbon atom bonded to a sulfur atom is substituted with a fluorine atom. The number of carbon atoms in the preferred group is preferably 2 or more and 18 or less.

As R^{22a}, a perfluoroalkyl group having 1 or more and 8 or less carbon atoms is preferable. Since a resist pattern with a high resolution is easily formed, a camphor-10-il group is also preferable as R^{22a}.

In the formula (a21), R^{23a} to R^{26a} are a hydrogen atom or a monovalent organic group. R^{23a} and R^{24a}, R^{24a} and R^{25a} or R^{25a} and R^{26a} may be bonded to each other to form a ring. For example, R^{25a} and R^{26a} are bonded to form a 5-membered ring together with a naphthalene ring, with the result that an acenaphthene skeleton may be formed.

Preferred examples of the monovalent organic group include: an alkyl group and an alkoxy group having 4 or more and 18 or less carbon atoms which may be substituted with an alicyclic hydrocarbon group, a heterocyclic group (heterocyclyl group) or a halogen atom and may branch; a heterocyclyloxy group; an alkylthio group having 4 or more and 18 or less carbon atoms which may be substituted with an alicyclic hydrocarbon group, a heterocyclic group (heterocyclyl group) or a halogen atom and may branch; and a heterocyclylthio group. A group in which a methylene group in an arbitrary position that is not adjacent to an oxygen atom in the alkoxy group is substituted with —CO— is also preferable. A group in which the alkoxy group is interrupted by a —O—CO-bond or a O—CO—NH-bond is also preferable. The left end of the —O—CO-bond or the O—CO—NH-bond is a side close to a naphthalic acid matrix in the alkoxy group. Furthermore, an alkylthio group having 4 or more and 18 or less carbon atoms which may be substituted with an alicyclic hydrocarbon group, a heterocyclic group or a halogen atom and may branch is also preferable as R^{23a} to R^{26a}. A group in which a methylene group in an arbitrary position that is not adjacent to a sulfur atom in the alkylthio group is substituted with —CO— is also preferable. A group in which the alkylthio group is interrupted by a —O—CO-bond or a —O—CO—NH-bond is also preferable. The left end of the —O—CO-bond or the —O—CO—NH-bond is a side close to a naphthalic acid matrix in the alkylthio group.

In R^{23a} to R^{26a}, it is preferable that R^{23a} is an organic group and R^{24a} to R^{26a} are a hydrogen atom, or R^{24a} is an organic group and R^{23a}, R^{25a} and R^{26a} are a hydrogen atom. All R^{23a} to R^{26a} may be a hydrogen atom.

Examples when R^{23a} to R^{26a} are an unsubstituted alkyl group include an n-butyl group, a sec-butyl group, a tert-butyl group, an isobutyl group, an n-pentyl group, an isopentyl group, a tert-pentyl group, an n-hexyl group, an n-heptyl group, an isoheptyl group, a tert-heptyl group, an n-octyl group, an isooctyl group, a tert-octyl group, a 2-ethylhexyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group and an n-octadecyl group.

Examples when R^{23a} to R^{26a} are an unsubstituted alkoxy group include an n-butyloxy group, a sec-butyloxy group, a tert-butyloxy group, an isobutyloxy group, an n-pentyloxy group, an isopentyloxy group, a tert-pentyloxy group, an n-hexyloxy group, an n-heptyloxy group, an isoheptyloxy group, a tert-heptyloxy group, an n-octyloxy group, an isooctyloxy group, a tert-octyloxy group, a 2-ethylhexyl group, an n-nonyloxy group, an n-decyloxy group, an n-undecyloxy group, an n-dodecyloxy group, an n-tridecyloxy group, an n-tetradecyloxy group, an n-pentadecyloxy group, an n-hexadecyloxy group, an n-heptadecyloxy group and an n-octadecyloxy group.

Examples when R^{23a} to R^{26a} are an unsubstituted alkylthio group include an n-butylthio group, a sec-butylthio group, a tert-butylthio group, an isobutylthio group, an n-pentylthio group, an isopentylthio group, a tert-pentylthio group, an n-hexylthio group, an n-heptylthio group, an isoheptylthio group, a tert-heptylthio group, an n-octylthio group, an isooctylthio group, a tert-octylthio group, a 2-ethylhexylthio group, an n-nonylthio group, an n-decylthio group, an n-undecylthio group, an n-dodecylthio group, an n-tridecylthio group, an n-tetradecylthio group, an n-pentadecylthio group, an n-hexadecylthio group, an n-heptadecylthio group and an n-octadecylthio group.

When R^{23a} to R^{26a} are an alkyl group, an alkoxy group or an alkylthio group substituted with an alicyclic hydrocarbon group, examples of an alicyclic hydrocarbon constituting the main skeleton of the alicyclic hydrocarbon group include cyclopropane, cyclobutane, cyclopentane, cyclohexane, cycloheptane, cyclooctane, cyclodecane, bicyclo[2.1.1] hexane, bicyclo[2.2.1] heptane, bicyclo[3.2.1] octane, bicyclo[2.2.2] octane and adamantane. As the alicyclic hydrocarbon group, groups obtained by removing one hydrogen atom from these alicyclic hydrocarbons are preferable.

When R^{23a} to R^{26a} are an alkyl group, an alkoxy group or an alkylthio group substituted with a heterocyclic group or when R^{23a} to R^{26a} are a heterocyclyloxy group, examples of a heterocycle constituting the main skeleton of the heterocyclic group or the heterocyclyloxy group include pyrrole, thiophene, furan, pyrane, thiopyran, imidazole, pyrazole, thiazole, isothiazole, oxazole, isooxazole, pyridine, pyrazine, pyrimidine, pyridazine, pyrrolidine, pyrazolidine, imidazolidine, isooxazolidine, isothiazolidine, piperidine, piperazine, morpholin, thiomorpholin, chroman, thiochroman, isochroman, isothiochroman, indolin, isoindrin, pyrindin, indridin, indole, indazole, purine, quinolysin, isoquinoline, quinoline, naphthylidine, phthalazine, quinoxalin, quinazoline, cinnoline, pteridine, acridin, perimidine, phenanthroline, carbazole, carboline, phenazine, antilysine, thiazylazole, oxadiazole, triazine, triazole, tetrazole, benzoimidazole, benzoxazole, benzothiazole, benzothiadiazol, benzofloxane, naphthoimidazole, benzotriazole and tetraazainden. Among these heterocyclic groups, a saturated heterocyclic group obtained by hydrogenating a ring having a conjugated bond is also preferable. As a heterocyclic group substituting an alkyl group, an alkoxy group or an alkylthio group or a heterocyclic group included in a heterocyclyloxy group, a group obtained by removing one hydrogen atom from the heterocyclic group is preferable.

Examples when R^{23a} to R^{26a} are an alkoxy group including an alicyclic hydrocarbon group include a cyclopentyloxy group, a methylcyclopentioxy group, a cyclohexyloxy group, a fluorocyclohexyloxy group, a chlorocyclohexyloxy group, a cyclohexylmethyloxy group, a methylcyclohexyloxy group, a norbornyloxy group, an ethylcyclohexyloxy group, a cyclohexylethyloxy group, a dimethyl cyclohexyloxy group, a methylcyclohexylmethyloxy group, a norbornylmethyloxy group, a trimethylcyclohexyloxy group, a 1-cyclohexylbutyloxy group, an adamantyloxy group, menthyloxy group, an n-butylcyclohexyloxy group, a tert-butylcyclohexyloxy group, a bornyloxy group, an isobornyloxy group, a decahydronaphthyloxy group, a dicyclopentadienoxy group, a 1-cyclohexylpentyloxy group, a methyleneadamantyloxy group, an adamanthylmethyloxy group, a 4-pentylcyclohexyloxy group, a cyclohexylcyclohexyl oxy group, an adamantyl ethyloxy group and a dimethyl adamantyloxy group.

Examples when R^{23a} to R^{26a} are a heterocyclyloxy group include a tetrahydrofuranyloxy group, a furfuryloxy group, a tetrahydrofurfuryloxy group, a tetrahydropyranyloxy group, a butyrolactonyloxy group and an indolyloxy group.

Examples when R^{23a} to R^{26a} are an alkylthio group including an alicyclic hydrocarbon group include a cyclopentylthio group, a cyclohexylthio group, a cyclopentylmethylthio group, a norbornylthio group and an isonorbornylthio group.

Examples when R^{23a} to R^{26a} are a heterocyclylthio group include a furfurylthio group and a tetrahydrofuranylthio group.

Examples when R^{23a} to R^{26a} are a group in which a methylene group in an arbitrary position that is not adjacent to an oxygen atom in an alkoxy group is substituted with —CO— include a 2-ketobutyl-1-oxy group, a 2-ketopentyl-1-oxy group, a 2-ketohexyl-1-oxy group, a 2-ketoheptyl-1-oxy group, a 2-ketooctyl-1-oxy group, a 3-ketobutyl-1-oxy group, a 4-ketopentyl-1-oxy group, a 5-ketohexyl-1-oxy group, a 6-ketoheptyl-1-oxy group, a 7-ketooctyl-1-oxy group, a 3-methyl-2-ketopentane-4-oxy group, a 2-ketopentan-4-oxy group, a 2-methyl-2-ketopentan-4-oxy group, a 3-ketoheptane-5-oxy group and a 2-adamantanone-5-oxy group.

Examples when R^{23a} to R^{26a} are a group in which a methylene group in an arbitrary position that is not adjacent to a sulfur atom in an alkylthio group is substituted with —CO— include a 2-ketobutyl-1-thio group, a 2-ketopentyl-1-thio group, a 2-ketohexyl-1-thio group, a 2-ketoheptyl-1-thio group, a 2-ketooctyl-1-thio group, a 3-ketobutyl-1-thio group, a 4-ketopentyl-1-thio group, a 5-ketohexyl-1-thio group, a 6-ketoheptyl-1-thio group, a 7-ketooctyl-1-thio group, a 3-methyl-2-ketopentane-4-thio group, a 2-ketopentan-4-thio group, a 2-methyl-2-ketopentan-4-thio group and a 3-ketoheptane-5-thio group.

Specific examples of the compound represented by the formula (a21) include the following compounds.

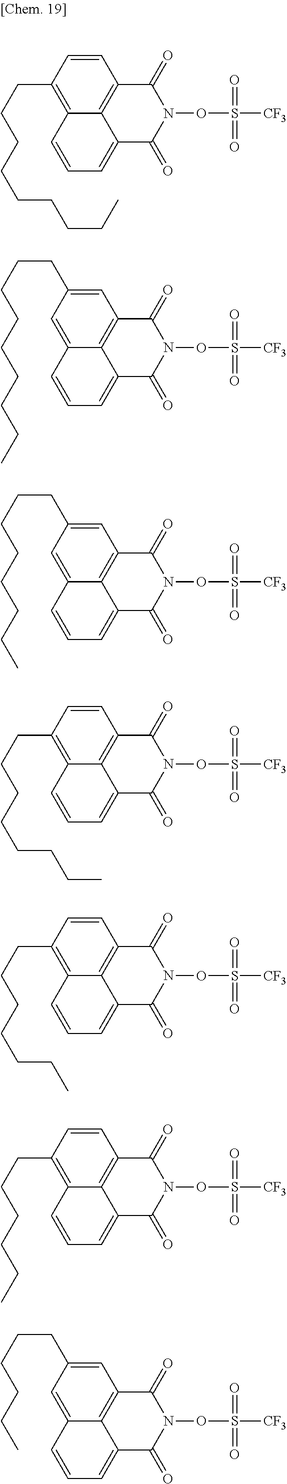

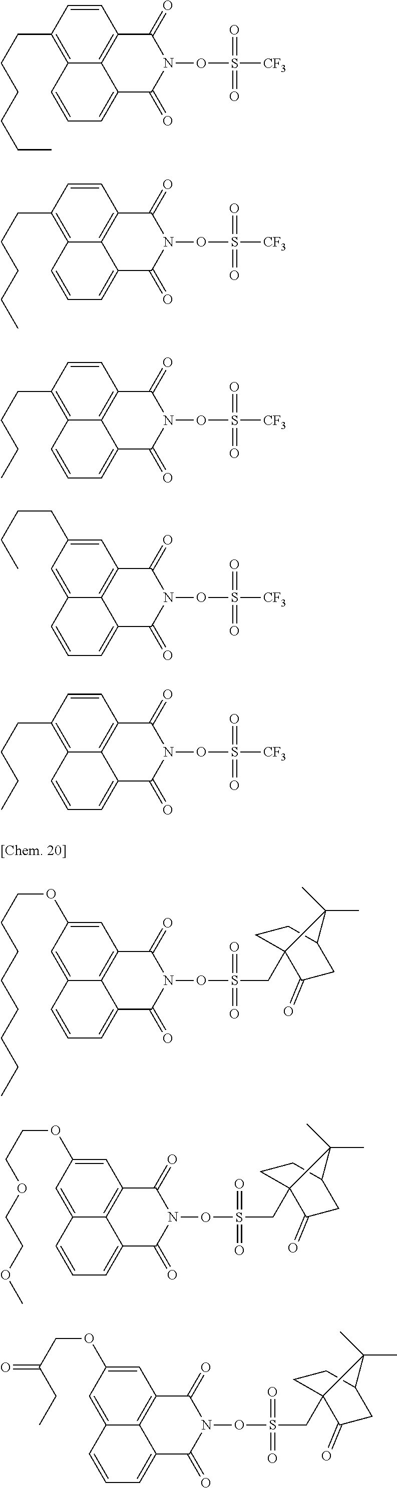

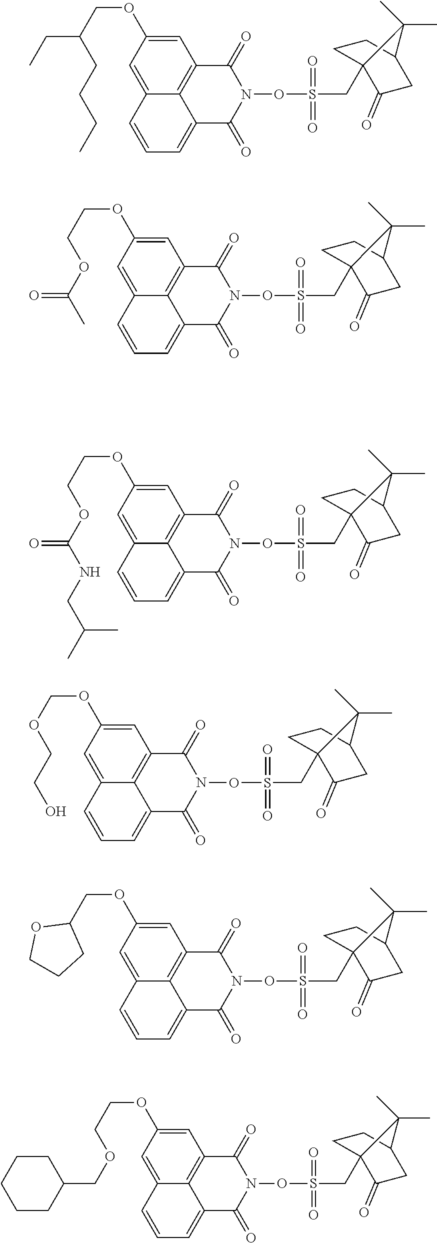

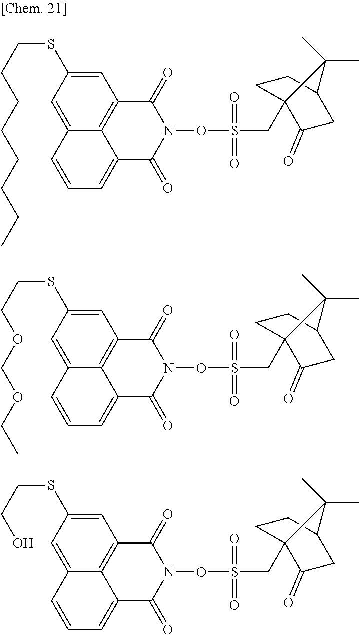

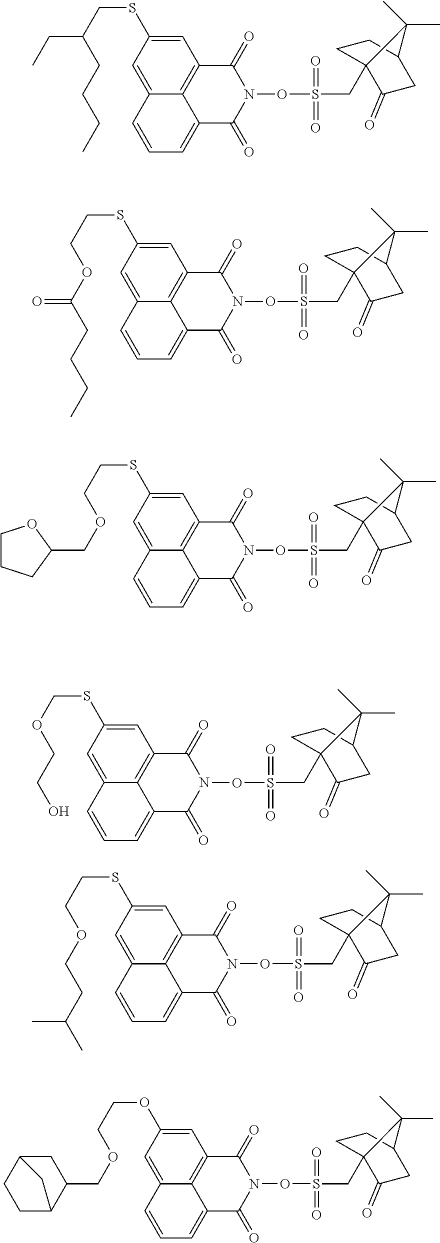

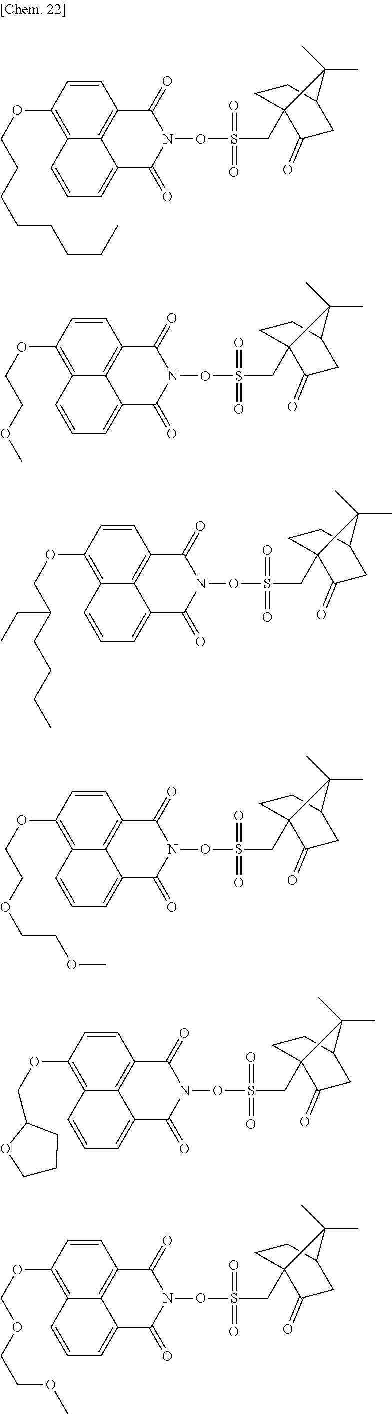

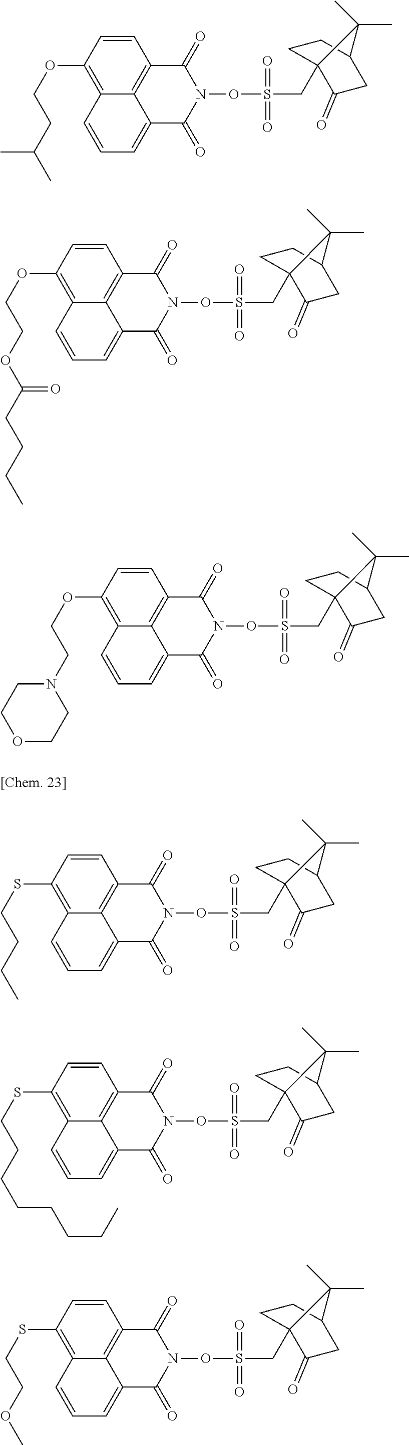 [SMILES: CC(C)CCOc1ccc2c3c(cccc13)C(=O)N(OS(=O)(=O)CC13CCC(CC1=O)C3(C)C)C2=O ; CCCCC(=O)OCCOc1ccc2c3c(cccc13)C(=O)N(OS(=O)(=O)CC13CCC(CC1=O)C3(C)C)C2=O ; CC1(C)C2CCC1(CS(=O)(=O)ON1C(=O)c3cccc4c(OCCN5CCOCC5)ccc(c34)C1=O)C(=O)C2 ; CCCCSc1ccc2c3c(cccc13)C(=O)N(OS(=O)(=O)CC13CCC(CC1=O)C3(C)C)C2=O ; CCCCCCCCSc1ccc2c3c(cccc13)C(=O)N(OS(=O)(=O)CC13CCC(CC1=O)C3(C)C)C2=O ; COCCSc1ccc2c3c(cccc13)C(=O)N(OS(=O)(=O)CC13CCC(CC1=O)C3(C)C)C2=O]

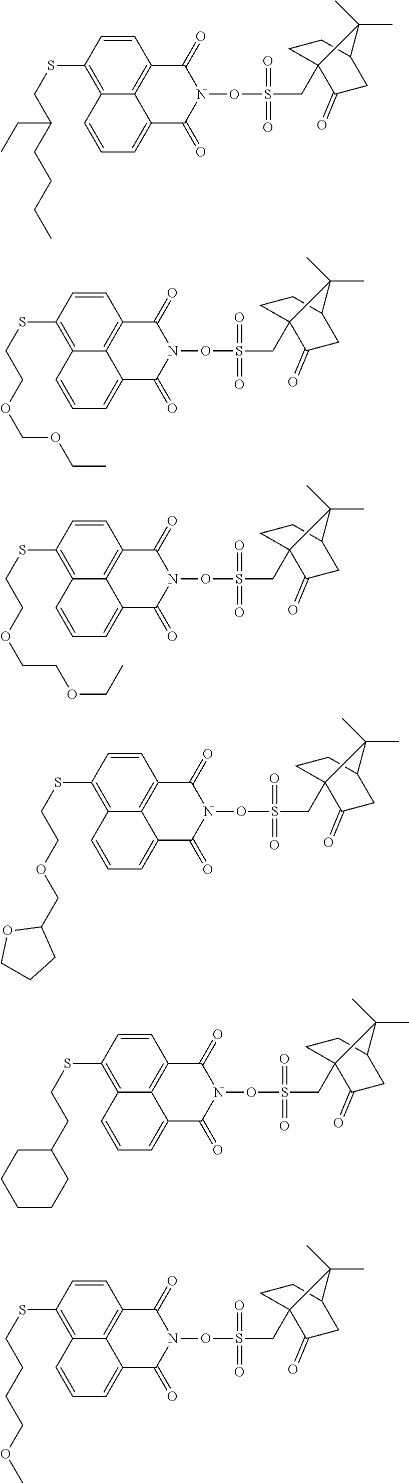 [SMILES: CCCCC(CC)CSc1ccc2c3c(cccc13)C(=O)N(OS(=O)(=O)CC13CCC(CC1=O)C3(C)C)C2=O ; CCOCOCCSc1ccc2c3c(cccc13)C(=O)N(OS(=O)(=O)CC13CCC(CC1=O)C3(C)C)C2=O ; CCOCCOCCSc1ccc2c3c(cccc13)C(=O)N(OS(=O)(=O)CC13CCC(CC1=O)C3(C)C)C2=O ; CC1(C)C2CCC1(CS(=O)(=O)ON1C(=O)c3cccc4c(SCCOCC5CCCO5)ccc(c34)C1=O)C(=O)C2 ; CC1(C)C2CCC1(CS(=O)(=O)ON1C(=O)c3cccc4c(SCCC5CCCCC5)ccc(c34)C1=O)C(=O)C2 ; COCCCCSc1ccc2c3c(cccc13)C(=O)N(OS(=O)(=O)CC13CCC(CC1=O)C3(C)C)C2=O]

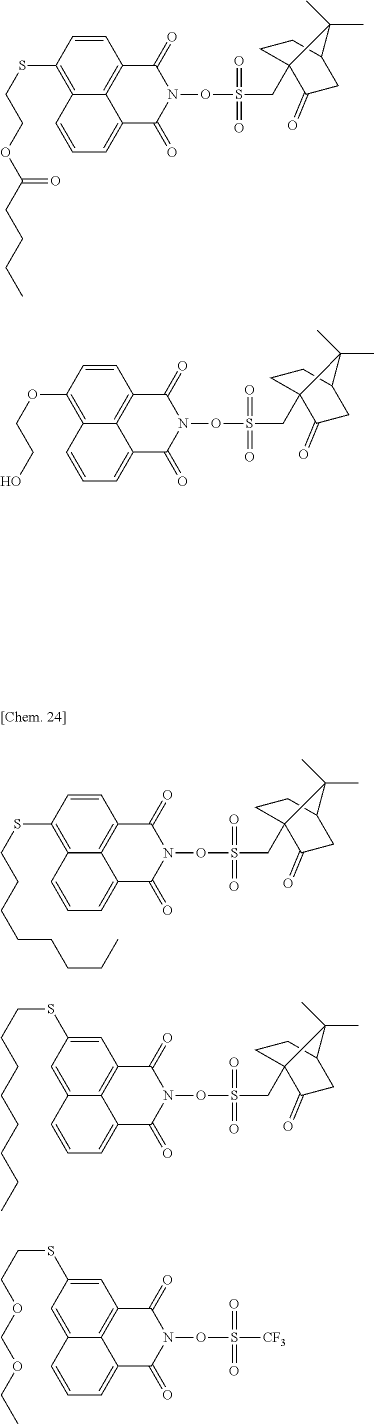

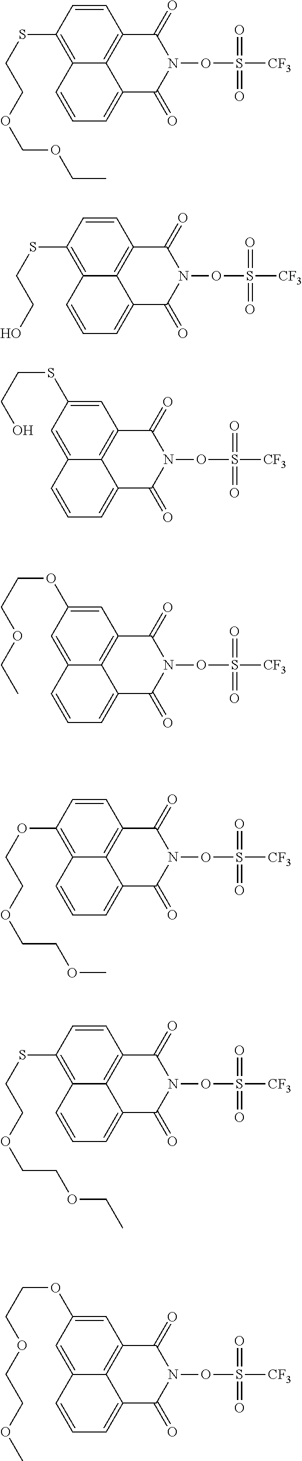

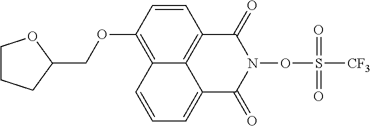 [SMILES: O=C1c2cccc3c(OCC4CCCO4)ccc(c23)C(=O)N1OS(=O)(=O)C(F)(F)F]

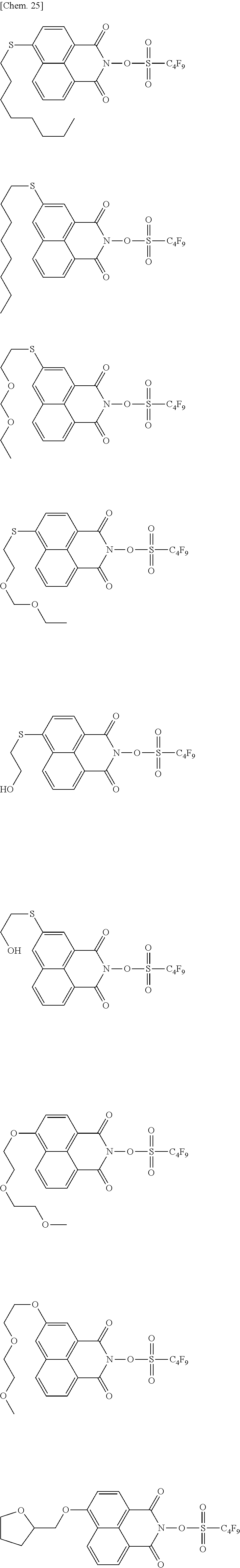

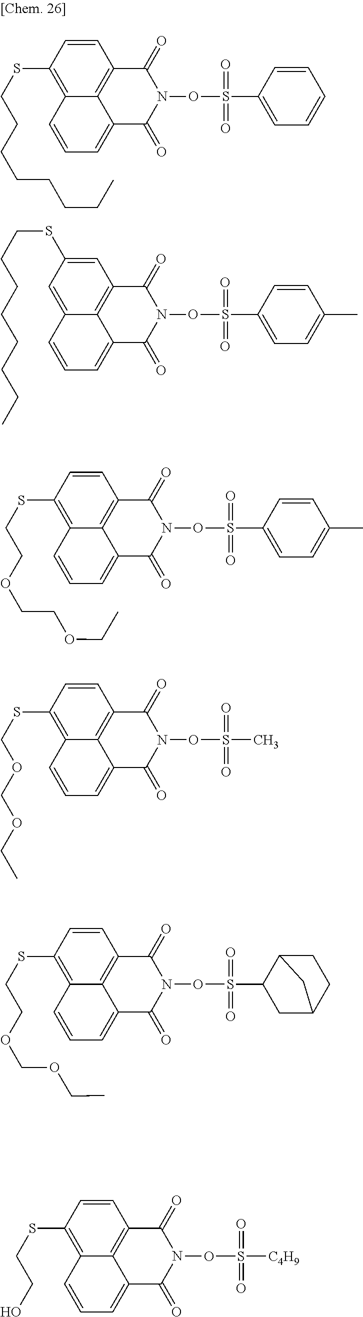

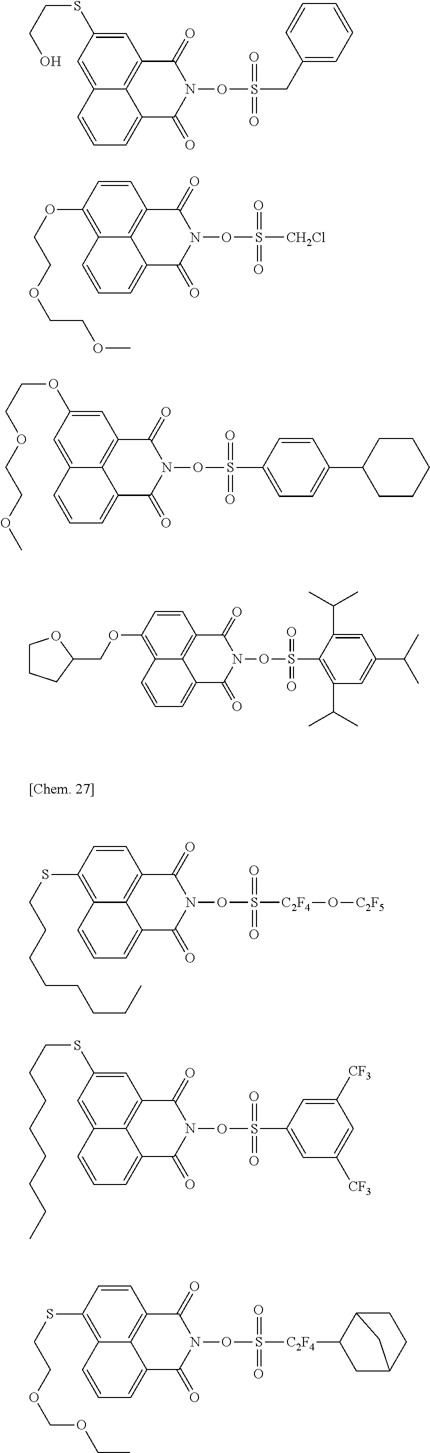

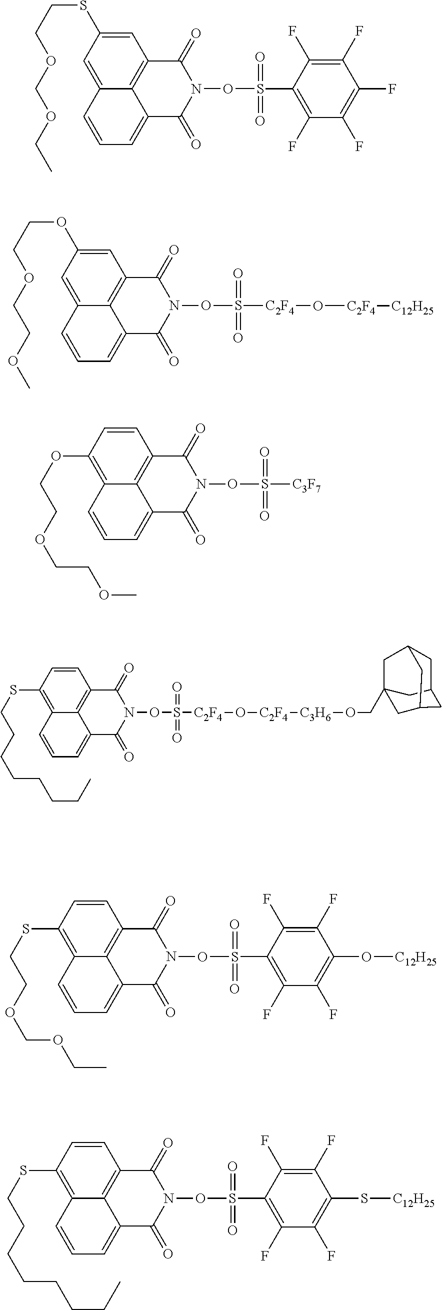

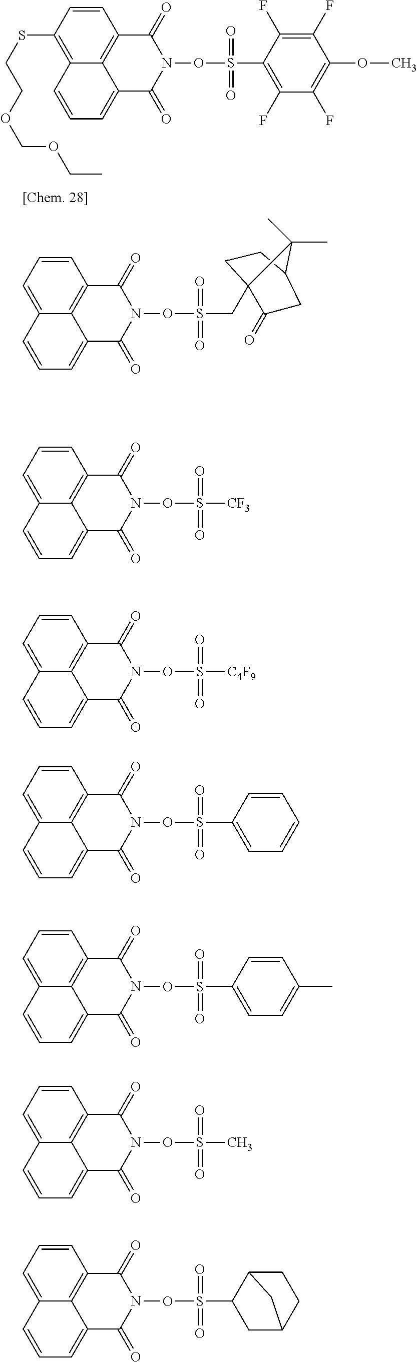

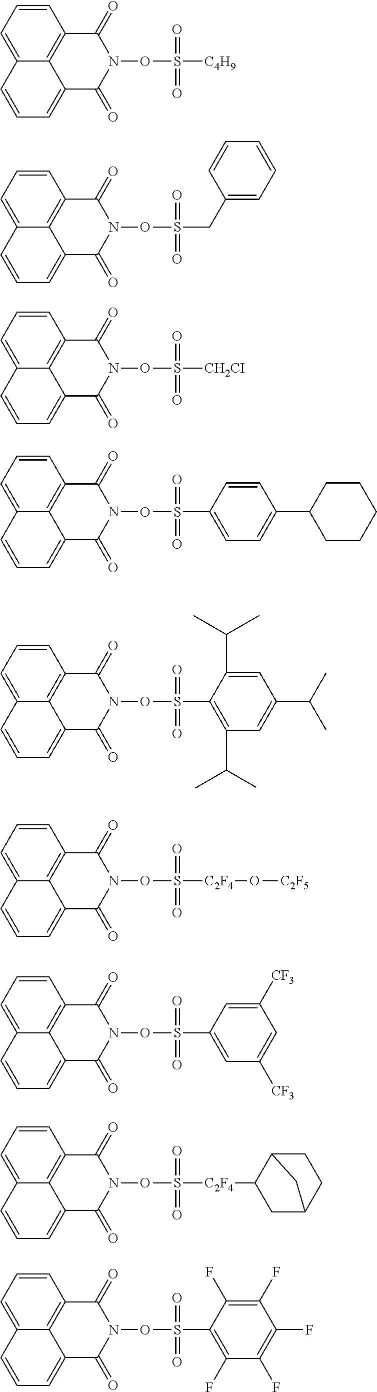

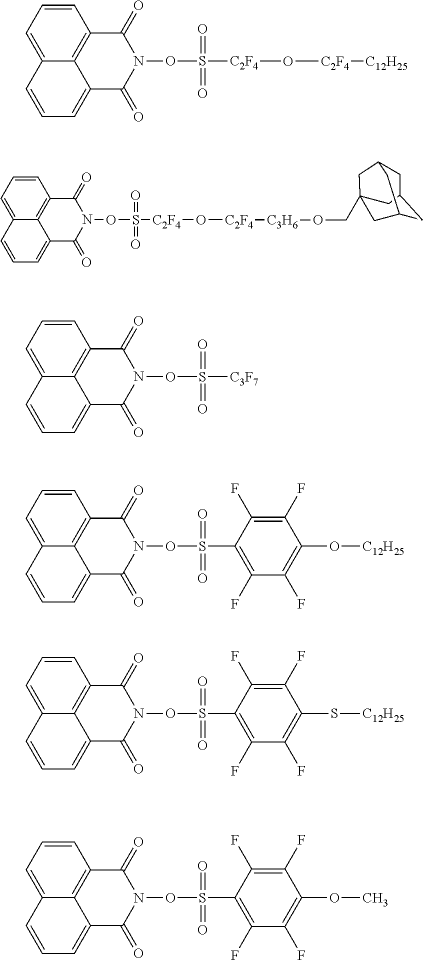

As the acid generating agent (A), a naphthalic acid derivative represented by the following formula (a22) is also preferable.

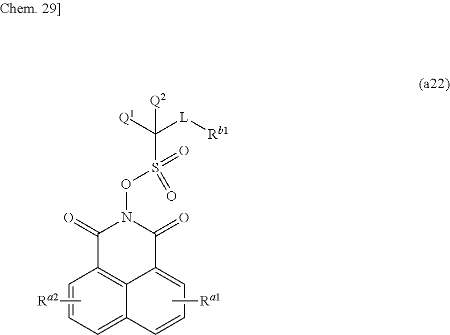

In the formula (a22), R^{b1} represents a hydrocarbon group having 1 or more and 30 or less carbon atoms. When the hydrocarbon group serving as R^{b1} includes at least one or more methylene groups, at least part of the methylene groups may be substituted with a group selected from the group consisting of —O—, —S—, —CO—, —CO—O—, —SO—, —SO₂—, —CR^{b4}R^{b5}— and —NR^{b6}—. When the hydrocarbon group serving as R^{b1} includes a hydrocarbon ring, at least one of carbon atoms constituting the hydrocarbon ring may be substituted with a heteroatom selected from the group consisting of N, O, P, S and Se or an atomic group including the heteroatom. R^{b4} and R^{b5} each independently represent a hydrogen atom or a halogen atom, and at least one of R^{b4} and R^{b5} is a halogen atom. R^{b6} represents a hydrogen atom or a hydrocarbon group having 1 or more and 6 or less carbon atoms. R^{a1} and R^{a2} each independently represent a hydrogen atom, an aliphatic hydrocarbon group having 1 or more and 20 or less carbon atoms which may have a substituent, an aromatic group having 5 or more and 20 or less ring constituent atoms which may have a substituent, or a group represented by —R^{a3}—R^{a4}. R^{a1} and R^{a2} are not simultaneously a hydrogen atom. When the aliphatic hydrocarbon group serving as R^{a1} or R^{a2} includes one or more methylene groups, at least part of the methylene groups may be substituted with a group selected from the group consisting of —O—, —S—, —CO—, —CO—O—, —SO—, —SO₂— and —NR^{a5}—. R^{a5} represents a hydrogen atom or a hydrocarbon group having 1 or more and 6 or less carbon atoms. R^{a3} represents a methylene group, —O—, —CO—, —CO—O—, —SO—, —SO₂— or —NR^{a6}—. R^{a6} represents a hydrogen atom or a hydrocarbon group having 1 or more and 6 or less carbon atoms. R^{a4} represents an aromatic group having 5 or more and 20 or less ring constituent atoms which may have a substituent, a perfluoroalkyl group having 1 or more and 6 or less carbon atoms, an aralkyl group having 7 or more and 20 or less carbon atoms which may have a substituent or a heteroarylalkyl group including an aromatic heterocyclic group having 5 or more and 20 or less ring constituent atoms which may have a substituent. Q¹ and Q² each independently represent a fluorine atom or a perfluoroalkyl group having 1 or more and 6 or less carbon atoms. L represents an ester bond.

In the formula (a22), the aliphatic hydrocarbon group serving as R^{a1} and R^{a2} and having 1 or more and 20 or less carbon atoms may be linear, branched, cyclic or a combination of the structures thereof. As the aliphatic hydrocarbon group, an alkyl group is preferable. Preferred specific examples of the alkyl group include a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, a 2-ethyl hexyl group, an n-nonyl group and an n-decyl group. Examples of a substituent which the aliphatic hydrocarbon group serving as R^{a1} and R^{a2} and having 1 or more and 20 or less carbon atoms may include a hydroxy group, a mercapto group, an amino group, a halogen atom, an oxygen atom, a nitro group, a cyano group, and the like. The number of substituents is arbitrary. Examples of the aliphatic hydrocarbon group serving as R^{a1} and R^{a2} and having a substituent and 1 or more and 20 or less carbon atoms include a perfluoroalkyl group having 1 or more and 6 or less carbon atoms. Specific examples thereof include CF₃—, CF₃CF₂—, (CF₃)₂CF—, CF₃CF₂CF₂—, CF₃CF₂CF₂CF₂—, (CF₃)₂CFCF₂—, CF₃CF₂ (CF₃)CF— and (CF₃)₃C—.

In the formula (a22), the aromatic group serving as R^{a1} and R^{a2} and having 5 or more and 20 or less ring constituent atoms which may have a substituent may be an aromatic hydrocarbon group or an aromatic heterocyclic group. Examples of the aromatic group include aryl groups such as a phenyl group and a naphthyl group and heteroaryl groups such as a furyl group and a thienyl group. A substituent which the aromatic group having 5 or more and 20 or less ring constituent atoms may have, is the same as the substituent which the aliphatic hydrocarbon group serving as R^{a1} and R^{a2} and having 1 or more and 20 or less carbon atoms may have.

In the formula (a22), an aromatic group serving as R^{a4} and having 5 or more and 20 or less ring constituent atoms which may have a substituent, is the same as the aromatic group having 5 or more and 20 or less ring constituent atoms which may have a substituent in the description of R^{a1} and R^{a2}, In the formula (a22), a perfluoroalkyl group serving as R^{a4} and having 1 or more and 6 or less carbon atoms is the same as the perfluoroalkyl group having 1 or more and 6 or less carbon atoms in the description of R^{a1} and R^{a2}. In the formula (a22), specific examples of the aralkyl group serving as R^{a4} and having 7 or more and 20 or less carbon atoms which may have a substituent include a benzyl group, a phenethyl group, an α-naphthylmethyl group, a β-naphthylmethyl group, a 2-α-naphthylethyl group, 2-β-naphthylethyl group, and the like. In the formula (a22), the heteroarylalkyl group refers to a group in which a portion of the carbon atoms constituting an aromatic hydrocarbon ring in an arylalkyl group are substituted with a heteroatom such as N, O or S. Specific examples of the heteroarylalkyl group including the aromatic heterocyclic group serving as R^{a4} and having 5 or more and 20 or less ring constituent atoms which may have a substituent include a pyridine-2-ylmethyl group, a pyridine-3-ylmethyl group, a pyridine-4-ylmethyl group, and the like.

In the formula (a22), the hydrocarbon group serving as R^{a5} and having 1 or more and 6 or less carbon atoms may be an aliphatic hydrocarbon group, an aromatic hydrocarbon group or a combination thereof. The aliphatic hydrocarbon group may be linear, branched, cyclic or a combination of the structures thereof. Examples of the aliphatic hydrocarbon group include alkyl groups such as a methyl group, an ethyl group, an n-propyl group, an isopropyl group, an n-butyl group, an isobutyl group, a sec-butyl group, a tert-butyl group, an n-pentyl group and an n-hexyl group. Examples of the aromatic hydrocarbon group include a phenyl group.

In the formula (a22), the hydrocarbon group serving as R^{a6} and having 1 or more and 6 or less carbon atoms is the same as the hydrocarbon group having 1 or more and 6 or less carbon atoms in the description of R^{a5}.

In the formula (a22), the hydrocarbon group serving as R^{b1} and having 1 or more and 30 or less carbon atoms may be an aliphatic hydrocarbon group, an aromatic hydrocarbon group or a combination thereof. The aliphatic hydrocarbon group may be linear, branched, cyclic or a combination of the structures thereof. Examples of the aliphatic hydrocarbon group include chain aliphatic hydrocarbon groups such as a methyl group, an ethyl group, an n-propyl group, an isopropyl group, an n-butyl group, an isobutyl group, a sec-butyl group, a tert-butyl group, an n-pentyl group and an n-hexyl group and cyclic aliphatic hydrocarbon groups (hydrocarbon rings) such as a cyclopropyl group, a cyclobutyl group, a cyclopentyl group, a cyclohexyl group, an adamantyl group and a norbornyl group. Examples of the aromatic hydrocarbon group include a phenyl group and a naphthyl group. Examples of the combination of the aliphatic hydrocarbon group and the aromatic hydrocarbon group include a benzyl group, a phenethyl group and a furylmethyl group. When the hydrocarbon group serving as R^{b1} includes a hydrocarbon ring, examples of an atomic group including a heteroatom which substitutes with at least one of carbon atoms constituting the hydrocarbon ring include —CO—, —CO—O—, —SO—, —SO₂—, —SO₂—O— and —P(═O)—(OR^{b7})₃. R^{b7} is a hydrocarbon group having 1 or more and 6 or less carbon atoms and is the same as the hydrocarbon group having 1 or more and 6 or less carbon atoms in the description of R^{a5}.

In the formula (a22), specific examples of a halogen atom serving as R^{b4} and R^{b5} include a chlorine atom, a fluorine atom, a bromine atom and an iodine atom.

In the formula (a22), the hydrocarbon group serving as R^{b6} and having 1 or more and 6 or less carbon atoms is the same as the hydrocarbon group having 1 or more and 6 or less carbon atoms in the description of R^{a5} in the formula (a22).

In the formula (a22), a perfluoroalkyl group serving as Q¹ and Q² and having 1 or more and 6 or less carbon atoms is the same as the perfluoroalkyl group having 1 or more and 6 or less carbon atoms in the description of R^{a1} and R^{a2} in the formula (a22).

In the compound represented by the formula (a22), the orientation of an ester bond serving as L is not particularly limited and may be either of —CO—O— or —O—CO—.

The compound represented by the formula (a22) is preferably a compound represented by the following formula (a22-1).

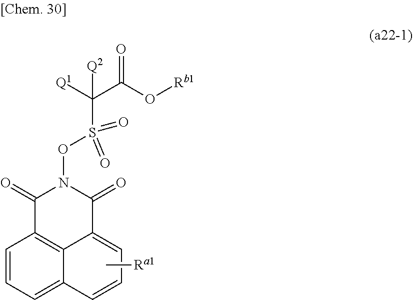

(in the formula (a22-1), R^{b1}, R^{a1}, Q¹ and Q² are the same as those in the formula (a22)).

When R^{a1} in the formula (a22-1) is a hydrocarbon group having 1 or more and 20 or less carbon atoms which may have a substituent, and the aliphatic hydrocarbon group serving as R^{a1} includes one or more methylene groups, a compound represented by the formula (a22-1) is preferable in which at least part of the methylene groups may be substituted with a group selected from the group consisting of —O—, —S—, —CO—, —CO—O—, —SO—, —SO₂— and —NR^{a5}—.

The compound represented by the formula (a22) can be manufactured by the following manufacturing method of an N-organosulfonyloxy compound. In the manufacturing method of the N-organosulfonyloxy compound capable of manufacturing the compound represented by the formula (a22), a step of making an N-hydroxy compound (a′) and a sulfonic acid fluoride compound (b′) react with each other in the presence of a basic compound (d′) is included, when the N-hydroxy compound (a′) and the sulfonic acid fluoride compound (b′) are made to react with each other, a silylating agent (c′) is present in its system, the sulfonic acid fluoride compound (b′) is represented by the following formula (b1-1) and the silylating agent (c′) can convert a hydroxy group on a nitrogen atom included in the N-hydroxy compound (a′) into a cyriloxy group represented by the following formula (ac1).

—O—Si(R^{c1})₃ (ac1)

(in the formula (ac1), R^{c1} each independently represents a hydrocarbon group having 1 or more and 10 or less carbon atoms).

R^{b1}-L-CQ¹Q²—SO₂—F (b1-1)

(in the formula (b1-1), R^{b1}, L, Q¹ and Q² each are the same as those in the above formula (a22)).

In the manufacturing method of the N-organosulfonyloxy compound capable of manufacturing the compound represented by the formula (a22), a silylating step of silylating the N-hydroxy compound (a′) with the silylating agent (c′) and a condensation step of condensing the silylated product of the N-hydroxy compound (a′) generated in the silylating step with the sulfonic acid fluoride compound (b′) in the presence of the basic compound (d′) are included, the sulfonic acid fluoride compound (b′) is represented by the above formula (b1-1) and the silylating agent can convert the hydroxy group on the nitrogen atom included in the N-hydroxy compound (a′) into the cyriloxy group represented by the above formula (ac1).

The N-hydroxy compound (a′) is a compound represented by the following formula (a22-2).

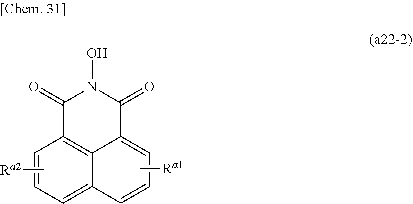

In the formula (a22-2), R^{a1} and R^{a2} are the same as those in the above formula (a22).

The N-hydroxy compound (a′) can be synthesized by, for example, an ordinary method as disclosed in the pamphlet of International Publication No. 2014/084269 and Japanese Unexamined Patent Application Publication (Translation of PCT Application) No. 2017-535595. For example, a compound in which R^{a2} represented by the formula (a22-1) is a hydrogen atom can be synthesized by converting a bromo group on a naphthalic anhydride into R^{a1} by a reaction represented by the following formula using a commercially available bromide as a starting material and thereafter causing a hydroxylamine compound such as a hydroxylamine hydrochloride to act on an acid anhydride group into N-hydroxyimide. As the N-hydroxy compound (a′), a commercially available product may be used.

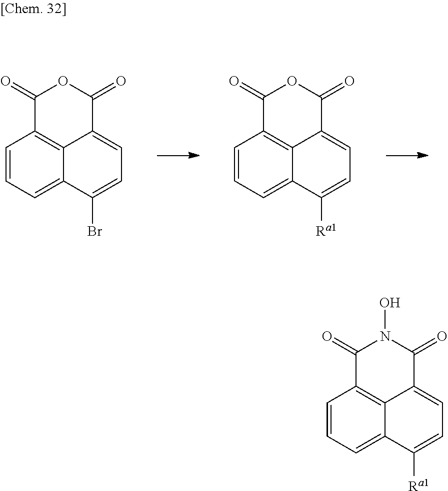

The sulfonic acid fluoride compound (b′) can be synthesized by an ordinary method. For example, in the formula (b1-1), a compound in which Q¹ and Q² are a fluorine atom can be synthesized by a reaction represented by the following formula. As the sulfonic acid fluoride compound (b′), a commercially available product may be used.

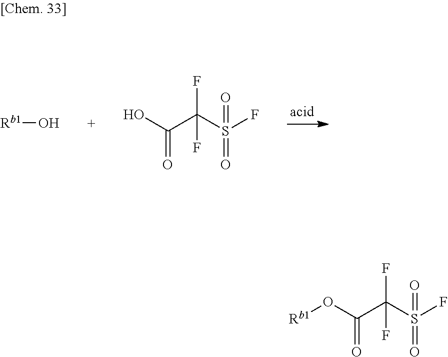

In the formula (ac1), the hydrocarbon group serving as R^{c1} and having 1 or more and 10 or less carbon atoms may be an aliphatic hydrocarbon group, an aromatic hydrocarbon group or a combination thereof. The aliphatic hydrocarbon group may be linear, branched, cyclic or a combination of the structures thereof. Examples of the aliphatic hydrocarbon group include alkyl groups such as a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, a 2-ethyl hexyl group, an n-nonyl group and an n-decyl group. Examples of the aromatic hydrocarbon group include a phenyl group and a naphthyl group.

Examples of the silylating agent (c′) include a compound represented by the following formula (c1).

X—Si(R^{c1})₃ (c1)

(in the formula (c1), R^{c1} is the same as R^{c1} in the formula (ac1), and X represents a halogen atom).

In the formula (c1), specific examples of the halogen atom serving as X include a chlorine atom, a fluorine atom, a bromine atom and an iodine atom.

Specific examples of the silylating agent (c′) include trimethylsilyl chloride, trimethylsilyl fluoride, trimethylsilyl bromide, t-butyldimethylsilyl chloride, ethyldimethylsilyl chloride and isopropyldimethylsilyl chloride.

The basic compound (d′) may be an organic base or an inorganic base. Examples of the organic base include nitrogen-containing basic compounds, and specific examples include: amines such as methylamine, ethylamine, n-propylamine, isopropylamine, n-butylamine, dimethylamine, diethylamine, di-n-propylamine, diisopropylamine, di-n-butylamine, trimethylamine, triethylamine, methyldiethylamine, N-ethyldiisopropylamine, tri-n-propylamine, triisopropylamine, monoethanolamine, diethanolamine and triethanolamine; cyclic basic compounds such as pyrrole, piperidine, 1,8-diazabicyclo[5,4,0]-7-undecene and 1,5-diazabicyclo[4,3,0]-5-nonane; quaternary ammonium salts such as tetramethylammonium hydroxide (TMAH), tetraethylammonium hydroxide, tetrapropylammonium hydroxide (TPAH), tetrabutylammonium hydroxide, methyltripropylammonium hydroxide, methyltributylammonium hydroxide, benzyltrimethylammonium hydroxide, benzyl triethylammonium hydroxide and trimethylammonium hydroxide (2-hydroxyethyl); and the like. Examples of the inorganic base include a metal hydroxide, a metal hydrogencarbonate and a metal bicarbonate. Specific examples of the inorganic base include: metal hydroxides such as lithium hydroxide, potassium hydroxide, sodium hydroxide, rubidium hydroxide, cesium hydroxide, magnesium hydroxide, calcium hydroxide, strontium hydroxide and barium hydroxide; metal hydrogencarbonates such as lithium carbonate, potassium carbonate, sodium carbonate, rubidium carbonate, cesium carbonate, magnesium carbonate, calcium carbonate, strontium carbonate and barium carbonate; and metal bicarbonates such as lithium hydrogen carbonate, potassium hydrogen carbonate, sodium hydrogen carbonate, rubidium hydrogen carbonate and cesium hydrogen carbonate.

In the manufacturing method of the N-organosulfonyloxy compound, the N-hydroxy compound (a′) and the sulfonic acid fluoride compound (b′) as described above are made to react with each other in the presence of the silylating agent (c′) and the basic compound (d′). When as described above, the N-hydroxy compound (a′) and the sulfonic acid fluoride compound (b′) are made to react with each other in the presence of the basic compound (d′), the silylating agent (c′) is present, and thus it is possible to efficiently manufacture the N-organosulfonyloxy compound. For example, with respect to the N-hydroxy compound (a′) and the sulfonic acid fluoride compound (b′) serving as the raw materials, 65% or more of the N-organosulfonyloxy compound can be obtained.

By the manufacturing method of the N-organosulfonyloxy compound, the N-organosulfonyloxy compound can be obtained which has a structure where a group obtained by removing a hydrogen atom in a hydroxy group bonded to a nitrogen atom in the N-hydroxy compound (a′) is bonded to R^{b1}—SO₂— derived from sulfonic acid fluoride compound (b′).

In the manufacturing method of the N-organosulfonyloxy compound, when the N-hydroxy compound (a′) and the sulfonic acid fluoride compound (b′) are made to react with each other in the presence of the basic compound (d′), the silylating agent (c′) is preferably present in the system, the N-hydroxy compound (a′), the sulfonic acid fluoride compound (b′), the silylating agent (c′) and the basic compound (d′) may be mixed at the same time and the sulfonic acid fluoride compound (b′) and the basic compound (d′) may be added after part of the N-hydroxy compound (a′) and the silylating agent (c′) are partially made to react with each other or after the completion of the reaction of the N-hydroxy compound (a′) and the silylating agent (c′).

When the N-hydroxy compound (a′) and the sulfonic acid fluoride compound (b′) as described above are made to react with each other in the presence of the silylating agent (c′) and the basic compound (d′), the N-hydroxy compound (a′) is silylated by the silylating agent (c′), and thus the hydroxy group on the nitrogen atom is converted into the cyriloxy group represented by the above formula (ac1) (step 1: the silylating step). Then, the silylated product of the N-hydroxy compound (a′) generated in the silylating step is condensed with the sulfonic acid fluoride compound (b′) on which the basic compound (d′) acts (step 2: the condensation step). In this way, it is possible to obtain the N-organosulfonyloxy compound.

As an example of the manufacturing method of the N-organosulfonyloxy compound, a reaction formula is shown below when the compound represented by the above formula (a22-2) is used as the N-hydroxy compound (a′), the compound in which Q¹ and Q² are a fluorine atom in the above formula (b1-1) is used as the sulfonic acid fluoride compound (b′), trimethylsilyl chloride is used as the silylating agent (c′), and triethylamine is used as the basic compound (d′). A reaction mechanism shown below is not a reaction mechanism which is analytically confirmed but a reaction mechanism which is estimated from the raw materials and behaviors in the reaction thereof.

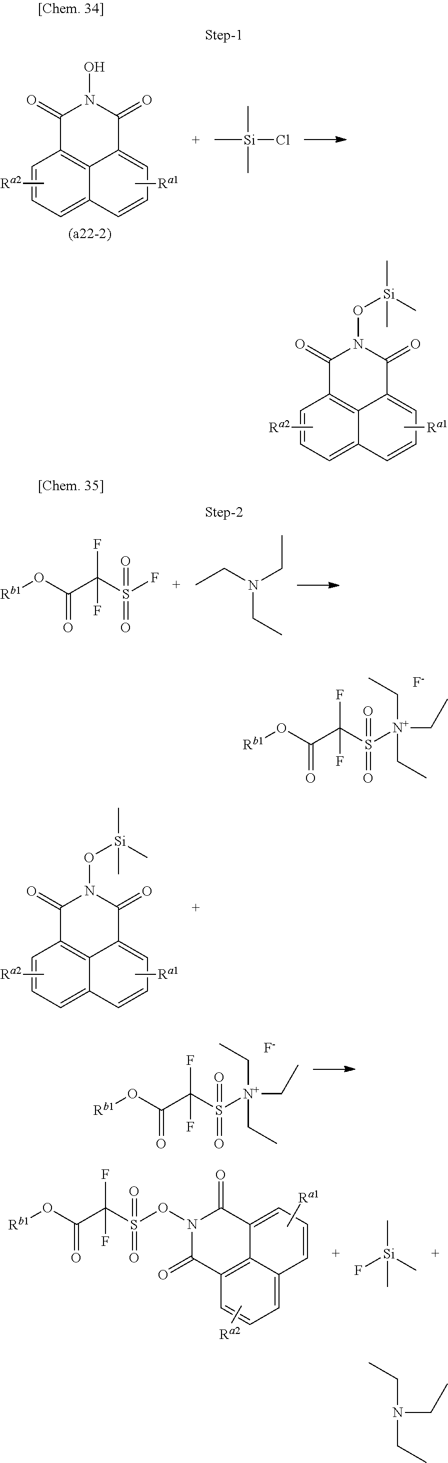

Examples of an organic solvent which can be adopted for the reaction include: esters such as ethyl acetate, butyl acetate and cellosolve acetate; ketones such as acetone, methyl ethyl ketone, isobutyl ketone and methyl isobutyl ketone; esters such as ethyl acetate, butyl acetate and diethyl malonate; amides such as N-methylpyrrolidone and N,N-dimethylformamide; ethers such as diethyl ether, ethyl cyclopentyl ether, tetrahydrofuran and dioxane; aromatic hydrocarbons such as toluene and xylene; aliphatic hydrocarbons such as hexane, heptane, octane and decahydronaphthalene; halogenated hydrocarbons such as chloroform, dichloromethane, methylene chloride and ethylene chloride; nitrile-based solvents such as acetonitrile and propionitrile; dimethyl sulfoxide; dimethyl sulfamide; and the like. One type of solvent may be used or any two or more types thereof may be combined to be used. A reaction temperature which can be adopted is in, for example, a range of −10° C. to 200° C., is preferably in a range of 0° C. to 150° C. and is more preferably in a range of 5° C. to 120° C. A reaction time which can be adopted is, for example, 5 minutes or more and 20 hours or less, 10 minutes or more and 15 hours or less or 30 minutes or more and 12 hours or less.

Preferably, each of the sulfonic acid fluoride compound (b′), the silylating agent (c′) and the basic compound (d′) is excessively used for the N-hydroxy compound (a′). For example, 1.1 moles or more and 2.5 moles or less of the sulfonic acid fluoride compound (b′), 1.1 moles or more and 2.5 moles or less of the silylating agent (c′) and 1.1 moles or more and 2.5 moles or less of the basic compound (d′) are preferably used with respect to 1.0 mole of the N-hydroxy compound (a′).

The acid generating agent (A) may be used alone or two or more types may be combined to be used. The total content of the acid generating agent (A) is preferably 0.1% by mass or more and 10% by mass or less, more preferably 0.2% by mass or more and 6% by mass or less and particularly preferably 0.5% by mass or more and 3% by mass or less with respect to the total solid content of the photosensitive composition. The amount of acid generating agent (A) used falls within the range described above, and thus it is easy to prepare the photosensitive composition which has satisfactory sensitivity, is a uniform solution and has excellent storage stability.

### <Resin (B)>

A resin (B) having alkali solubility that increases under action of acid is not particularly limited, and any resin having an alkali solubility that increases under action of acid can be used. Among them, it is preferable to contain at least one type of resin selected from the group consisting of a novolak resin (B1), a polyhydroxystyrene resin (B2) and an acrylic resin (B3).

### [Novolak Resin (B1)]

As the novolak resin (B1), a resin including a constituent unit represented by the following formula (b1) can be used.

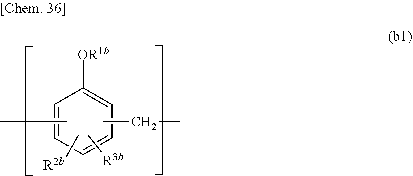

In the formula (b1), R^{1b} represents an acid-dissociable dissolution-inhibiting group, and R^{2b} and R^{3b} each independently represent a hydrogen atom or an alkyl group having 1 or more and 6 or less carbon atoms.

The acid-dissociable dissolution-inhibiting group represented by the above R^{1b} is preferably a group represented by the following formula (b2) or (b3), a linear, branched or cyclic alkyl group having 1 or more and 6 or less carbon atoms, a vinyloxyethyl group, a tetrahydropyranyl group, a tetrahydrofuranyl group or a trialkylsilyl group.

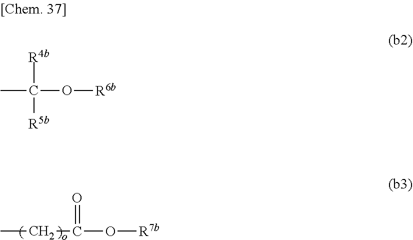

In the above formulae (b2) and (b3), R^{4b} and R^{5b} each independently represent a hydrogen atom or a linear or branched alkyl group having 1 or more and 6 or less carbon atoms, R^{6b} represents a linear, branched or cyclic alkyl group having 1 or more and 10 or less carbon atoms, R^{7b} represents a linear, branched or cyclic alkyl group having 1 or more and 6 or less carbon atoms and o represents 0 or 1.

Examples of the above linear or branched alkyl group include a methyl group, an ethyl group, a propyl group, an isopropyl group, an n-butyl group, an isobutyl group, a tert-butyl group, a pentyl group, an isopentyl group, a neopentyl group, and the like. Examples of the above cyclic alkyl group include a cyclopentyl group, a cyclohexyl group, and the like.

Specific examples of the acid-dissociable dissolution-inhibiting group represented by the above formula (b2) include a methoxyethyl group, ethoxyethyl group, n-propoxyethyl group, isopropoxyethyl group, n-butoxyethyl group, isobutoxyethyl group, tert-butoxyethyl group, cyclohexyloxyethyl group, methoxypropyl group, ethoxypropyl group, 1-methoxy-1-methylethyl group, 1-ethoxy-1-methylethyl group, and the like. Specific examples of the acid-dissociable dissolution-inhibiting group represented by the above formula (b3) include a tert-butoxycarbonyl group, a tert-butoxycarbonylmethyl group, and the like. Examples of the above trialkylsilyl group include a trimethylsilyl group and a tri-tert-butyldimethylsilyl group in which each alkyl group has 1 or more and 6 or less carbon atoms.

### [Polyhydroxystyrene Resin (B2)]

As the polyhydroxystyrene resin (B2), a resin including a constituent unit represented by the following formula (b4) can be used.

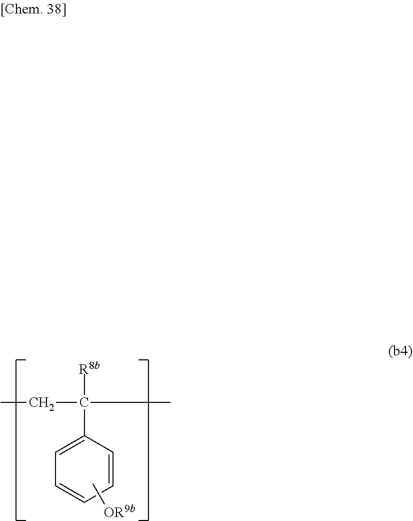

In the above formula (b4), R^{8b} represents a hydrogen atom or an alkyl group having 1 or more and 6 or less carbon atoms, and R^{9b} represents an acid-dissociable dissolution-inhibiting group.

The above alkyl group having 1 or more and 6 or less carbon atoms is, for example, a linear, branched or cyclic alkyl group having 1 or more and 6 or less carbon atoms. Examples of the linear or branched alkyl group include a methyl group, ethyl group, propyl group, isopropyl group, n-butyl group, isobutyl group, tert-butyl group, pentyl group, isopentyl group, neopentyl group, and the like. Examples of the cyclic alkyl group include a cyclopentyl group, a cyclohexyl group, and the like.

As an acid-dissociable dissolution-inhibiting group represented by the above R^{9b}, the acid-dissociable dissolution-inhibiting groups similar to those exemplified by the above formulae (b2) and (b3) can be used.

Furthermore, the polyhydroxystyrene resin (B2) can include another polymerizable compound as a constituent unit in order to moderately control physical and chemical properties. Examples of the polymerizable compound as described above include a conventional radical polymerizable compound and an anion polymerizable compound. Examples of the polymerizable compound include monocarboxylic acids such as acrylic acid, methacrylic acid and crotonic acid; dicarboxylic acids such as maleic acid, fumaric acid and itaconic acid; methacrylic acid derivatives having a carboxyl group and an ester bond such as 2-methacryloyloxyethyl succinic acid, 2-methacryloyloxyethyl maleic acid, 2-methacryloyloxyethyl phthalic acid and 2-methacryloyloxyethyl hexahydrophthalic acid; (meth)acrylic acid alkyl esters such as methyl(meth)acrylate, ethyl (meth)acrylate and butyl (meth)acrylate; (meth)acrylic acid hydroxyalkyl esters such as 2-hydroxyethyl (meth)acrylate and 2-hydroxypropyl (meth)acrylate; (meth)acrylic acid aryl esters such as phenyl (meth)acrylate and benzyl (meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; and amide bond-containing polymerizable compounds such as acrylamide and methacrylamide.

### [Acrylic Resin (B3)]

An acrylic resin (B3) is not particularly limited as long as it is an acrylic resin which has an alkali solubility that increases under action of acid and is conventionally mixed with various photosensitive compositions. Preferably, the acrylic resin (B3) contains a constituent unit (b-3) derived from, for example, an acrylic ester including an —SO₂— containing cyclic group or a lactone-containing cyclic group. In such a case, when a resist pattern is formed, a resist pattern having a preferable cross-sectional shape can easily be formed.

### (—SO₂-Containing Cyclic Group)

Here, the “—SO₂-containing cyclic group” refers to a cyclic group containing a ring including —SO₂— in the ring skeleton thereof, and is specifically a cyclic group in which the sulfur atom (S) in —SO₂— forms part of the ring skeleton of the cyclic group. With the assumption that a ring including —SO₂— in the ring skeleton thereof is the first ring, a group which has that ring alone is called a monocyclic group, and a group that further has another ring structure is called a polycyclic group regardless of its structure. The —SO₂— containing cyclic group may be monocyclic or polycyclic.

In particular, the —SO₂-containing cyclic group is preferably a cyclic group containing —O—SO₂— in the ring skeleton thereof, that is, a cyclic group containing a sultone ring in which —O—S— in —O—SO₂— forms part of the ring skeleton.

The number of carbon atoms in the —SO₂-containing cyclic group is preferably 3 or more and 30 or less, more preferably 4 or more and 20 or less, further preferably 4 or more and 15 or less and particularly preferably 4 or more and 12 or less. The number of carbon atoms described above is the number of carbon atoms constituting a ring skeleton, and is assumed to exclude the number of carbon atoms in a substituent.

The —SO₂-containing cyclic group may be an —SO₂-containing aliphatic cyclic group or an —SO₂-containing aromatic cyclic group. The —SO₂-containing cyclic group is preferably an —SO₂-containing aliphatic cyclic group.

Examples of the —SO₂-containing aliphatic cyclic group include a group in which at least one hydrogen atom is removed from an aliphatic hydrocarbon ring where part of the carbon atoms constituting the ring skeleton thereof is substituted with —SO₂— or —O—SO₂—. More specifically, examples include a group in which at least one hydrogen atom is removed from an aliphatic hydrocarbon ring where —CH₂— constituting the ring skeleton thereof is substituted with —SO₂—, a group in which at least one hydrogen atom is removed from an aliphatic hydrocarbon ring where —CH₂—CH₂— constituting the ring thereof is substituted with —O—SO₂—, and the like.

The number of carbon atoms in the alicyclic hydrocarbon ring described above is preferably 3 or more and 20 or less, and more preferably 3 or more and 12 or less. The alicyclic hydrocarbon ring described above may be polycyclic or monocyclic. As the monocyclic alicyclic hydrocarbon group, a group in which two hydrogen atoms are removed from monocycloalkane having 3 or more and 6 or less carbon atoms is preferable. Examples of the monocycloalkane described above can include cyclopentane, cyclohexane, and the like. As the polycyclic alicyclic hydrocarbon ring, a group in which two hydrogen atoms are removed from polycycloalkane having 7 or more and 12 or less carbon atoms is preferable, and specific examples of the polycycloalkane described above include adamantane, norbornane, isobornane, tricyclodecane, tetracyclododecane, and the like.

The —SO₂-containing cyclic group may have a substituent. Examples of the substituent described above include an alkyl group, an alkoxy group, a halogen atom, a halogenated alkyl group, a hydroxyl group, an oxygen atom (═O), —COOR″, —OC(═O)R″, a hydroxyalkyl group, a cyano group, and the like.

As an alkyl group serving as the substituent described above, an alkyl group which has 1 or more and 6 or less carbon atoms is preferable. The alkyl group described above is preferably linear or branched. Specific examples include a methyl group, an ethyl group, an n-propyl group, an isopropyl group, an n-butyl group, an isobutyl group, a tert-butyl group, an n-pentyl group, an isopentyl group, a neopentyl group, an n-hexyl group, and the like. Among these, a methyl group or an ethyl group is preferable, and a methyl group is particularly preferable.

As an alkoxy group serving as the substituent described above, an alkoxy group which has 1 or more and 6 or less carbon atoms is preferable. The alkoxy group described above is preferably linear or branched. Specific examples include a group in which the alkyl group described as the above substituent is bonded to the oxygen atom (—O—).

Examples of the halogen atom serving as the substituent described above include a fluorine atom, a chlorine atom, a bromine atom, an iodine atom, and the like, and a fluorine atom is preferable.

Examples of the halogenated alkyl group serving as the substituent described above include a group in which part or all of the hydrogen atoms in the above alkyl group are substituted with the halogen atoms described above.

Examples of the halogenated alkyl group serving as the substituent described above include a group in which part or all of the hydrogen atoms in the alkyl group described as the alkyl group serving as the above substituent are substituted with the halogen atoms described above. As the halogenated alkyl group described above, a fluorinated alkyl group is preferable, and a perfluoroalkyl group is particularly preferable.

R″s in the —COOR″ and —OC(═O)R″ described above are either a hydrogen atom or a linear, branched or cyclic alkyl group having 1 or more and 15 or less carbon atoms.

When R″ is a linear or branched alkyl group, the number of carbon atoms in the chain alkyl group described above is preferably 1 or more and 10 or less, more preferably 1 or more and 5 or less and particularly preferably 1 or 2.

When R″ is a cyclic alkyl group, the number of carbon atoms in the cyclic alkyl group described above is preferably 3 or more and 15 or less, more preferably 4 or more and 12 or less, and particularly preferably 5 or more and 10 or less. Specific examples can include a group in which one or more hydrogen atoms are removed from monocycloalkane, or polycycloalkane such as bicycloalkane, tricycloalkane or tetracycloalkane that may be substituted with a fluorine atom or a fluorinated alkyl group. More specific examples include a group in which one or more hydrogen atoms are removed from monocycloalkane such as cyclopentane or cyclohexane, or polycycloalkane such as adamantane, norbornane, isobornane, tricyclodecane or tetracyclododecane.

As a hydroxyalkyl group serving as the substituent described above, a hydroxyalkyl group which has 1 or more and 6 or less carbon atoms is preferable. Specific examples include a group in which at least one of the hydrogen atoms in the alkyl group described as an alkyl group serving as the above substituent is substituted with a hydroxyl group.

More specific examples of the —SO₂-containing cyclic group include groups represented by the following formulae (3-1) to (3-4):

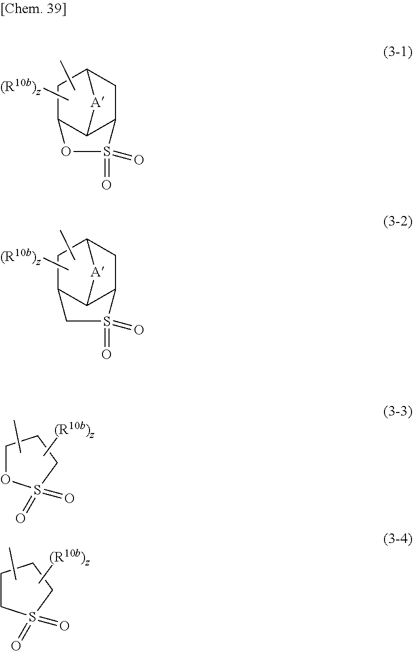

(in the formulae, A′ represents an alkylene group having 1 or more and 5 or less carbon atoms optionally including an oxygen atom or a sulfur atom, an oxygen atom or a sulfur atom; z represents an integer of 0 or more and 2 or less; R^{10b} represents an alkyl group, an alkoxy group, a halogenated alkyl group, a hydroxyl group, —COOR″, —OC(═O)R″, a hydroxyalkyl group or a cyano group; and R″ represents a hydrogen atom or an alkyl group).

In the above formulae (3-1) to (3-4), A′ represents an alkylene group having 1 or more and 5 or less carbon atoms optionally including an oxygen atom (—O—) or a sulfur atom (—S—), an oxygen atom or a sulfur atom. As an alkylene group having 1 or more and 5 or less carbon atoms in A′, a linear or branched alkylene group is preferable, and examples thereof include a methylene group, an ethylene group, an n-propylene group, an isopropylene group, and the like.

When the alkylene group described above includes an oxygen atom or a sulfur atom, specific examples thereof include a group in which —O— or —S— is present at a terminal or between carbon atoms of the above alkylene group, and examples thereof include —O—CH₂—, —CH₂—O—CH₂—, —S—CH₂—, —CH₂—S—CH₂—, and the like. As A′, an alkylene group having 1 or more and 5 or less carbon atoms or —O— is preferable, an alkylene group having 1 or more and 5 or less carbon atoms is more preferable and a methylene group is most preferable.

z may be any of 0, 1 and 2, and is most preferably 0. When z is 2, a plurality of R^{10b}s may be the same as or different from each other.

Examples of the alkyl group, the alkoxy group, the halogenated alkyl group, —COOR″, —OC(═O)R″ and the hydroxyalkyl group in R^{10b} include groups similar to those described on the alkyl group, the alkoxy group, the halogenated alkyl group, —COOR″, —OC(═O)R″ and the hydroxyalkyl group, each of which is mentioned as a substituent optionally contained in the —SO₂-containing cyclic group.

Specific cyclic groups represented by the above formulae (3-1) to (3-4) will be illustrated below.

“Ac” in the formulae represents an acetyl group.

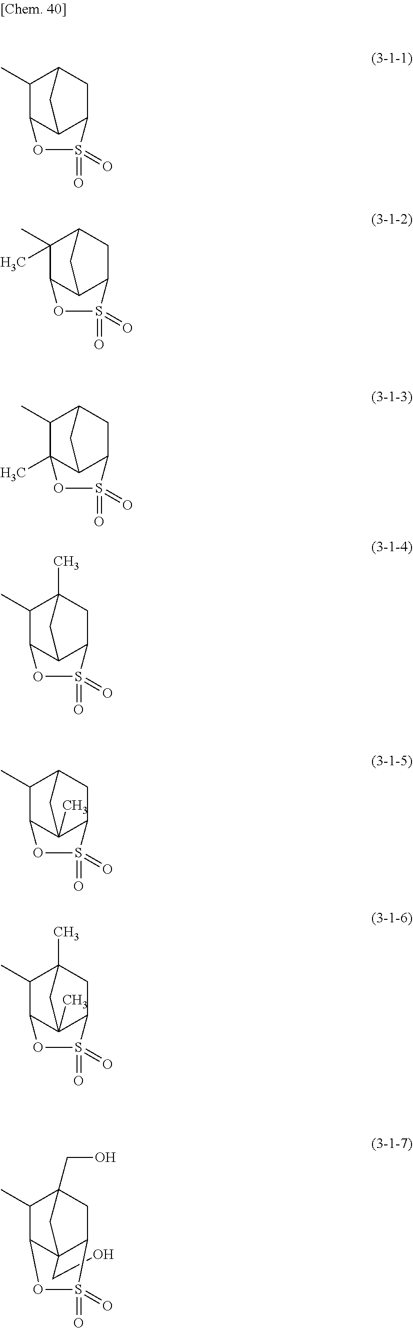

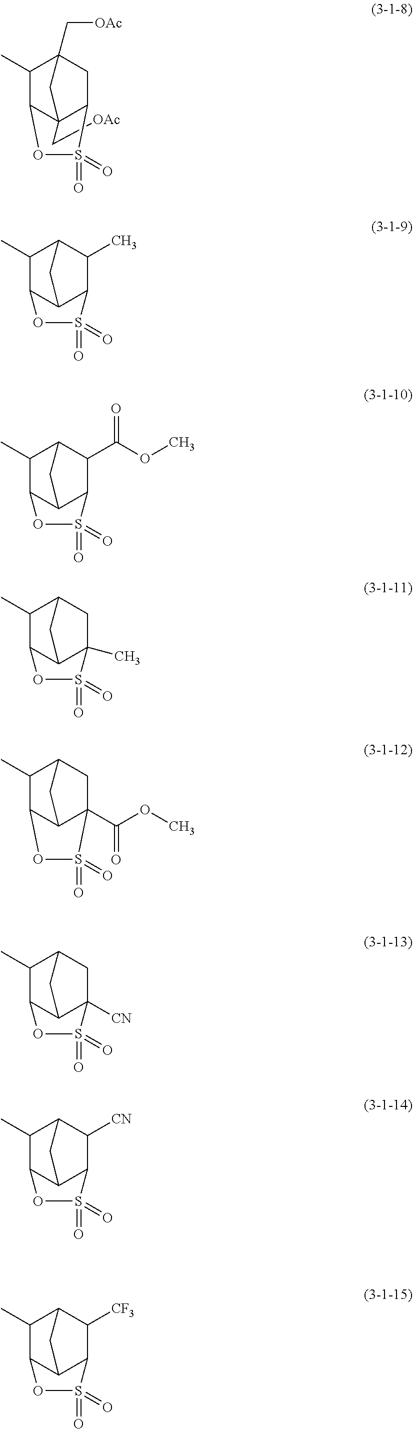

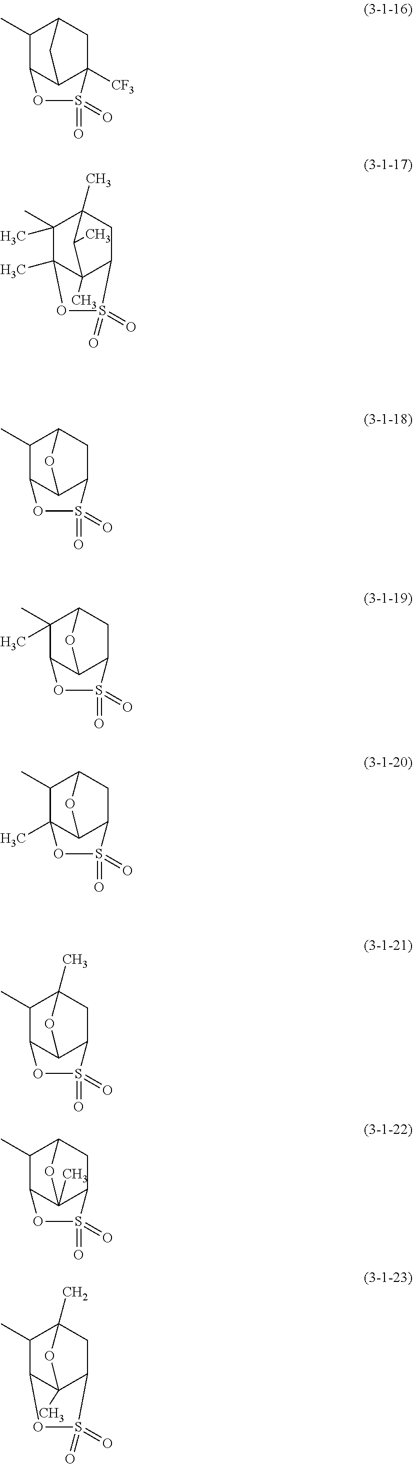

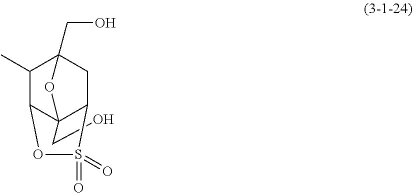 [SMILES: CC1C2OS(=O)(=O)C3CC1(CO)OC23CO]

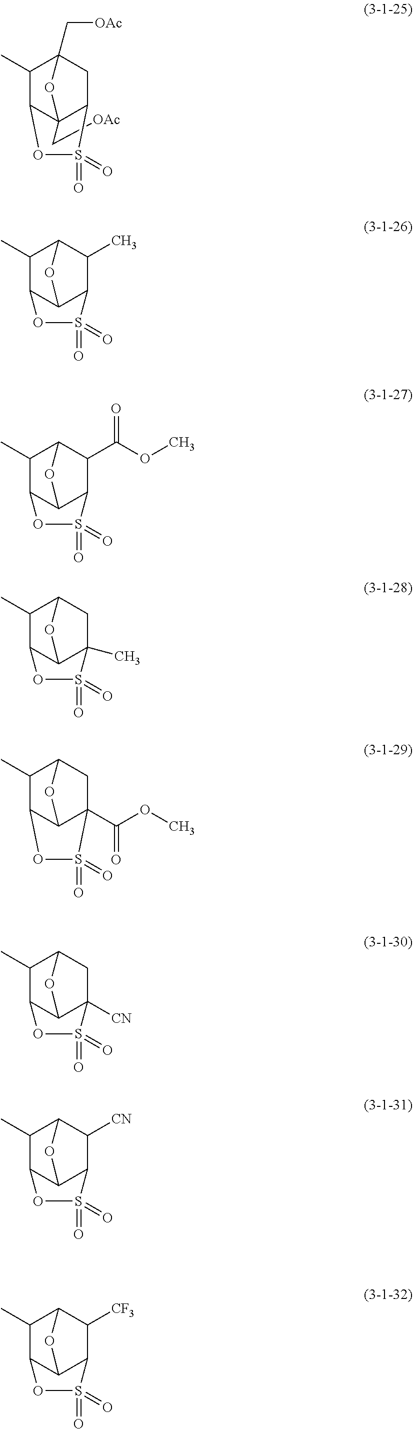

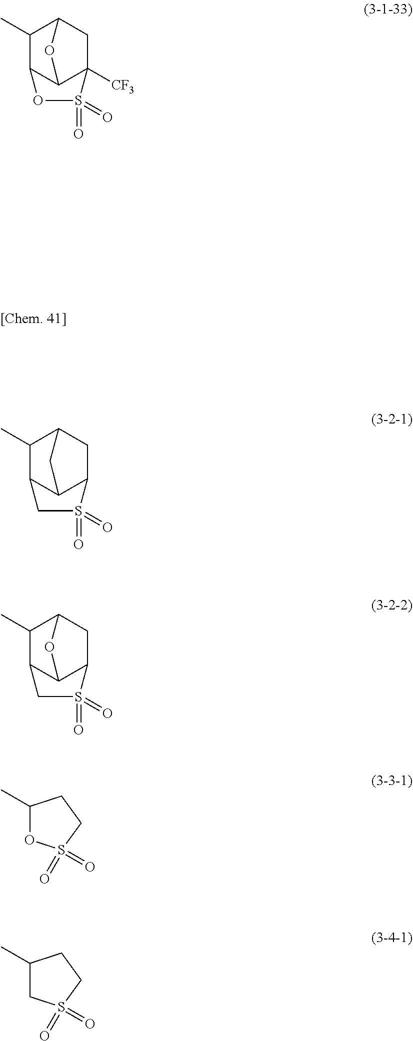

As the —SO₂-containing cyclic group, among those shown above, a group represented by the above formula (3-1) is preferable, and at least one type selected from the group consisting of the groups represented by any of the above formulae (3-1-1), (3-1-18), (3-3-1) and (3-4-1) is more preferable and a group represented by the above formula (3-1-1) is most preferable.

### (Lactone-Containing Cyclic Group)

The “lactone-containing cyclic group” refers to a cyclic group which contains a ring (lactone ring) including —O—C(═O)— in the ring skeleton thereof. With the assumption that the lactone ring is the first ring, a group which has the lactone ring alone is called a monocyclic group, and a group that has further ring structures is called a polycyclic group regardless of its structure. The lactone-containing cyclic group may be a monocyclic group or a polycyclic group.

There is no particular limitation on the lactone cyclic group in the constituent unit (b-3), and any cyclic group can be used. Specific examples of the lactone-containing monocyclic group include a group in which one hydrogen atom is removed from a 4- to 6-membered ring lactone, for example, a group in which one hydrogen atom is removed from β-propionolactone, a group in which one hydrogen atom is removed from γ-butyrolactone, a group in which one hydrogen atom is removed from δ-valerolactone, and the like. Further examples of the lactone-containing polycyclic group include groups having a lactone ring in which one hydrogen atom is removed from bicycloalkane, tricycloalkane and tetracycloalkane.

As long as the constituent unit (b-3) has an —SO₂-containing cyclic group or a lactone-containing cyclic group, the structures of other parts are not particularly limited. A preferred constituent unit (b-3) is at least one type of constituent unit selected from the group consisting of a constituent unit (b-3-S) derived from an acrylic acid ester and including an —SO₂-containing cyclic group in which a hydrogen atom bonded to the carbon atom in the α position may be substituted with a substituent; and a constituent unit (b-3-L) derived from an acrylic acid ester and including a lactone-containing cyclic group in which the hydrogen atom bonded to the carbon atom in the α position may be substituted with a substituent.

[Constituent Unit (b-3-S)]

More specifically, examples of the constituent unit (b-3-S) include a constituent unit represented by the following formula (b-S1):

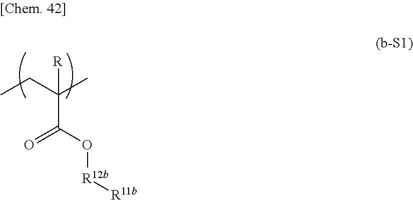

(in the formula, R represents a hydrogen atom, an alkyl group having 1 or more and 5 or less carbon atoms or a halogenated alkyl group having 1 or more and 5 or less carbon atoms; R^{11b} represents an —SO₂-containing cyclic group; and R^{12b} represents a single bond or a divalent linking group).

In the formula (b-S1), R is the same as described above. R^{11b} is the same as in the —SO₂-containing cyclic group described above. R^{12b} may be either a single bond or a divalent linking group.

There is no particular limitation on the divalent linking group in R^{12b}, and preferred groups include an optionally substituted divalent hydrocarbon group, a divalent linking group including a heteroatom, and the like.

Optionally Substituted Divalent Hydrocarbon Group

The hydrocarbon group serving as a divalent linking group may be an aliphatic hydrocarbon group or an aromatic hydrocarbon group. The aliphatic hydrocarbon group means a hydrocarbon group without aromaticity. The aliphatic hydrocarbon group described above may be saturated or unsaturated. In general, a saturated hydrocarbon group is preferable. More specifically, examples of the aliphatic hydrocarbon group described above include a linear or branched aliphatic hydrocarbon group, an aliphatic hydrocarbon group including a ring in the structure thereof, and the like.

The number of carbon atoms in the linear or branched aliphatic hydrocarbon group is preferably 1 or more and 10 or less, more preferably 1 or more and 8 or less and further preferably 1 or more and 5 or less.

As the linear aliphatic hydrocarbon group, a linear alkylene group is preferable. Specific examples include a methylene group [—CH₂—], an ethylene group [—(CH₂)₂—], a trimethylene group [—(CH₂)₃—], a tetramethylene group [—(CH₂)₄—], a pentamethylene group [—(CH₂)₅—], and the like.

As the branched aliphatic hydrocarbon group, a branched alkylene group is preferable. Specific examples include alkyl alkylene groups such as: alkyl methylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; alkyl ethylene groups such as —CH(CH₃)CH₂—, —CH(CH₃)CH(CH₃)—, —C(CH₃)₂CH₂—, —CH(CH₂CH₃)CH₂— and —C(CH₂CH₃)₂—CH₂—; alkyl trimethylene groups such as —CH(CH₃)CH₂CH₂— and —CH₂CH(CH₃)CH₂—; alkyl tetramethylene groups such as —CH(CH₃)CH₂CH₂CH₂— and —CH₂CH(CH₃)CH₂CH₂—; and the like. As an alkyl group in the alkyl alkylene group, a linear alkyl group having 1 or more and 5 or less carbon atoms is preferable.

The linear or branched aliphatic hydrocarbon group described above may or may not have a substituent (a group or atom other than a hydrogen atom) which substitutes a hydrogen atom. Examples of the substituent include a fluorine atom, a fluorinated alkyl group having 1 or more and 5 or less carbon atoms substituted with a fluorine atom, an oxo group (═O), and the like.

Examples of the aliphatic hydrocarbon group including a ring in the structure thereof include: a cyclic aliphatic hydrocarbon group optionally including a heteroatom in the ring structure (a group in which two hydrogen atoms are removed from an aliphatic hydrocarbon ring); a group in which the above cyclic aliphatic hydrocarbon group is bonded to an end of a linear or branched aliphatic hydrocarbon group; a group in which the above cyclic aliphatic hydrocarbon group is present partway through a linear or branched aliphatic hydrocarbon group; and the like. Examples of the linear or branched aliphatic hydrocarbon group described above include the same groups as described above.

The number of carbon atoms in the cyclic aliphatic hydrocarbon group is preferably 3 or more and 20 or less and more preferably 3 or more and 12 or less.

The cyclic aliphatic hydrocarbon group may be polycyclic or monocyclic. As the monocyclic aliphatic hydrocarbon group, a group in which two hydrogen atoms are removed from monocycloalkane is preferable. The number of carbon atoms in the monocycloalkane described above is preferably 3 or more and 6 or less. Specific examples include cyclopentane, cyclohexane, and the like. As the polycyclic aliphatic hydrocarbon group, a group in which two hydrogen atoms are removed from polycycloalkane is preferable. The number of carbon atoms in the polycycloalkane described above is preferably 7 or more and 12 or less. Specific examples include adamantane, norbornane, isobornane, tricyclodecane, tetracyclododecane, and the like.

The cyclic aliphatic hydrocarbon group may or may not have a substituent which substitutes a hydrogen atom (a group or atom other than a hydrogen atom). Examples of the substituent described above include an alkyl group, an alkoxy group, a halogen atom, a halogenated alkyl group, a hydroxyl group, an oxo group (═O), and the like.

As an alkyl group serving as the substituent described above, an alkyl group having 1 or more and 5 or less carbon atoms is preferable, and a methyl group, an ethyl group, a propyl group, an n-butyl group and a tert-butyl group are more preferable.

As an alkoxy group serving as the substituent described above, an alkoxy group having 1 or more and 5 or less carbon atoms is preferable, a methoxy group, an ethoxy group, an n-propoxy group, an iso-propoxy group, an n-butoxy group and a tert-butoxy group are more preferable and a methoxy group and an ethoxy group are particularly preferable.

Examples of halogen atom serving as the substituent described above include a fluorine atom, a chlorine atom, a bromine atom, an iodine atom, and the like, and a fluorine atom is preferable.

Examples of halogenated alkyl group serving as the substituent described above include a group in which part or all of hydrogen atoms in the alkyl group described above are substituted with the halogen atoms described above.

In the cyclic aliphatic hydrocarbon group, part of carbon atoms constituting the ring structure thereof may be substituted with —O— or —S—. As the substituent including the heteroatom described above, —O—, —C(═O)—O—, —S—, —S(═O)₂— and —S(═O)₂—O— are preferable.

The aromatic hydrocarbon group serving as the divalent hydrocarbon group is a divalent hydrocarbon group having at least one aromatic ring, and may have a substituent. There is no particular limitation on the aromatic ring as long as it is a cyclic conjugated system having 4n+2 π electrons, and it may be monocyclic or polycyclic. The number of carbon atoms in the aromatic ring is preferably 5 or more and 30 or less, more preferably 5 or more and 20 or less, further preferably 6 or more and 15 or less and particularly preferably 6 or more and 12 or less. However, it is assumed that the number of carbon atoms described above does not include the number of carbon atoms in the substituent.

Specific examples of the aromatic ring include: aromatic hydrocarbon rings such as benzene, naphthalene, anthracene and phenanthrene; and aromatic heterocycles in which part of the carbon atoms constituting the above aromatic hydrocarbon ring are substituted with heteroatoms. Examples of the heteroatom in the aromatic heterocycle include an oxygen atom, a sulfur atom, a nitrogen atom, and the like. Specific examples of the aromatic heterocycle include a pyridine ring, a thiophene ring, and the like.

Specific examples of the aromatic hydrocarbon group serving as a divalent hydrocarbon group include: a group in which two hydrogen atoms are removed from the aromatic hydrocarbon ring or the aromatic heterocycle described above (an arylene group or a heteroarylene group); a group in which two hydrogen atoms are removed from an aromatic compound including two or more aromatic rings (for example, biphenyl, fluorene, and the like); a group in which one hydrogen atom from a group where one hydrogen atom is removed from the aromatic hydrocarbon ring or the aromatic heterocycle described above (an aryl group or a heteroaryl group) is substituted with an alkylene group (for example, a group in which one hydrogen atom is further removed from an aryl group in an arylalkyl group such as a benzyl group, a phenethyl group, a 1-naphthylmethyl group, a 2-naphthylmethyl group, a 1-naphthylethyl group and a 2-naphthylethyl group); and the like.

The number of carbon atoms in the alkylene group bonded to the aryl group or the heteroaryl group described above is preferably 1 or more and 4 or less, more preferably 1 or more and 2 or less and particularly preferably 1.

In the aromatic hydrocarbon group described above, the hydrogen atom included in the aromatic hydrocarbon group may be substituted with a substituent. For example, a hydrogen atom bonded to an aromatic ring in the aromatic hydrocarbon group described above may be substituted with a substituent. Examples of the substituent include an alkyl group, an alkoxy group, a halogen atom, a halogenated alkyl group, a hydroxyl group, an oxo group (═O), and the like.

As an alkyl group serving as the substituent described above, an alkyl group having 1 or more and 5 or less carbon atoms is preferable, and a methyl group, an ethyl group, an n-propyl group, an n-butyl group and a tert-butyl group are more preferable.

As an alkoxy group serving as the substituent described above, an alkoxy group having 1 or more and 5 or less carbon atoms is preferable; a methoxy group, an ethoxy group, an n-propoxy group, an iso-propoxy group, an n-butoxy group and a tert-butoxy group are preferable; and a methoxy group and an ethoxy group are more preferable.

Examples of the halogen atom serving as the substituent described above include a fluorine atom, a chlorine atom, a bromine atom, an iodine atom, and the like, and a fluorine atom is preferable.

Examples of the halogenated alkyl group serving as the substituent described above include a group in which part or all of hydrogen atoms in the alkyl group described above are substituted with the halogen atoms described above.

Divalent Linking Group Including a Heteroatom

A heteroatom in the divalent linking group including a heteroatom is an atom other than a carbon atom and a hydrogen atom, and examples thereof include an oxygen atom, a nitrogen atom, a sulfur atom, a halogen atom, and the like.

Specific examples of the divalent linking group including a heteroatom include non-hydrocarbon based linking groups such as —O—, —C(═O)—, —C(═O)—O—, —O—C(═O)—O—, —S—, —S(═O)₂—, —S(═O)₂—O—, —NH—, —NH—C(═O)—, —NH—C(═NH)— and ═N—, combinations of at least one type of these non-hydrocarbon based linking groups and a divalent hydrocarbon group, and the like. Examples of the divalent hydrocarbon group described above include groups similar to the above divalent hydrocarbon groups optionally having a substituent, and linear or branched aliphatic hydrocarbon groups are preferable.

Among those described above, —NH— in —C(═O)—NH— and H in —NH— and —NH—C(═NH)— each may be substituted with a substituent such as an alkyl group or an acyl group. The number of carbon atoms in the substituent described above is preferably 1 or more and 10 or less, more preferably 1 or more and 8 or less and particularly preferably 1 or more and 5 or less.

As a divalent linking group in R^{12b}, a linear or branched alkylene group, a cyclic aliphatic hydrocarbon group or a divalent linking group including a heteroatom is particularly preferable.

When the divalent linking group in R^{12b} is a linear or branched alkylene group, the number of carbon atoms in the alkylene group described above is preferably 1 or more and 10 or less, more preferably 1 or more and 6 or less, particularly preferably 1 or more and 4 or less and most preferably 1 or more and 3 or less. Specific examples include groups similar to the linear alkylene groups or branched alkylene groups described as linear or branched aliphatic hydrocarbon groups in the description of the “divalent hydrocarbon group optionally having a substituent” serving as the divalent linking group described above.

When the divalent linking group in R^{12b} is a cyclic aliphatic hydrocarbon group, examples of the cyclic aliphatic hydrocarbon group described above include groups similar to cyclic aliphatic hydrocarbon groups described as the “aliphatic hydrocarbon group including a ring in the structure” in the description of the “divalent hydrocarbon group optionally having a substituent” serving as the divalent linking group described above.

As the cyclic aliphatic hydrocarbon group described above, a group in which two or more hydrogen atoms are removed from cyclopentane, cyclohexane, norbornane, isobornane, adamantane, tricyclodecane or tetracyclododecane, is particularly preferable.

When the divalent linking group in R^{12b} is a divalent linking group including a heteroatom, examples of a group preferred as the linking group described above include —O—, —C(═O)—O—, —C(═O)—, —O—C(═O)—O—, —C(═O)—NH—, —NH— (H may be substituted with a substituent such as an alkyl group or an acyl group), —S—, —S(═O)₂—, —S(═O)₂—O—, a group represented by a general formula of —Y¹—O—Y²—, —[Y¹—C(═O)—O]_{m′}—Y²— or —Y¹—O—C(═O)—Y₂— [where Y¹ and Y² are each independently divalent hydrocarbon groups optionally having a substituent, O represents an oxygen atom and m′ is an integer of 0 or more and 3 or less], and the like.

When the divalent linking group in R^{12b} is —NH—, the hydrogen atom in —NH— may be substituted with a substituent such as an alkyl group or an acyl group. The number of carbon atoms in the substituent described above (such as an alkyl group or an acyl group) is preferably 1 or more and 10 or less, more preferably 1 or more and 8 or less and particularly preferably 1 or more and 5 or less.

Y¹ and Y² in the formula of Y¹—O—Y²—, —[Y¹—C(═O)—O]_{m′}—Y²— or —Y¹—O—C(═O)—Y²— are each independently divalent hydrocarbon groups optionally having a substituent. Examples of the divalent hydrocarbon group described above include groups similar to the “divalent hydrocarbon group optionally having a substituent” described in the above description of the divalent linking group.

As Y¹, a linear aliphatic hydrocarbon group is preferable, a linear alkylene group is more preferable, a linear alkylene group having 1 or more and 5 or less carbon atoms is more preferable and a methylene group and an ethylene group are particularly preferable.

As Y², a linear or branched aliphatic hydrocarbon group is preferable, and a methylene group, an ethylene group and an alkylmethylene group are more preferable. The alkyl group in the alkylmethylene group described above is preferably a linear alkyl group having 1 or more and 5 or less carbon atoms, more preferably a linear alkyl group having 1 or more and 3 or less carbon atoms, and particularly preferably a methyl group.

In a group represented by the formula of —[Y¹—C(═O)—O]_{m′}—Y²—, m′ is an integer of 0 or more and 3 or less, preferably an integer of 0 or more and 2 or less, more preferably 0 or 1, and particularly preferably 1. In other words, as a group represented by the formula of —[Y¹—C(═O)—O]_{m′}—Y²—, a group represented by the formula of —Y¹—C(═O)—O—Y²— is particularly preferable. Among these, a group represented by the formula of —(CH₂)_{a′}—C(═O)—O—(CH₂)_{b′}— is preferable. In the above formula, a′ is an integer of 1 or more and 10 or less, preferably an integer of 1 or more and 8 or less, more preferably an integer of 1 or more and 5 or less, further preferably 1 or 2, and most preferably 1. b′ is an integer of 1 or more and 10 or less, preferably an integer of 1 or more and 8 or less, more preferably an integer of 1 or more and 5 or less, further preferably 1 or 2, and most preferably 1.

With respect to the divalent linking group in R^{12b}, an organic group including a combination of at least one non-hydrocarbon group and a divalent hydrocarbon group is preferable as the divalent linking group including a heteroatom. Among these, a linear chain group having an oxygen atom as a heteroatom, for example, a group including an ether bond or an ester bond is preferable, a group represented by the above formula of —Y¹—O—Y²—, —[Y¹—C(═O)—O]_{m′}—Y²— or —Y¹—O—C(═O)—Y²— is more preferable, and a group represented by the above formula of —[Y¹—C(═O)—O]_{m′}—Y²— or —Y¹—O—C(═O)—Y²— is particularly preferable.

As the divalent linking group in R^{12b}, a group including an alkylene group or an ester bond (—C(═O)—O—) is preferable.

The alkylene group described above is preferably a linear or branched alkylene group. Preferred examples of the linear aliphatic hydrocarbon group described above include a methylene group [—CH₂—], an ethylene group [—(CH₂)₂—], a trimethylene group [—(CH₂)₃—], a tetramethylene group [—(CH₂)₄—], a pentamethylene group [—(CH₂)₅—], and the like. Preferred examples of the branched alkylene group described above include alkyl alkylene groups such as: alkyl methylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; alkyl ethylene groups such as —CH(CH₃)CH₂—, —CH(CH₃)CH(CH₃)—, —C(CH₃)₂CH₂—, —CH(CH₂CH₃)CH₂— and —C(CH₂CH₃)₂—CH₂—; alkyl trimethylene groups such as —CH(CH₃)CH₂CH₂— and —CH₂CH(CH₃)CH₂—; and alkyl tetramethylene groups such as —CH(CH₃)CH₂CH₂CH₂— and —CH₂CH(CH₃)CH₂CH₂—.

As the divalent linking group including an ester bond, a group represented by the formula of —R^{13b}—C(═O)—O— [where R^{13b} represents a divalent linking group] is particularly preferable. In other words, the constituent unit (b-3-S) is preferably a constituent unit represented by the following formula (b-S1-1):

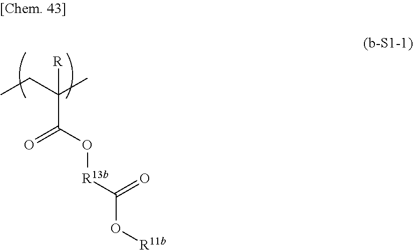

(in the formula, R and R^{11b} each are similar to those described above, and R^{13b} represents a divalent linking group).

There is no particular limitation on R^{13b}, and examples thereof include groups similar to the divalent linking group in R^{12b} described above. As the divalent linking group in R^{13b}, a linear or branched alkylene group, an aliphatic hydrocarbon group including a ring in the structure or a divalent linking group including a heteroatom is preferable, and a linear or branched alkylene group or a divalent linking group including an oxygen atom as a heteroatom is preferable.

As the linear alkylene group, a methylene group or an ethylene group is preferable, and a methylene group is particularly preferable. As the branched alkylene group, an alkylmethylene group or an alkylethylene group is preferable, and —CH(CH₃)—, —C(CH₃)₂— or —C(CH₃)₂CH₂— is particularly preferable.

As the divalent linking group including an oxygen atom, a divalent linking group including an ether bond or an ester bond is preferable, and —Y¹—O—Y²—, —[Y¹—C(═O)—O]_{m′}—Y²—, or —Y¹—O—C(═O)—Y²— described above is more preferable. Y¹ and Y² are each independently divalent hydrocarbon groups optionally having a substituent, and m′ is an integer of 0 or more and 3 or less. Among these, —Y¹—O—C(═O)—Y²— is preferable, and a group represented by —(CH₂)_{c}—O—C(═O)—(CH₂)_{d}— is particularly preferable. c is an integer of 1 or more and 5 or less, and preferably an integer of 1 or 2. d is an integer of 1 or more and 5 or less, and preferably an integer of 1 or 2.

As the constituent unit (b-3-S), in particular, a constituent unit represented by the following formula (b-S1-11) or (b-S1-12) is preferable, and the constituent unit represented by the formula (b-S1-12) is more preferable:

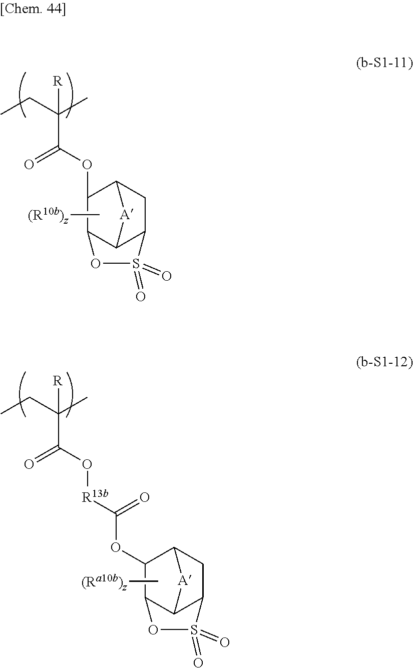

(in the formulae, R, A′, R^{10b}, z and R^{13b} each are the same as described above).

In the formula (b-S1-11), A′ is preferably a methylene group, an oxygen atom (—O—) or a sulfur atom (—S—).

As R^{13b}, a linear or branched alkylene group or a divalent linking group including an oxygen atom is preferable. Examples of the linear or branched alkylene group and the divalent linking group including an oxygen atom in R^{13b} include groups similar to the linear or branched alkylene group described above and the divalent linking group including an oxygen atom described above.

As the constituent unit represented by the formula (b-S1-12), in particular, a constituent unit represented by the following formula (b-S1-12a) or (b-S1-12b) is preferable:

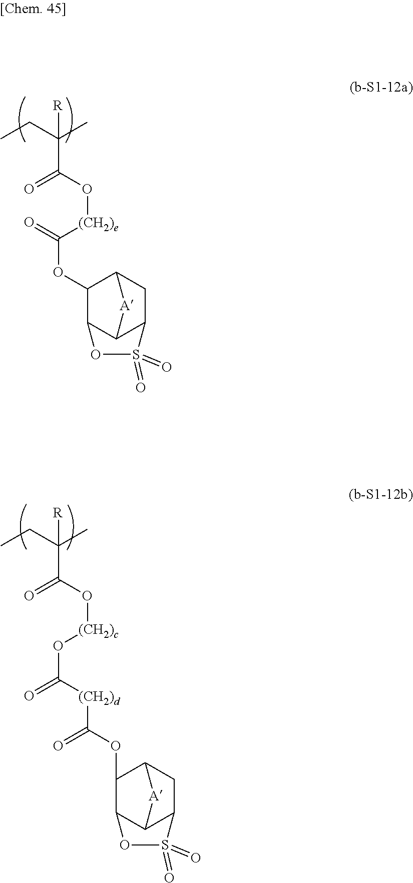

(in the formulae, R and A′ each are the same as described above, and c to e are each independently an integer of 1 or more and 3 or less).
[Constituent Unit (b-3-L)]

Examples of the constituent unit (b-3-L) include a constituent unit in which R^{11b} in the above formula (b-S1) is substituted with a lactone-containing cyclic group, and more specific examples include units represented by the following formulae (b-L1) to (b-L5):

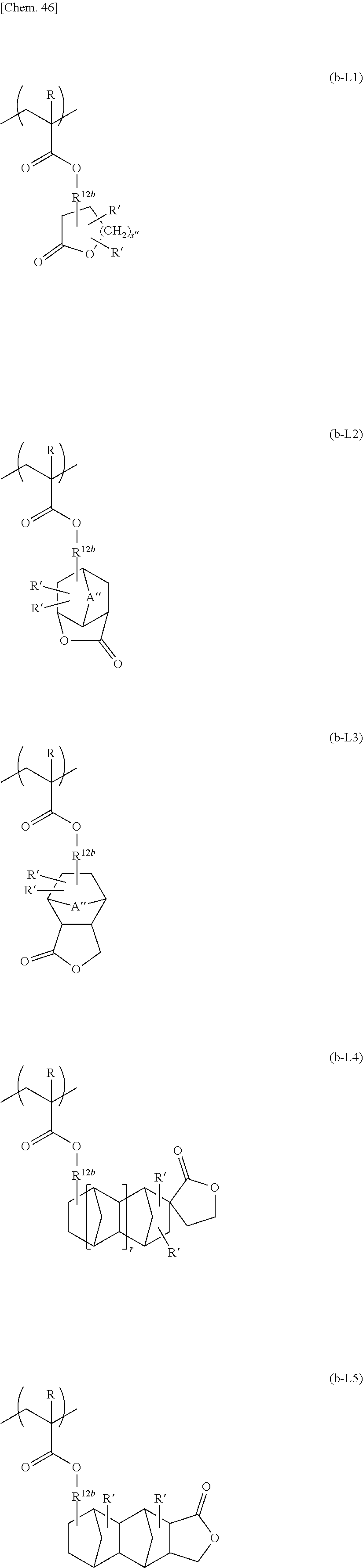

(in the formulae, R represents a hydrogen atom, an alkyl group having 1 or more and 5 or less carbon atoms or a halogenated alkyl group having 1 or more and 5 or less carbon atoms; R′ each independently represents a hydrogen atom, an alkyl group, an alkoxy group, a halogenated alkyl group, a hydroxyl group, —COOR″, —OC(═O)R″, a hydroxyalkyl group or a cyano group; R″ represents a hydrogen atom or an alkyl group; R^{12b} represents a single bond or divalent linking group; s″ is an integer of 0 or more and 2 or less; A″ represents an alkylene group having 1 or more and 5 or less carbon atoms and optionally including an oxygen atom or a sulfur atom, an oxygen atom or a sulfur atom; and r represents 0 or 1).

R in the formulae (b-L1) to (b-L5) is the same as described above. Examples of the alkyl group, the alkoxy group, the halogenated alkyl group, —COOR″, —OC(═O)R″ and the hydroxyalkyl group in R′ include groups similar to those described in the alkyl group, the alkoxy group, the halogenated alkyl group, —COOR″, —OC(═O)R″ and the hydroxyalkyl group each of which is mentioned as a substituent optionally contained in the —SO₂-containing cyclic group.

R′ is preferably a hydrogen atom with consideration given to ease of industrial availability and the like. The alkyl group in R″ may be any of linear, branched and cyclic chains. When R″ is a linear or branched alkyl group, the number of carbon atoms is preferably 1 or more and 10 or less and more preferably 1 or more and 5 or less. When R″ is a cyclic alkyl group, the number of carbon atoms is preferably 3 or more and 15 or less, more preferably 4 or more and 12 or less, and most preferably 5 or more and 10 or less. Specifically, groups can be illustrated in which one or more hydrogen atoms are removed from monocycloalkane and polycycloalkane, such as bicycloalkane, tricycloalkane, tetracycloalkane, and the like; optionally substituted with a fluorine atom or a fluorinated alkyl group. Specific examples include groups in which one or more hydrogen atoms are removed from monocycloalkane such as cyclopentane and cyclohexane, and polycycloalkane such as adamantane, norbornane, isobornane, tricyclodecane and tetracyclododecane, and the like. Examples of A″ include those similar to A′ in the above formula (3-1). A″ is preferably an alkylene group having 1 to 5 carbon atoms, an oxygen atom (—O—) or a sulfur atom (—S—), and more preferably an alkylene group having 1 or more and 5 or less carbon atoms or —O—. As the alkylene group having 1 or more and 5 or less carbon atoms, a methylene group or a dimethylmethylene group is more preferable, and a methylene group is most preferable.

R^{12b} is similar to R^{12b} in the above formula (b-S1). In the formula (b-L1), s″ is preferably 1 or 2. Specific examples of the constituent units represented by the above formulae (b-L1) to (b-L3) will be described below. In each of the following formulae, R^{α} represents a hydrogen atom, a methyl group, or a trifluoromethyl group.

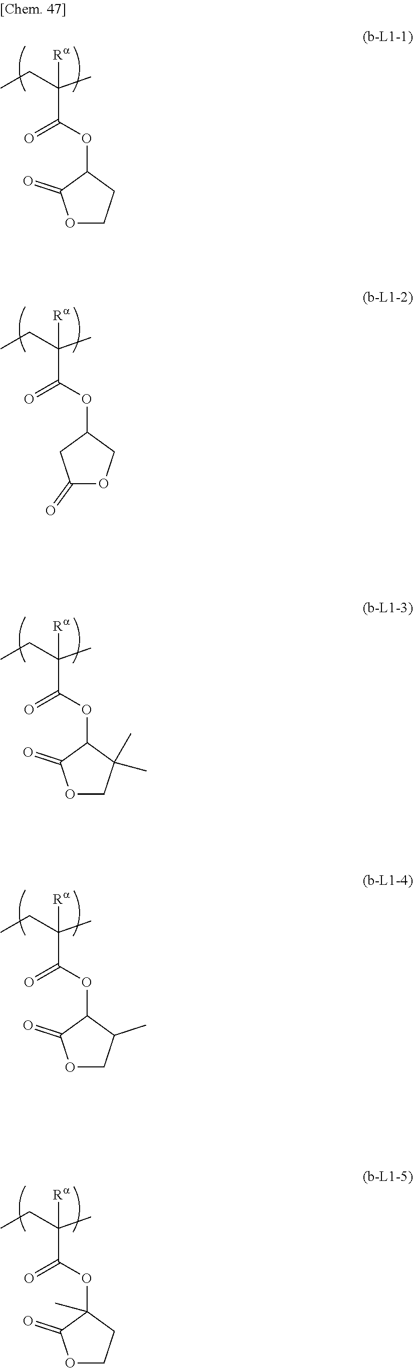

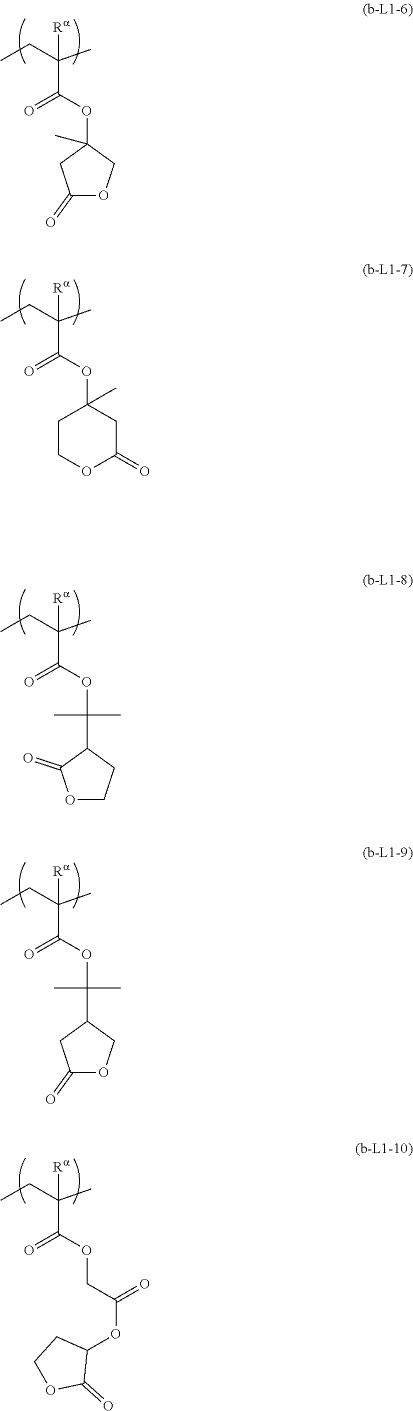

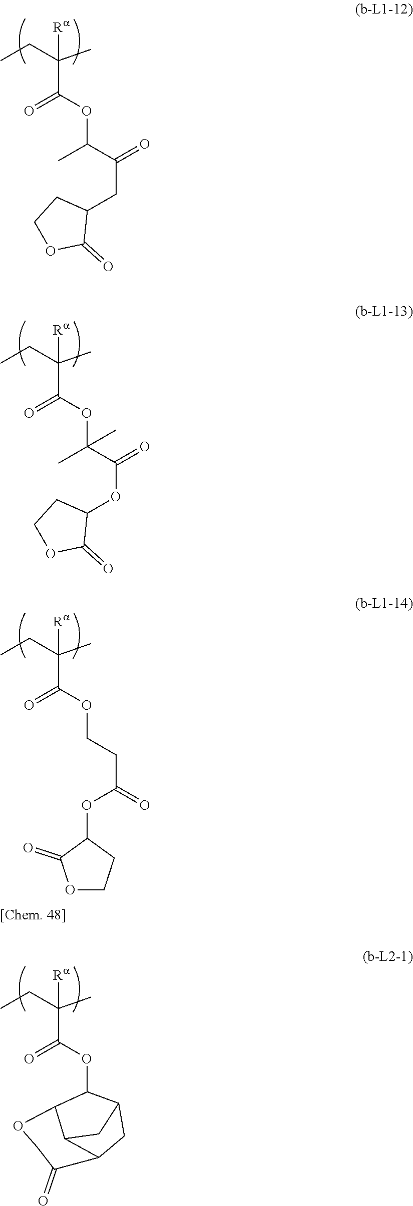

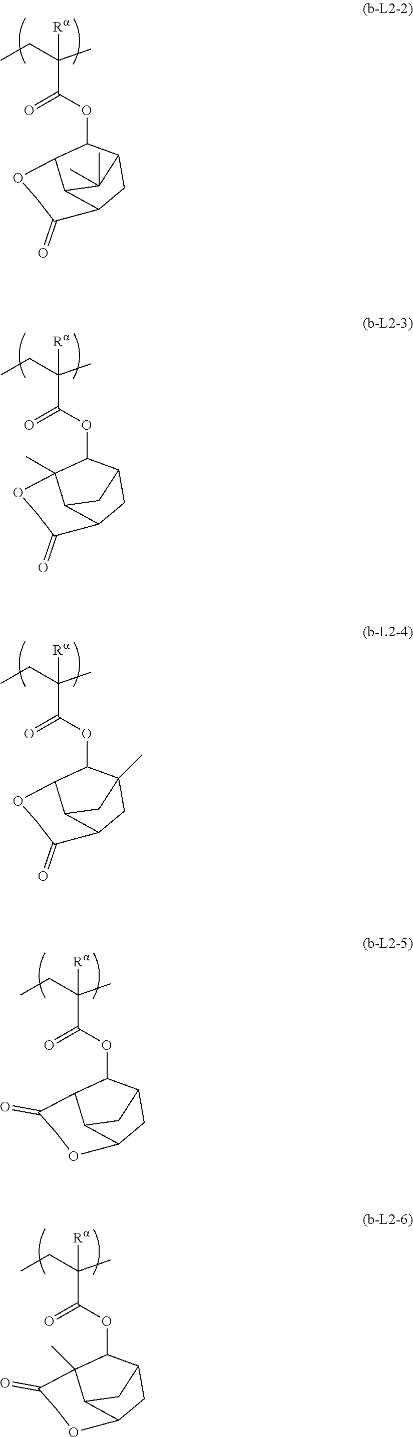

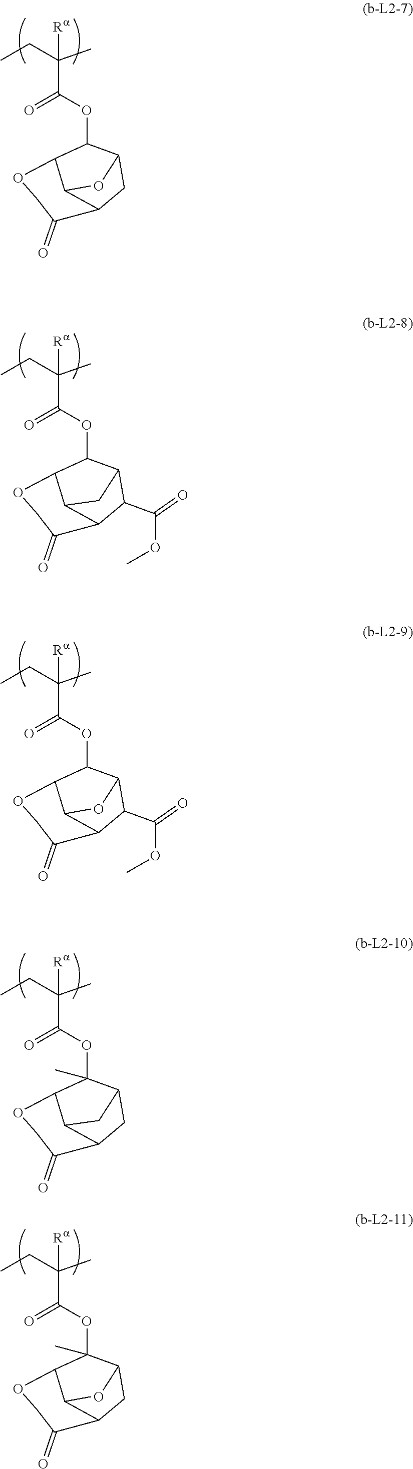

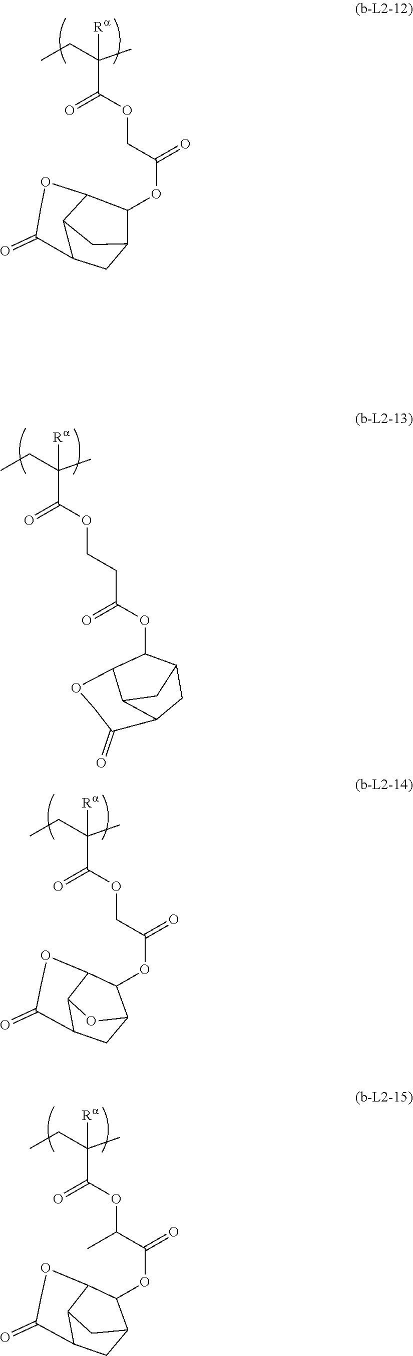

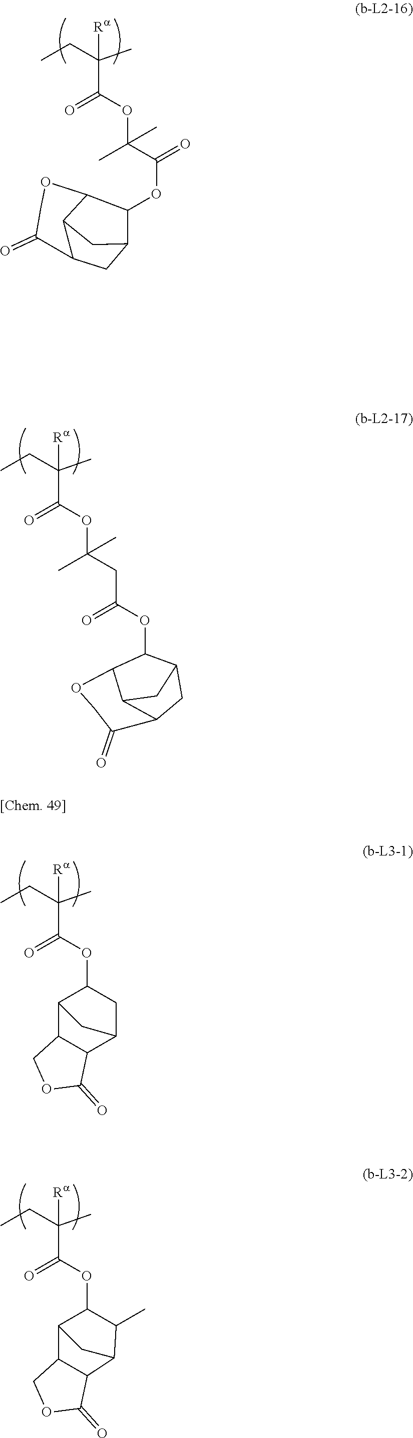

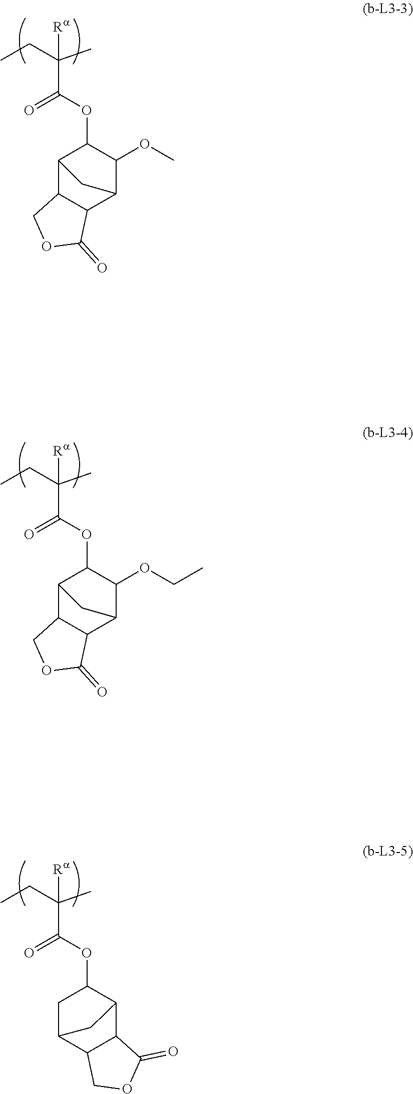

As the constituent unit (b-3-L), at least one type selected from the group consisting of the constituent units represented by the above formulae (b-L1) to (b-L5) is preferable, at least one type selected from the group consisting of the constituent units represented by the above formulae (b-L1) to (b-L3) is more preferable and at least one type selected from the group consisting of the constituent units represented by the above formula (b-L1) or (b-L3) is particularly preferable. Among these, at least one type selected from the group consisting of the constituent units represented by the above formulae (b-L1-1), (b-L1-2), (b-L2-1), (b-L2-7), (b-L2-12), (b-L2-14), (b-L3-1) and (b-L3-5) is preferable.

As the constituent unit (b-3-L), the constituent units represented by following formulae (b-L6) to (b-L7) are also preferable:

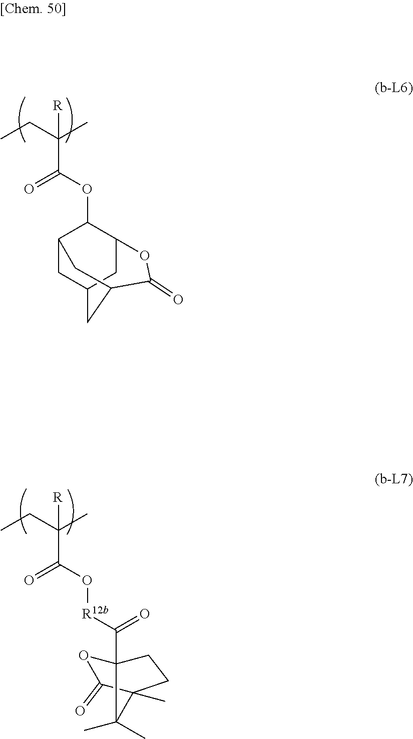

In the formulae (b-L6) and (b-L7), R and R^{12b} are the same as described above.

The acrylic resin (B3) includes constituent units having an acid dissociable group and represented by the following formulae (b5) to (b7) as constituent units which enhance the solubility of the acrylic resin (B3) in an alkali under action of acid.

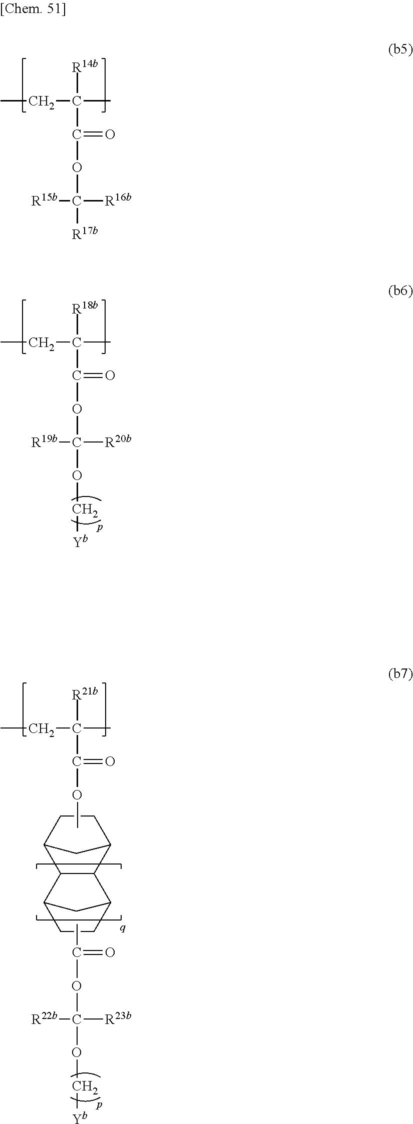

In the above formulae (b5) to (b7), R^{14b} and R^{18b} to R^{23b} each independently represent a hydrogen atom, a linear or branched alkyl group having 1 or more and 6 or less carbon atoms, a fluorine atom or a linear or branched fluorinated alkyl group having 1 or more and 6 or less carbon atoms; R^{15b} to R^{17b} each independently represent a linear or branched alkyl group having 1 or more and 6 or less carbon atoms, a linear or branched fluorinated alkyl group having 1 or more and 6 or less carbon atoms or an aliphatic cyclic group having 5 or more and 20 or less carbon atoms; R^{16b} and R^{17b} may be bonded to each other to form a hydrocarbon ring having 5 or more and 20 or less carbon atoms together with the carbon atom to which both of them are bonded; Y^{b} represents an optionally substituted aliphatic group or alkyl group; p represents an integer of 0 or more and 4 or less; and q represents 0 or 1.

Examples of the linear or branched alkyl group include a methyl group, an ethyl group, a propyl group, an isopropyl group, an n-butyl group, an isobutyl group, a tert-butyl group, a pentyl group, an isopentyl group, a neopentyl group, and the like. The fluorinated alkyl group refers to the above alkyl group in which part or all of the hydrogen atoms thereof are substituted with fluorine atoms. Specific examples of the aliphatic cyclic group include groups in which one or more hydrogen atoms are removed from monocycloalkane and polycycloalkane, such as bicycloalkane, tricycloalkane and tetracycloalkane. Specifically, groups are mentioned in which one hydrogen atom is removed from monocycloalkane, such as cyclopentane, cyclohexane, cycloheptane and cyclooctane; and polycycloalkane such as adamantane, norbornane, isobornane, tricyclodecane, and tetracyclododecane. In particular, groups in which one hydrogen atom is removed from cyclohexane and adamantane (which may further have a substituent) are preferable.

When R^{16b} and R^{17b} are not bonded to each other to form a hydrocarbon ring, R^{15b}, R^{16b} and R^{17b} described above preferably represent a linear or branched alkyl group having 1 or more and 4 or less carbon atoms and more preferably represent a linear or branched alkyl group having 2 or more and 4 or less carbon atoms from the viewpoint of a high contrast and resolution, the depth of focus and the like, which are satisfactory. The R^{19b}, R^{20b}, R^{22b} and R^{23b} described above preferably represent a hydrogen atom or a methyl group.

The R^{16b} and R^{17b} described above may form an aliphatic cyclic group having 5 or more and 20 or less carbon atoms together with a carbon atom to which both of them are bonded. Specific examples of the aliphatic cyclic group as described above include groups in which one or more hydrogen atoms are removed from monocycloalkane and polycycloalkane such as bicycloalkane, tricycloalkane and tetracycloalkane. Specifically, groups are mentioned in which one or more hydrogen atoms are removed from monocycloalkane such as cyclopentane, cyclohexane, cycloheptane and cyclooctane; and polycycloalkane such as adamantane, norbornane, isobornane, tricyclodecane and tetracyclododecane. In particular, the groups in which one or more hydrogen atoms are removed from cyclohexane and adamantane (which may further have a substituent) are preferable.

Furthermore, when the aliphatic cyclic group formed with R^{16b} and R^{17b} described above has a substituent on the ring skeleton thereof, examples of the substituent include polar groups such as a hydroxyl group, a carboxyl group, a cyano group and an oxygen atom (═O); and a linear or branched alkyl group having 1 or more and 4 or less carbon atoms. As the polar group, an oxygen atom (═O) is particularly preferable.

Y^{b} described above is an alicyclic cyclic group or an alkyl group, and examples thereof include groups in which one or more hydrogen atoms are removed from monocycloalkane and polycycloalkane, such as bicycloalkane, tricycloalkane, and tetracycloalkane. Specific examples thereof include groups in which one or more hydrogen atoms are removed from monocycloalkane such as cyclopentane, cyclohexane, cycloheptane and cyclooctane; and polycycloalkane such as adamantane, norbornane, isobornane, tricyclodecane, and tetracyclododecane. In particular, a group in which one or more hydrogen atoms are removed from adamantane (which may further have a substituent) is preferable.

Furthermore, when the alicyclic cyclic group of Y^{b} described above has a substituent on the ring skeleton thereof, examples of the substituent include polar groups such as a hydroxyl group, a carboxyl group, a cyano group and an oxygen atom (═O); and a linear or branched alkyl group having 1 or more and 4 or less carbon atoms. The polar group is particularly preferably an oxygen atom (═O).

When Y^{b} is an alkyl group, it is preferably a linear or branched alkyl group having 1 or more and 20 or less carbon atoms, and more preferably 6 or more and 15 or less carbon atoms. The alkyl group described above is particularly preferably an alkoxyalkyl group, and examples of the alkoxyalkyl group described above include a 1-methoxyethyl group, 1-ethoxyethyl group, 1-n-propoxyethyl group, 1-isopropoxyethyl group, 1-n-butoxyethyl group, 1-isobutoxyethyl group, 1-tert-butoxyethyl group, 1-methoxypropyl group, 1-ethoxypropyl group, 1-methoxy-1-methylethyl group, 1-ethoxy-1-methylethyl group, and the like.

Preferred specific examples of the constituent unit represented by the above formula (b5) include those represented by the following formulae (b5-1) to (b5-33).

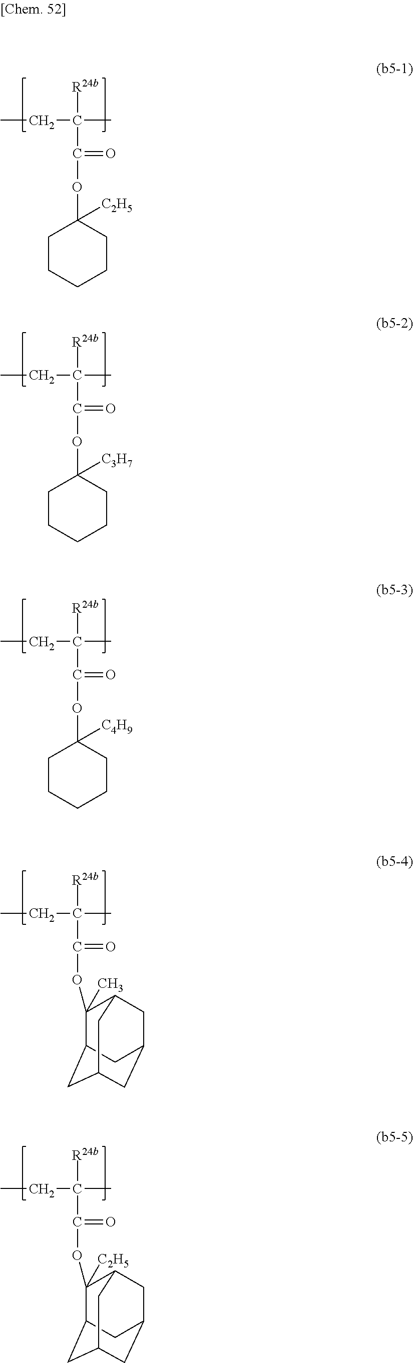

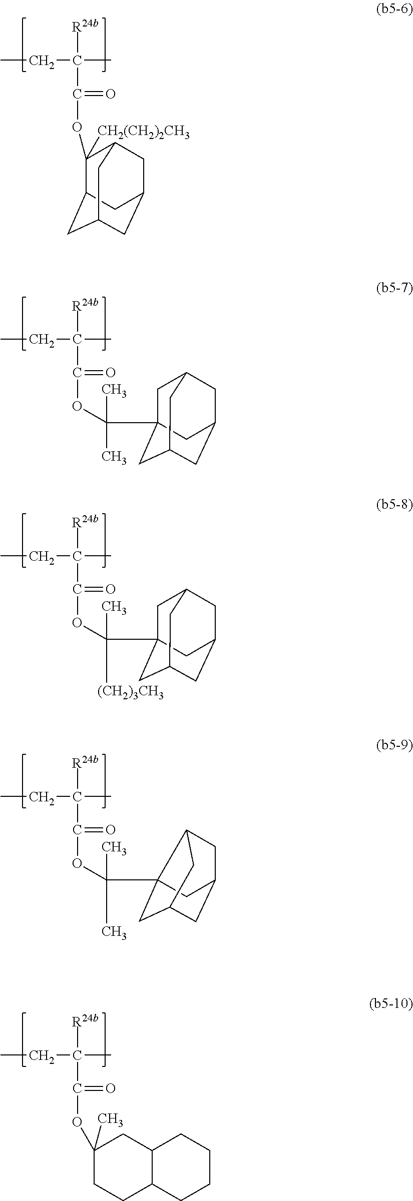

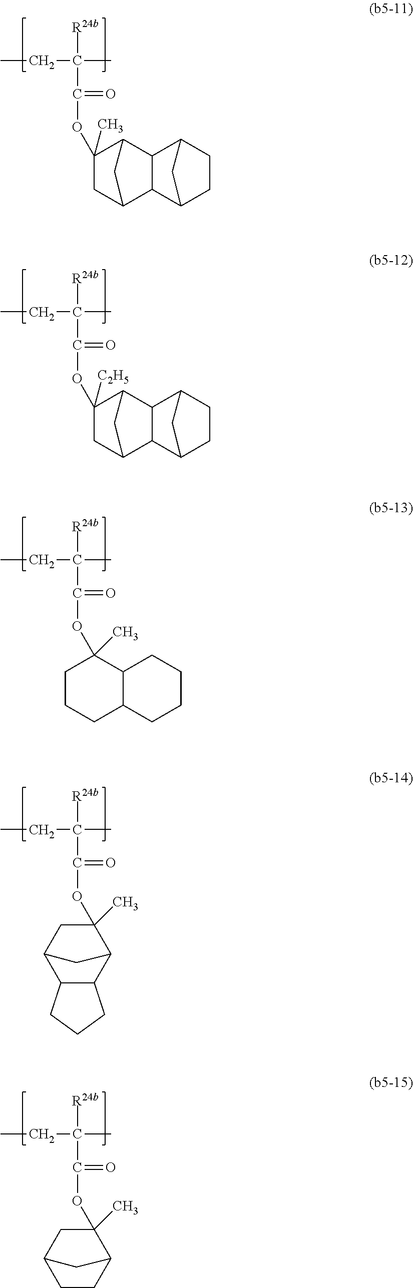

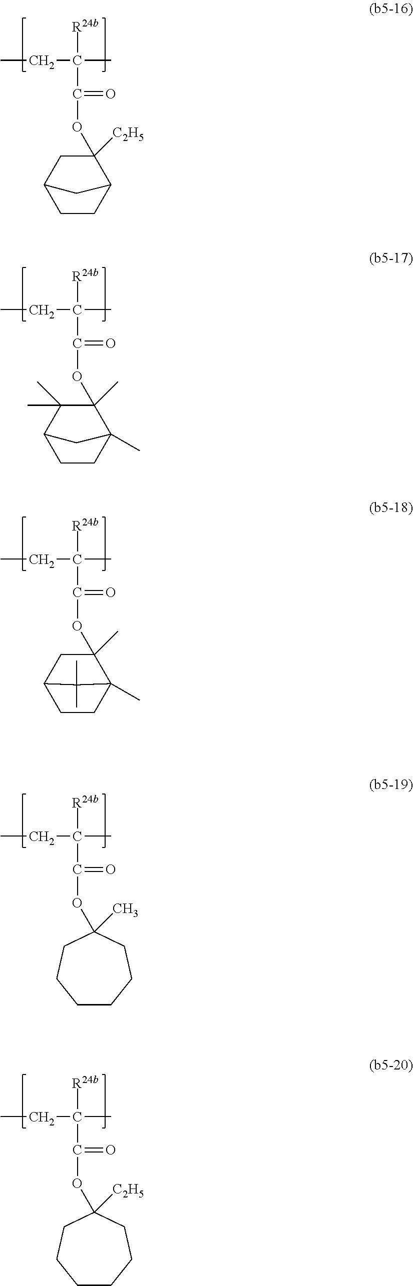

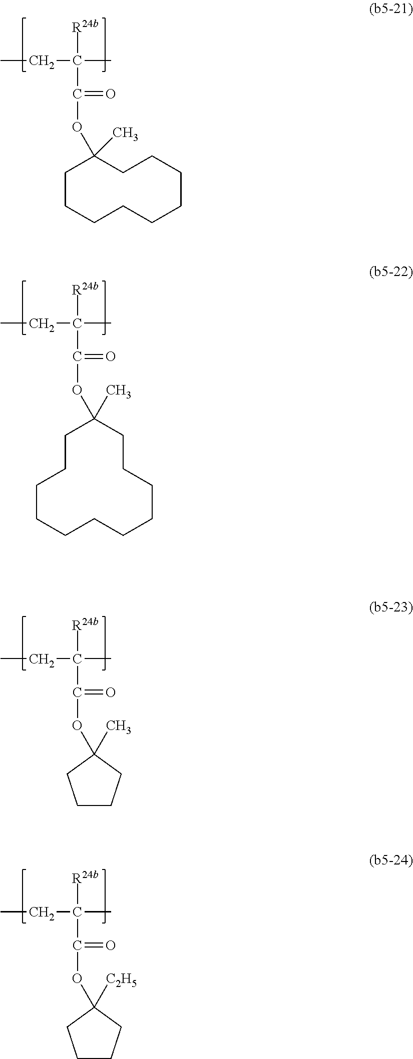

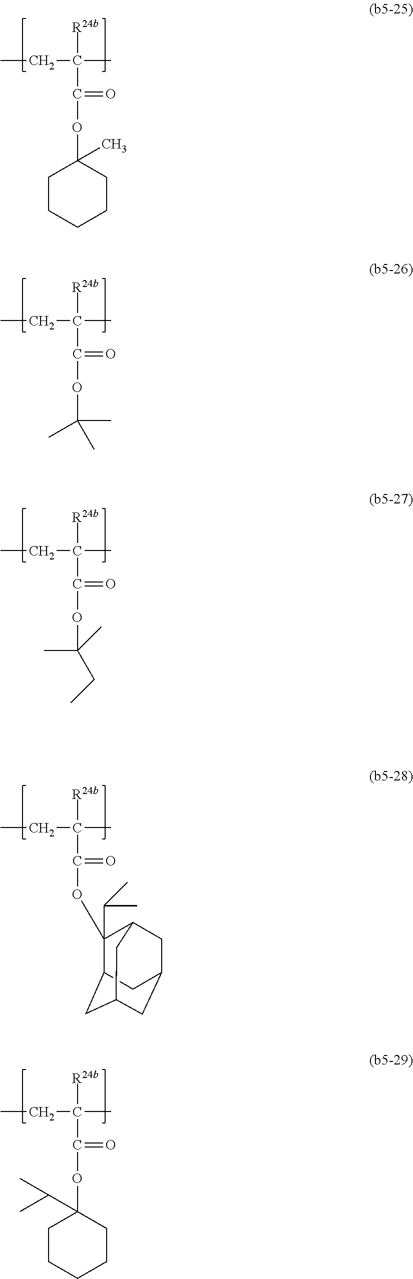

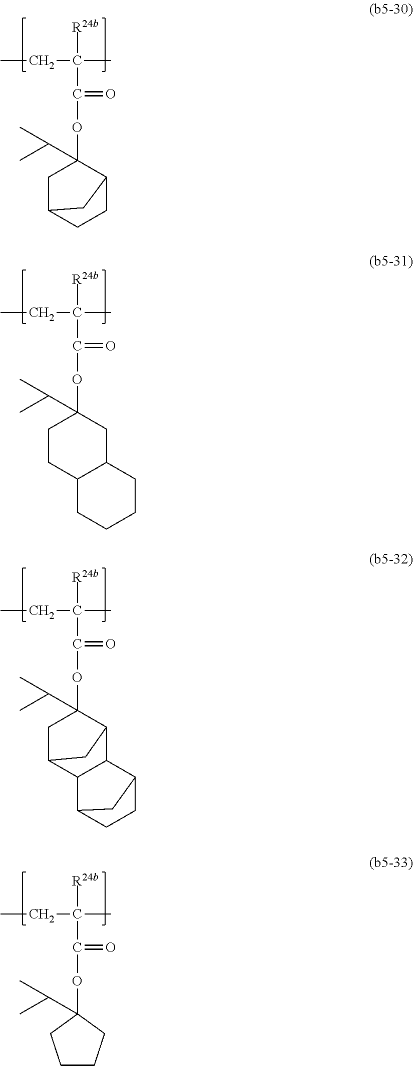

In the above formulae (b5-1) to (b5-33), R^{24b} represents a hydrogen atom or a methyl group.

Preferred specific examples of the constituent unit represented by the above formula (b6) include those represented by the following formulae (b6-1) to (b6-26).

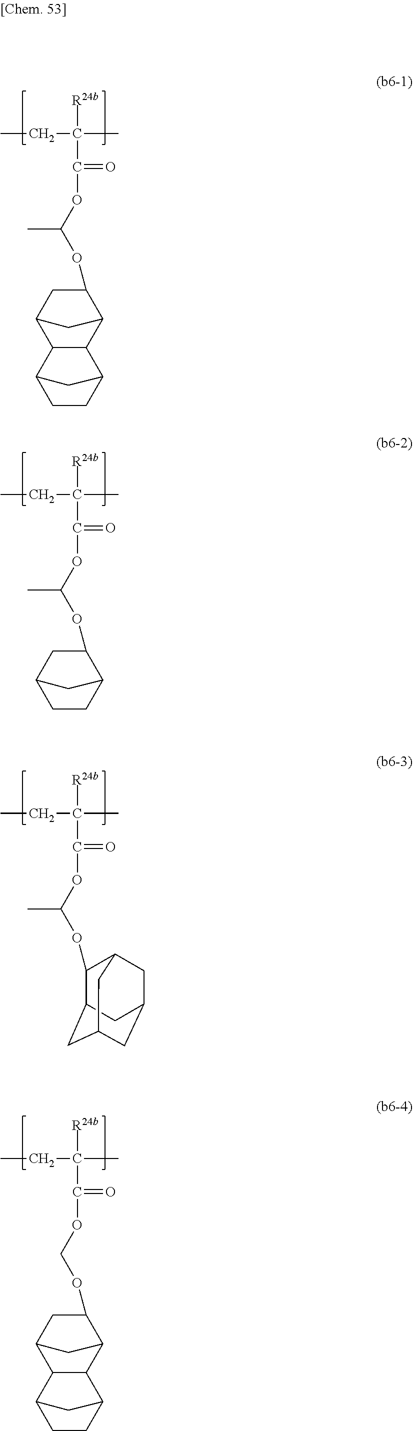

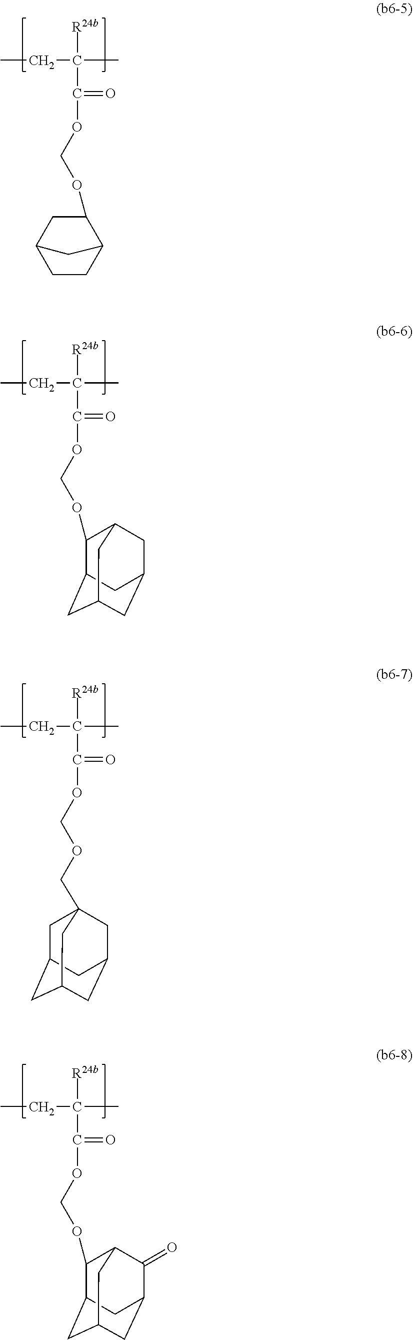

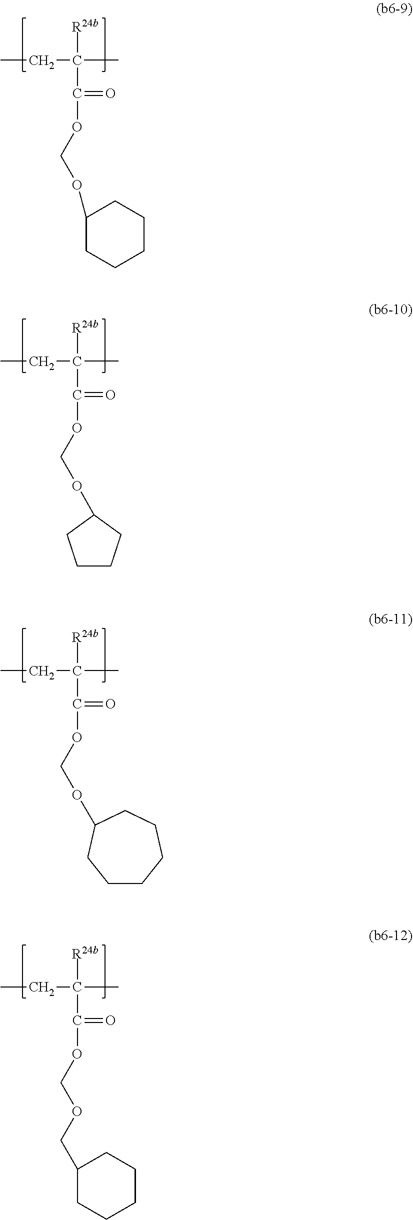

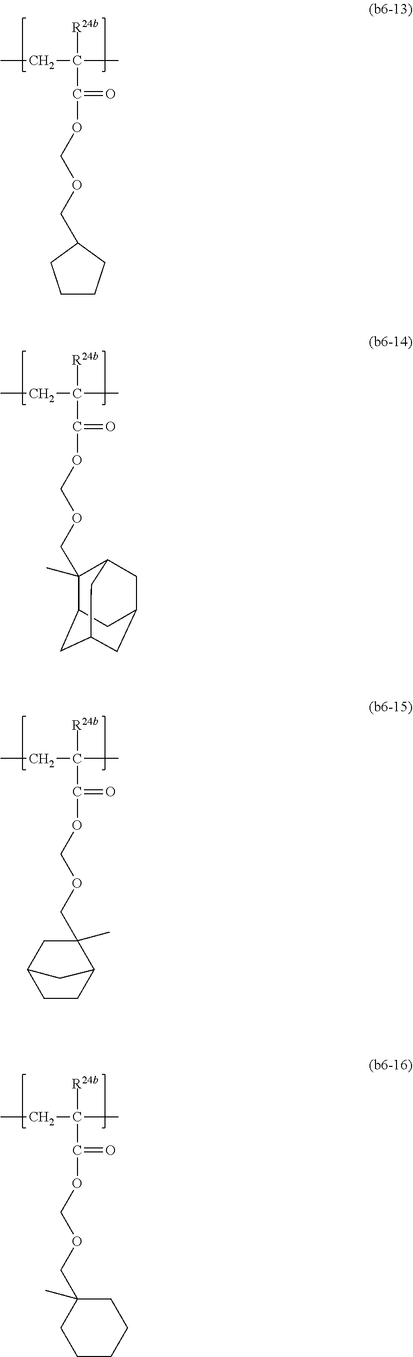

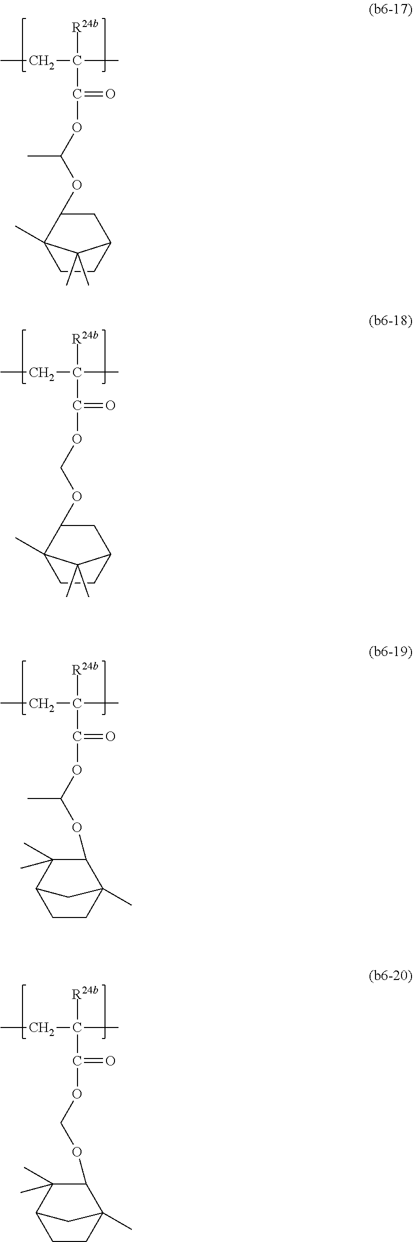

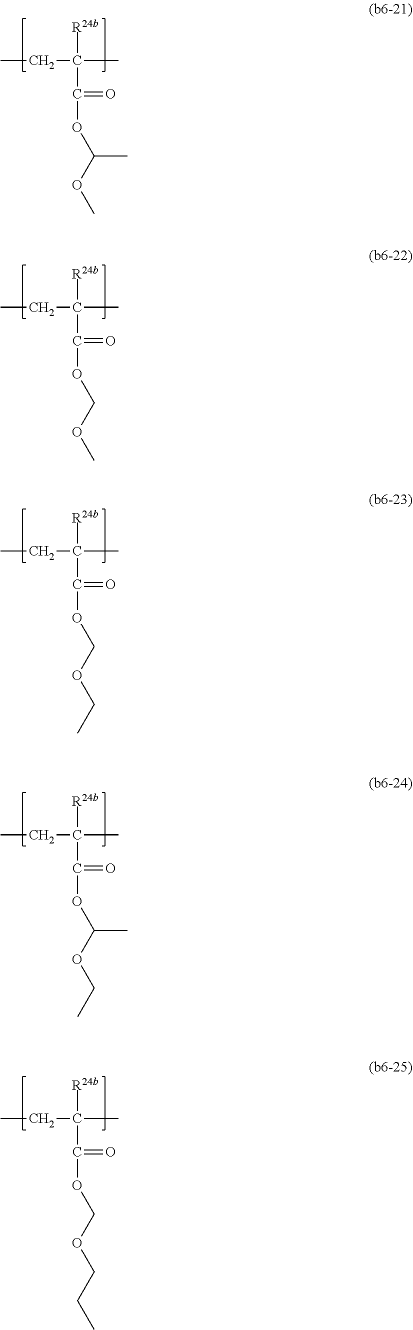

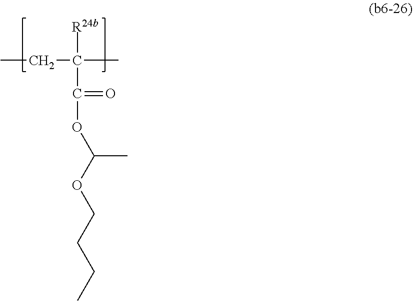

In the above formulae (b6-1) to (b6-26), R^{24b} represents a hydrogen atom or a methyl group.

Preferred specific examples of the constituent unit represented by the above formula (b7) include those represented by the following formulae (b7-1) to (b7-15).

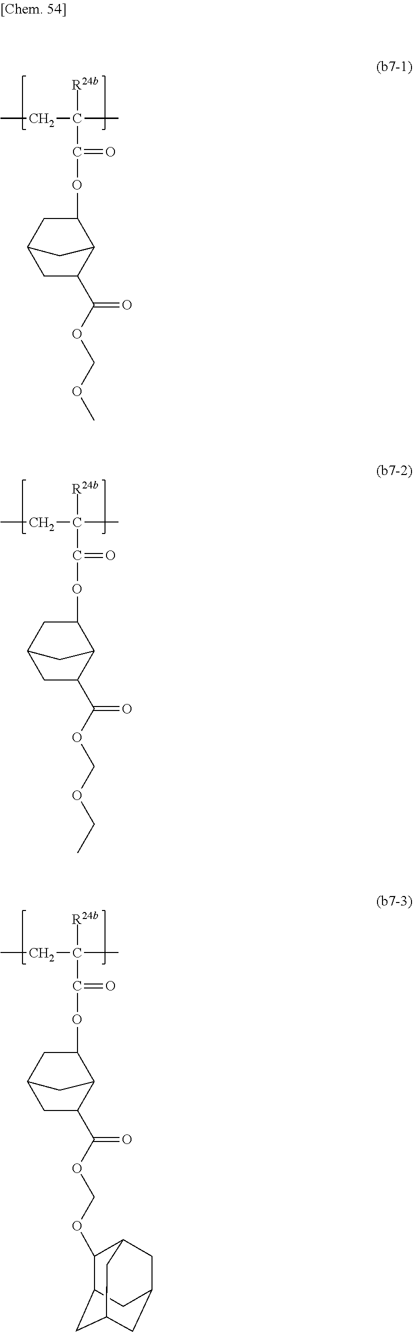

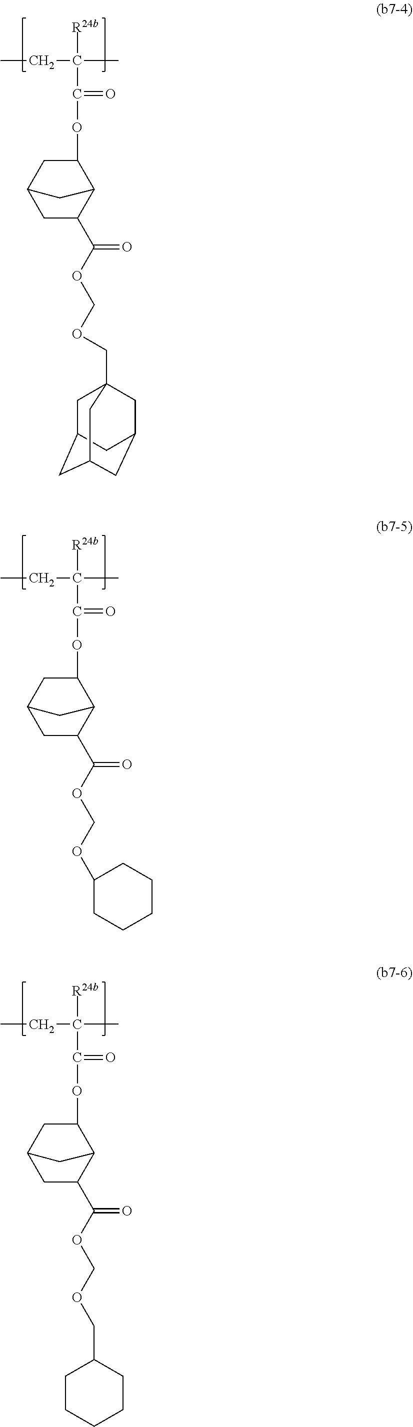

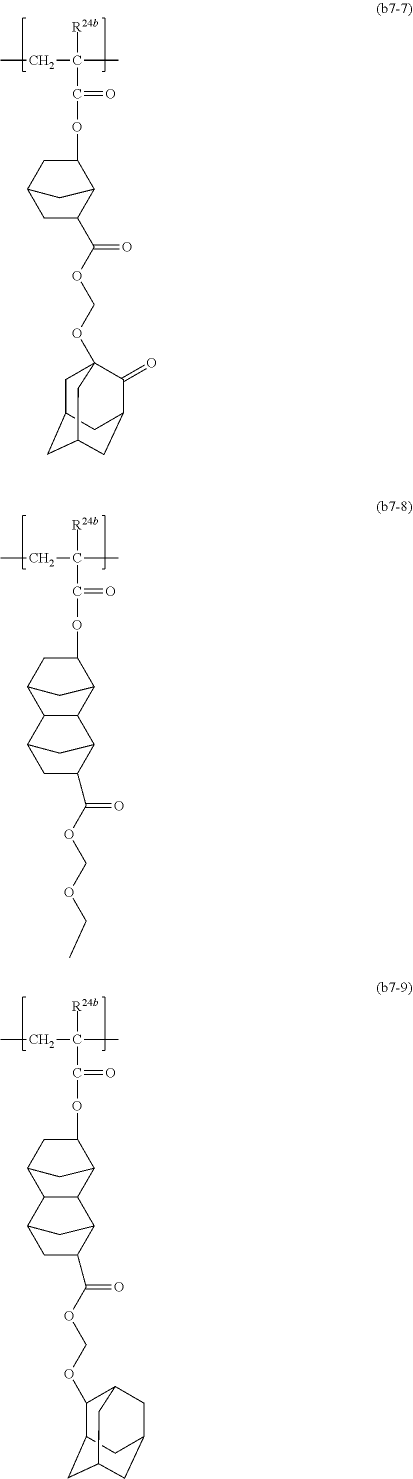

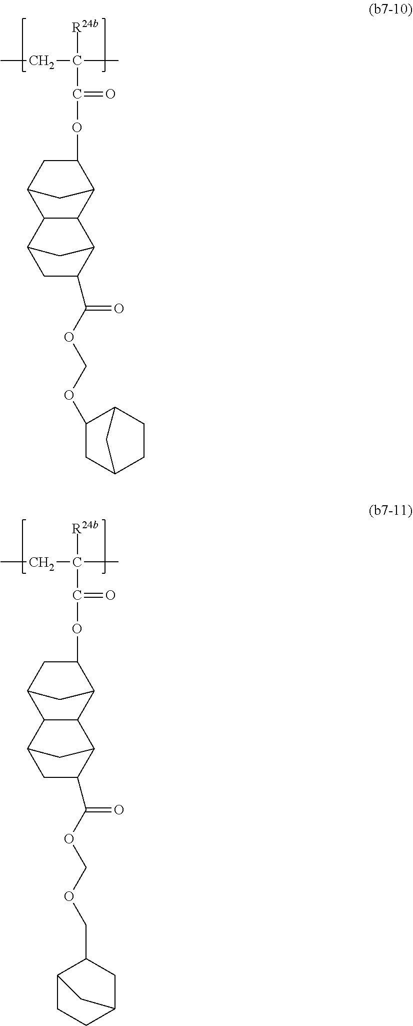

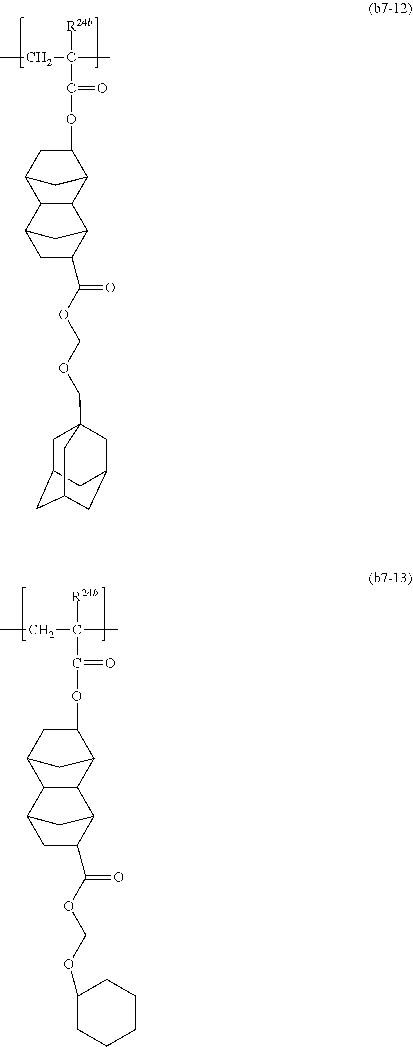

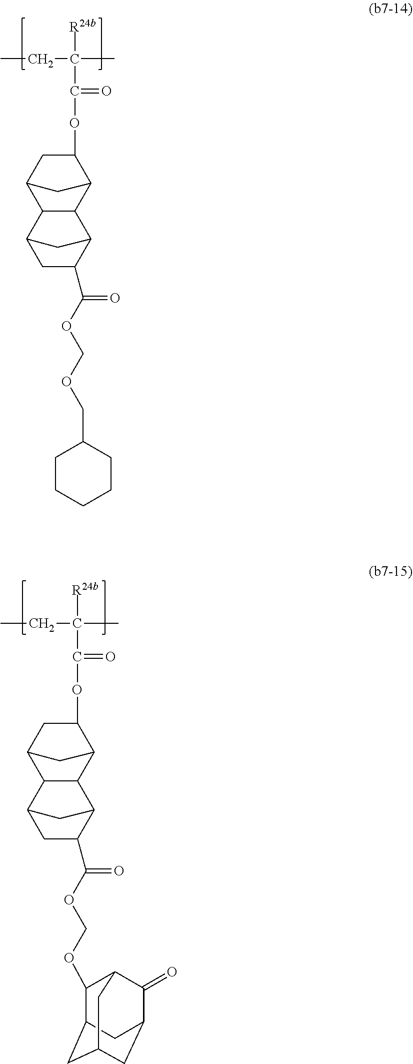

In the above formulae (b7-1) to (b7-15), R^{24b} represents a hydrogen atom or a methyl group.

Among the constituent units represented by the formulae (b5) to (b7) described above, constituent units represented by the formula (b6) are preferable because they can be easily synthesized and relatively easily sensitized. Among the constituent units represented by the formula (b6), constituent units in which Y^{b} is an alkyl group are preferable, and constituent units in which one or both of R^{19b} and R^{20b} are alkyl groups are preferable.

Furthermore, the acrylic resin (B3) is preferably a resin including a copolymer which includes constituent units represented by the above formulae (b5) to (b7) and constituent units derived from a polymerizable compound having an ether bond.

As the polymerizable compound having the ether bond described above, radical polymerizable compounds such as (meth)acrylic acid derivatives having an ether bond and an ester bond can be illustrated, and specific examples thereof include 2-methoxyethyl (meth)acrylate, 2-ethoxyethyl (meth)acrylate, methoxytriethylene glycol (meth)acrylate, 3-methoxybutyl (meth)acrylate, ethylcarbitol (meth)acrylate, phenoxypolyethylene glycol (meth)acrylate, methoxypolyethylene glycol (meth)acrylate, methoxypolypropylene glycol (meth)acrylate, tetrahydrofurfuryl (meth)acrylate, and the like. The above polymerizable compound having an ether bond is preferably 2-methoxyethyl (meth)acrylate, 2-ethoxyethyl (meth)acrylate or methoxytriethylene glycol (meth)acrylate. These polymerizable compounds may be used alone or in combination of two or more types thereof.

Furthermore, the acrylic resin (B3) can include another polymerizable compound as a constituent unit in order to moderately control physical and chemical properties. The polymerizable compound described above is exemplified by conventional radical polymerizable compounds and anion polymerizable compounds.

Examples of the polymerizable compound described above include: monocarboxylic acids such as acrylic acid, methacrylic acid and crotonic acid; dicarboxylic acids such as maleic acid, fumaric acid and itaconic acid; methacrylic acid derivatives having a carboxyl group and an ester bond such as 2-methacryloyloxyethyl succinic acid, 2-methacryloyloxyethyl maleic acid, 2-methacryloyloxyethyl phthalic acid, and 2-methacryloyloxyethyl hexahydrophthalic acid; (meth)acrylic acid alkyl esters such as methyl(meth)acrylate, ethyl(meth)acrylate, butyl(meth)acrylate and cyclohexyl(meth)acrylate; (meth)acrylic acid hydroxyalkyl esters such as 2-hydroxyethyl (meth)acrylate and 2-hydroxypropyl (meth)acrylate; (meth)acrylic acid aryl esters such as phenyl (meth)acrylate and benzyl (meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; amide bond-containing polymerizable compounds such as acrylamide and methacrylamide; and the like.

As described above, the acrylic resin (B3) may include a constituent unit derived from a polymerizable compound having carboxy groups such as the monocarboxylic acids and dicarboxylic acids described above. However, since a resist pattern including a non-resist portion having a more satisfactory rectangular cross-sectional shape can easily be formed, it is preferable that the acrylic resin (B3) does not substantially include a constituent unit derived from a polymerizable compound having a carboxyl group. Specifically, the proportion of a constituent unit derived from a polymerizable compound having a carboxyl group in the acrylic resin (B3) is preferably 20% by mass or less, more preferably 15% by mass or less and particularly preferably 10% by mass or less. In the acrylic resin (B3), an acrylic resin including a relatively large amount of constituent unit derived from a polymerizable compound having a carboxy group is preferably used in combination with an acrylic resin which includes only a small amount of constituent unit derived from a polymerizable compound having a carboxy group or does not include this constituent unit.

Examples of the polymerizable compound include (meth)acrylic acid esters having a non-acid-dissociable aliphatic polycyclic group, vinyl group-containing aromatic compounds, and the like. As the non-acid-dissociable aliphatic polycyclic group, in particular, a tricyclodecanyl group, an adamantyl group, a tetracyclododecanyl group, an isobornyl group, a norbornyl group, and the like are preferable in terms of ease of industrial availability and the like. These aliphatic polycyclic groups may have a linear or branched alkyl group having 1 or more and 5 or less carbon atoms as a substituent.

Specifically, as the (meth)acrylic acid esters having a non-acid-dissociable aliphatic polycyclic group, (meth)acrylic acid esters having structures represented by the following formulae (b8-1) to (b8-5) can be illustrated.

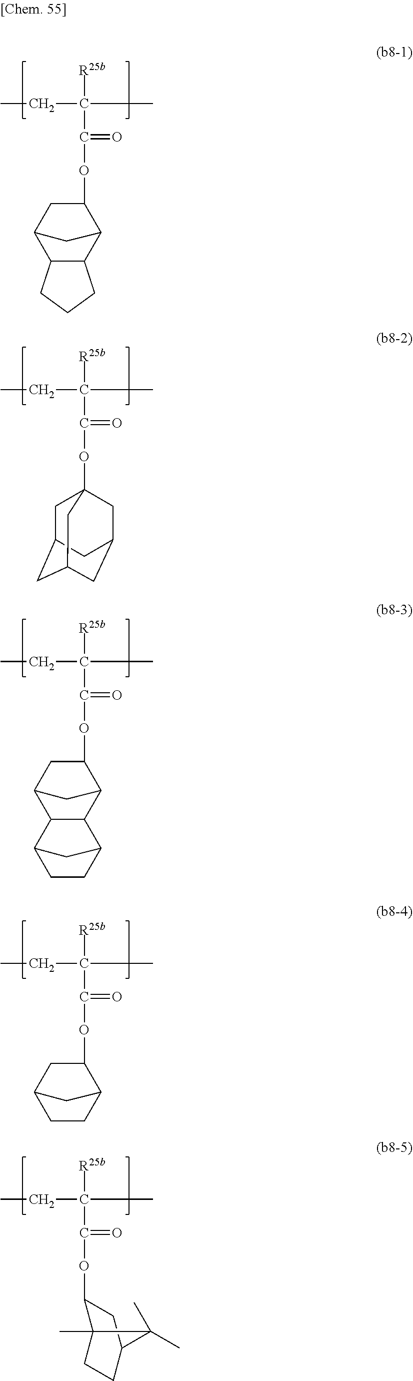

In the formulae (b8-1) to (b8-5), R^{25b} represents a hydrogen atom or a methyl group.

When the acrylic resin (B3) includes the constituent unit (b-3) including a —SO₂-containing cyclic group or a lactone-containing cyclic group, the content of the constituent unit (b-3) in the acrylic resin (B3) is preferably 5% by mass or more, more preferably 10% by mass or more, particularly preferably 10% by mass or more and 50% by mass or less and most preferably 10% by mass or more and 30% by mass or less. When the photosensitive composition includes the amount of constituent unit (b-3) which falls within the range described above, both a satisfactory developing property and a satisfactory pattern shape can easily be achieved.

In the acrylic resin (B3), the content of the constituent unit represented by the above formulae (b5) to (b7) is preferably 5% by mass or more, more preferably 10% by mass or more and particularly preferably 10% by mass or more and 50% by mass or less.

The acrylic resin (B3) preferably includes the above constituent unit derived from a polymerizable compound having an ether bond. The content of the constituent unit derived from a polymerizable compound having an ether bond in the acrylic resin (B3) is preferably 0% by mass or more and 50% by mass or less, more preferably 5% by mass or more and 40% by mass or less, and further preferably 5% by mass or more and 30% by mass or less.

The acrylic resin (B3) preferably includes the above constituent unit derived from (meth)acrylic acid esters having a non-acid-dissociable aliphatic polycyclic group. The content of the constituent unit derived from (meth)acrylic acid esters having a non-acid-dissociable aliphatic polycyclic group in the acrylic resin (B3) is preferably 0% by mass or more and 60% by mass or less, more preferably 5% by mass or more and 50% by mass or less, and further preferably 5% by mass or more and 30% by mass or less.

As long as the photosensitive composition contains a predetermined amount of acrylic resin (B3), an acrylic resin other than the acrylic resin (B3) described above can also be used as the resin (B). There is no particular limitation on such an acrylic resin other than the acrylic resin (B3) as long as it includes the constituent unit represented by the above formulae (b5) to (b7).

The mass-average molecular weight of the resin (B) described above in terms of polystyrene is preferably 10000 or more and 600000 or less, more preferably 20000 or more and 400000 or less, and further preferably 30000 or more and 300000 or less. The mass-average molecular weight falling within the range described above allows a photosensitive layer including the photosensitive composition to hold sufficient strength without reducing detachability from a substrate, and can further prevent a swelled profile and the occurrence of a crack at the time of plating.

The resin (B) preferably has a dispersivity of 1.05 or more. Dispersivity herein indicates a value obtained by dividing a mass average molecular weight by a number average molecular weight. The dispersivity falling within the range described above can prevent a problem with respect to stress resistance to intended plating or a problem with respect to possible swelling of a metal layer resulting from plating processing.

The content of the resin (B) is preferably 5% by mass or more and 60% by mass or less with respect to the total mass of the photosensitive composition. Furthermore, the content of the resin (B) is preferably 5% by mass or more and 98% by mass or less and more preferably 10% by mass or more and 95% by mass or less with respect to the total solid mass of the photosensitive composition.

### <Acid Diffusion Suppressing Agent (C)>

The acid diffusion suppressing agent (C) included in the photosensitive composition includes a compound represented by the following formula (C1). The photosensitive composition includes, as the acid diffusion suppressing agent (C), the compound represented by the formula (C1) to easily form a resist pattern having satisfactory cross-sectional rectangularity and to obtain the photosensitive composition having a high resolution and high dimensional controllability as will be shown in Examples later. Hence, it is possible to form a resist pattern which has a desired shape with a high resolution and a rectangular cross-sectional shape. For the cross-sectional shape, for example, around a contact surface between a substrate surface and a resist pattern, a footing shape (skirting shape) in which a resist portion is extended over the side of a non-resist portion or a biting shape (erosion shape) is suppressed to be formed. The cross-sectional verticality of the resist pattern is also satisfactory:

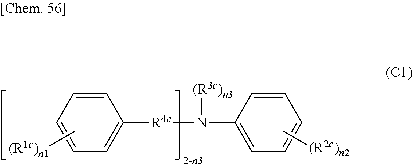

(in the formula (C1),
R^{1c} is an alkyl group or an aralkyl group,
R^{2c} is an alkyl group or an aralkyl group,
R^{3c} is a hydrogen atom or an alkyl group,
R^{4c} is a single bond or an alkylene group,
n1 is an integer of 0 or more and 5 or less,
n2 is an integer of 0 or more and 5 or less,
n3 is 0 or 1 and
when n3 is 1, n1 and n2 cannot simultaneously be 0).

In the formula (C1), the alkyl group serving as R^{1c} may be linear or branched. Although the number of carbon atoms in the alkyl group is not particularly limited, the number of carbon atoms is preferably 1 or more and 10 or less and more preferably 6 or more and 10 or less. Specific examples of the alkyl group include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, a 2-ethylhexyl group, an n-nonyl group, an isononyl group, an n-decyl group, and the like. The alkylene group constituting the aralkyl group (aryl group-alkylene group-) serving as R^{1c} may be linear or branched. Although the number of carbon atoms in the aralkyl group is not particularly limited, the number of carbon atoms is preferably 6 or more and 20 or less and more preferably 6 or more and 10 or less. Specific examples of the aralkyl group include a benzyl group, a 1-phenylethyl group, a 2-phenylethyl group, a naphthalene-1-ylmethyl group, a naphthalene-2-ylmethyl group, and the like. When n1 is an integer of 2 or more and 5 or less, a plurality of R^{1c}s may be the same as or different from each other. When n3 is 0, two groups of (R^{1c})ₙ₁—C₆H₄—R^{4C}— may be the same as or different from each other. —C₆H₄— represents a phenylene group. In the formula (C1), the alkyl group and the aralkyl group serving as R^{2c} are the same as R^{1c} in the formula (C1). When n2 is an integer of 2 or more and 5 or less, a plurality of R^{2c}s may be the same as or different from each other. Preferably, R^{1c} and R^{2c} are bulky and are an alkyl group having 6 or more and 10 or less carbon atoms or an aralkyl group having 6 or more and 10 or less carbon atoms.

In the formula (C1), the alkyl group serving as R^{3c} may be linear or branched. Although the number of carbon atoms in the alkyl group is not particularly limited, the number of carbon atoms is preferably 1 or more and 10 or less and preferably 6 or more and 10 or less. Specific examples of the alkyl group are the same as those of the alkyl group serving as R^{1c}.

In the formula (C1), the alkylene group serving as R^{4c} may be linear or branched. Although the number of carbon atoms in the alkylene group is not particularly limited, the number of carbon atoms is preferably 1 or more and 5 or less and preferably 1 or more and 3 or less. Specific examples of the alkylene group include a methylene group, an ethylene group, an n-propylene group, and an isopropylene group.

Among compounds represented by the formula (C1), a compound in which n3 is 1 and R^{4c} is a single bond, and a compound in which n3 is 0 and R^{4c} is an alkylene group are preferable.

The amount of compound represented by the formula (C1) is used so as to preferably fall within a range of 0.01 parts by mass or more and 20 parts by mass or less, more preferably fall within a range of 0.01 parts by mass or more and 5 parts by mass or less and further preferably fall within a range of 0.01 parts by mass or more and 3 parts by mass or less relative to 100 parts by mass of the resin (B).

Although the acid diffusion suppressing agent (C) may include an acid diffusion suppressing agent other than the compound represented by the formula (C1), the content of the compound represented by the formula (C1) in the acid diffusion suppressing agent (C) is preferably 50% by mass or more, more preferably 80% by mass or more and further preferably 100%.

### <Acid Diffusion Suppressing Agent (C′)>

An acid diffusion controlling agent other than the compound represented by the formula (C1) is preferably a nitrogen-containing compound (C′1) other than the compound represented by the formula (C1), and an organic carboxylic acid or an oxo acid of phosphorus or a derivative thereof (C′2) may be further included as necessary.

### [Nitrogen-Containing Compound (C′1)]

Examples of the nitrogen-containing compound (C′1) include trimethylamine, diethylamine, triethylamine, di-n-propylamine, tri-n-propylamine, tri-n-pentylamine, tribenzylamine, diethanolamine, triethanolamine, n-hexylamine, n-heptyl amine, n-octyl amine, n-nonyl amine, ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, formamide, N-methylformamide, N,N-dimethylformamide, acetamide, N-methylacetamide, N,N-dimethylacetamide, propionamide, benzamide, pyrrolidone, N-methylpyrrolidone, methylurea, 1,1-dimethylurea, 1,3-dimethylurea, 1,1,3,3-tetramethylurea, 1,3-diphenylurea, imidazole, benzimidazole, 4-methylimidazole, 8-oxyquinoline, acridine, purine, pyrrolidine, piperidine, 2,4,6-tri(2-pyridyl)-S-triazine, morpholine, 4-methylmorpholine, piperazine, 1,4-dimethylpiperazine, 1,4-diazabicyclo[2.2.2]octane, pyridine and like. These may be used alone or in combination of two or more types thereof.

Commercially available hindered amine compounds such as Adeka Stab LA-52, Adeka Stab LA-57, Adeka Stab LA-63P, Adeka Stab LA-68, Adeka Stab LA-72, Adeka Stab LA-77Y, Adeka Stab LA-77G, Adeka Stab LA-81, Adeka Stab LA-82 and Adeka Stab LA-87 (all manufactured by ADEKA), and pyridines in which 2,6-position is substituted with a substituent of a hydrocarbon group or the like such as 2,6-diphenyl pyridine and 2,6-di-tert-butyl pyridine can also be used as the nitrogen-containing compound (C′1).

The amount of nitrogen-containing compound (C′1) is used so as to generally fall within a range of 0 part by mass or more and 5 parts by mass or less and particularly preferably fall within a range of 0 part by mass or more and 3 parts by mass or less relative to the total mass of 100 parts by mass of the resin (B) and the alkali-soluble resin (D) described above.

### [Organic Carboxylic Acid or Oxo Acid of Phosphorus or Derivative Thereof (C′2)]

Among the organic carboxylic acid, the oxo acid of phosphorus and the derivative thereof (C′2), specific preferred examples of the organic carboxylic acid include malonic acid, citric acid, malic acid, succinic acid, benzoic acid, salicylic acid, and the like, and salicylic acid is particularly preferable.

Examples of the oxo acid of phosphorus or derivatives thereof include phosphoric acid and derivatives like esters thereof such as phosphoric acid, phosphoric acid di-n-butyl ester and phosphoric acid diphenyl ester; phosphonic acid and derivatives like esters thereof such as phosphonic acid, phosphonic acid dimethyl ester, phosphonic acid di-n-butyl ester, phenylphosphonic acid, phosphonic acid diphenyl ester and phosphonic acid dibenzyl ester; and phosphinic acid and derivatives like esters thereof such as phosphinic acid and phenylphosphinic acid; and the like. Among these, phosphonic acid is particularly preferable. These may be used alone or in combination of two or more types thereof.

The amount of organic carboxylic acid or oxo acid of phosphorus or derivative thereof (C′2) is used so as to generally fall within a range of 0 part by mass or more and 5 parts by mass or less and particularly preferably fall within a range of 0 part by mass or more and 3 parts by mass or less relative to the total mass of 100 parts by mass of the resin (B) and the alkali-soluble resin (D) described above.

In order to form a salt to achieve stabilization, the organic carboxylic acid or the oxo acid of phosphorous or the derivative thereof (C′2) is preferably used in an amount equivalent to that of the nitrogen-containing compound (C′1) described above.

### <Alkali-Soluble Resin (D)>

Preferably, the photosensitive composition further contains an alkali-soluble resin (D) in order to enhance crack resistance. Here, the alkali-soluble resin refers to a resin in which a resin solution having a resin concentration of 20% by mass (solvent: propylene glycol monomethyl ether acetate) is used to form a resin film having a thickness of 1 μm on a substrate and when the resin film is immersed in a TMAM aqueous solution of 2.38% by mass for 1 minute, the resin film of 0.01 μm or more is dissolved. As the alkali-soluble resin (D), at least one type selected from the group consisting of novolak resin (D1), polyhydroxystyrene resin (D2) and acrylic resin (D3) is preferable.

### [Novolak Resin (D1)]

A novolak resin is prepared by addition condensation of, for example, aromatic compounds having a phenolic hydroxyl group (hereinafter, simply referred to as “phenols”) and aldehydes in the presence of an acid catalyst.

Examples of the phenols described above include phenol, o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethyl phenol, 3,4,5-trimethyl phenol, p-phenylphenol, resorcinol, hydroquinone, hydroquinone monomethyl ether, pyrogallol, phloroglycinol, hydroxydiphenyl, bisphenol A, gallic acid, gallic acid ester, α-naphthol, β-naphthol, and the like. Examples of the aldehydes described above include formaldehyde, furfural, benzaldehyde, nitrobenzaldehyde, acetaldehyde, and the like. The catalyst used in the addition condensation reaction is not particularly limited, and examples of an acid catalyst include hydrochloric acid, nitric acid, sulfuric acid, formic acid, oxalic acid, acetic acid, and the like.

The flexibility of the novolak resin can be more enhanced by using o-cresol, by substituting a hydrogen atom of a hydroxyl group in the resin with another substituent or by using bulky aldehydes.

The mass average molecular weight of the novolak resin (D1) is not particularly limited as long as the object of the present invention is not impaired, but the mass average molecular weight is preferably 1000 or more and 50000 or less.

### [Polyhydroxystyrene Resin (D2)]

Examples of the hydroxystyrene compound which constitutes the polyhydroxystyrene resin (D2) include p-hydroxystyrene, α-methylhydroxystyrene, α-ethylhydroxystyrene, and the like. Furthermore, the polyhydroxystyrene resin (D2) is preferably used as a copolymer with a styrene resin. Examples of the styrene compound which constitutes such a styrene resin include styrene, chlorostyrene, chloromethylstyrene, vinyltoluene, α-methylstyrene, and the like.

The mass average molecular weight of the polyhydroxystyrene resin (D2) is not particularly limited as long as the object of the present invention is not impaired, but the mass average molecular weight is preferably 1000 or more and 50000 or less.

### [Acrylic Resin (D3)]

The acrylic resin (D3) preferably includes a constituent unit derived from a polymerizable compound having an ether bond and a constituent unit derived from a polymerizable compound having a carboxyl group.

Examples of the above polymerizable compound having an ether bond include (meth)acrylic acid derivatives having an ether bond and an ester bond such as 2-methoxyethyl (meth)acrylate, methoxytriethylene glycol (meth)acrylate, 3-methoxybutyl (meth)acrylate, ethylcarbitol (meth)acrylate, phenoxypolyethylene glycol (meth)acrylate, methoxypolypropylene glycol (meth)acrylate, tetrahydrofurfuryl (meth)acrylate, and the like. The above polymerizable compound having an ether bond is preferably 2-methoxyethyl acrylate and methoxytriethylene glycol acrylate. These polymerizable compounds may be used alone or in combination of two or more types thereof

Examples of the above polymerizable compound having a carboxy group include: monocarboxylic acids such as acrylic acid, methacrylic acid and crotonic acid; dicarboxylic acids such as maleic acid, fumaric acid and itaconic acid; compounds having a carboxy group and an ester bond such as 2-methacryloyloxyethyl succinic acid, 2-methacryloyloxyethyl maleic acid, 2-methacryloyloxyethyl phthalic acid, 2-methacryloyloxyethyl hexahydrophthalic acid; and the like. The above polymerizable compound having a carboxy group is preferably acrylic acid or methacrylic acid. These polymerizable compounds may be used alone or in combination of two or more types thereof.

The mass average molecular weight of the acrylic resin (D3) is not particularly limited as long as the object of the present invention is not impaired, but the mass average molecular weight is preferably 50000 or more and 800000 or less.

When the total of the resin (B) and the alkali-soluble resin (D) described above is assumed to be 100 parts by mass, the content of the alkali-soluble resin (D) is preferably 0 parts by mass or more and 80 parts by mass or less and more preferably 0 parts by mass or more and 60 parts by mass or less. The content of the alkali-soluble resin (D) falls within the range described above, and thus there is a tendency to enhance crack resistance and to prevent a loss of a film at the time of development.

### <Sulfur-Containing Compound (E)>

When a photosensitive composition is used for pattern formation on a metal substrate, the photosensitive composition preferably includes a sulfur-containing compound (E). The sulfur-containing compound (E) is a compound including a sulfur atom which can coordinate with a metal. When in a compound which can generate two or more tautomers, at least one tautomer includes a sulfur atom which coordinates with a metal constituting the surface of a metal substrate, the compound corresponds to the sulfur-containing compound. When a resist pattern used as a template for plating is formed on a surface including a metal such as Cu, a failure in a cross-sectional shape such as footing (skirting) may occur. As described above, when the above photosensitive composition is used, a resist pattern having satisfactory cross-sectional rectangularity is easily formed. On the other hand, in order to suppress the failure of the cross-sectional shape more reliably, the photosensitive composition preferably includes the sulfur-containing compound (E). In a case where the photosensitive composition includes the sulfur-containing compound (E), even when a resist pattern is formed on the surface of a metal in a substrate, it is easy to more reliably suppress the occurrence of a failure in a cross-sectional shape such as footing. When the photosensitive composition is used for pattern formation on a substrate other than a metal substrate, the photosensitive composition does not particularly need to include the sulfur-containing compound. When the photosensitive composition is used for pattern formation on a substrate other than a metal substrate, it is preferable that the photosensitive composition does not include the sulfur-containing compound (E), for example, from the viewpoint that a reduction in the number of components of the photosensitive composition makes it easy to manufacture the photosensitive composition and can reduce the manufacturing cost of the photosensitive composition. There is no particular failure resulting from the inclusion of the sulfur-containing compound (E) in the photosensitive composition used for pattern formation on a substrate other than a metal substrate.

The sulfur atom which can coordinate with a metal is included in the sulfur-containing compound as, for example, a mercapto group (—SH), a thiocarboxy group (—CO—SH), a dithiocarboxy group (—CS—SH), a thiocarbonyl group (—CS—), and the like. Since a mercapto group easily coordinates with a metal and is excellent in suppressing footing, the sulfur-containing compound preferably includes a mercapto group.

Preferred examples of the sulfur-containing compound having a mercapto group include a compound represented by the following formula (e1):

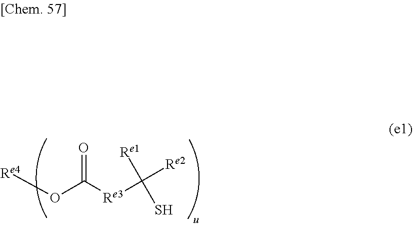

(in the formula, R^{e1} and R^{e2} each independently represent a hydrogen atom or an alkyl group, R^{e3} represents a single bond or an alkylene group, R^{e4} represents a u-valence aliphatic group which may include an atom other than carbon and u represents an integer of 2 or more and 4 or less).

When R^{e1} and R^{e2} are an alkyl group, the alkyl group may be linear or branched, and is preferably linear. When R^{e1} and R^{e2} are an alkyl group, the number of carbon atoms of the alkyl group is not particularly limited as long as the object of the present invention is not impaired. The number of carbon atoms of the alkyl group is preferably 1 or more and 4 or less, particularly preferably 1 or 2 and most preferably 1. As the combination of R^{e1} and R^{e2}, it is preferable that one is a hydrogen atom and the other is an alkyl group, and it is particularly preferable that one is a hydrogen atom and the other is a methyl group.

When R^{e3} is an alkylene group, the alkylene group may be linear or branched, and is preferably linear. When R^{e3} is an alkylene group, the number of carbon atoms of the alkylene group is not particularly limited as long as the object of the present invention is not impaired. The number of carbon atoms of the alkylene group is preferably 1 or more and 10 or less, more preferably 1 or more and 5 or less, particularly preferably 1 or 2 and most preferably 1.

R^{e4} is an aliphatic group which has two or more and four or less valences and which may include an atom other than carbon atom. Examples of the atom which may be included in R^{e4} include a nitrogen atom, an oxygen atom, a sulfur atom, a fluorine atom, a chlorine atom, a bromine atom, an iodine atom, and the like. The structure of the aliphatic group serving as R^{e4} may be linear, branch, cyclic, or a structure in which these structures are combined.

Among compounds represented by the formula (e1), a compound represented by the following formula (e2) is more preferable:

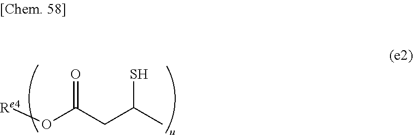

(in the formula (e2), R^{e4} and u have the same meanings as in the formula (e1)).

Among compounds represented by the above formula (e2), the following compounds are preferable.

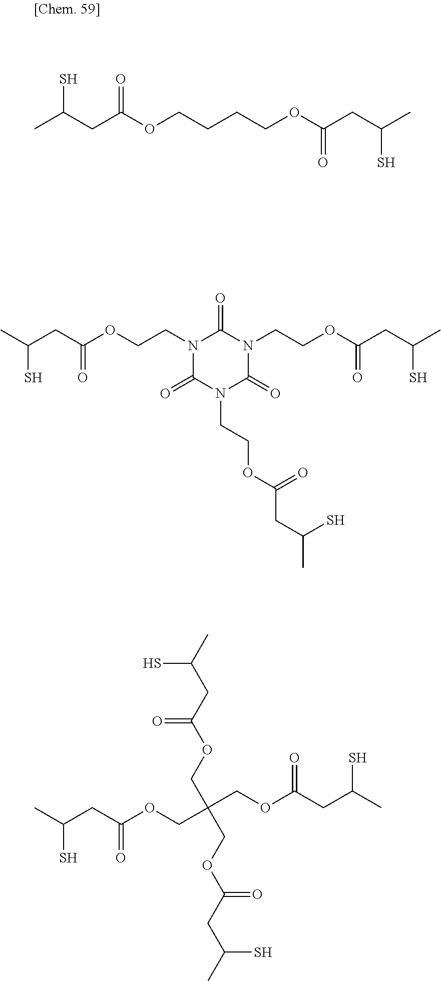

Compounds represented by the following formulae (e3-L1) to (e3-L7) are also preferred examples of the sulfur-containing compound having a mercapto group.

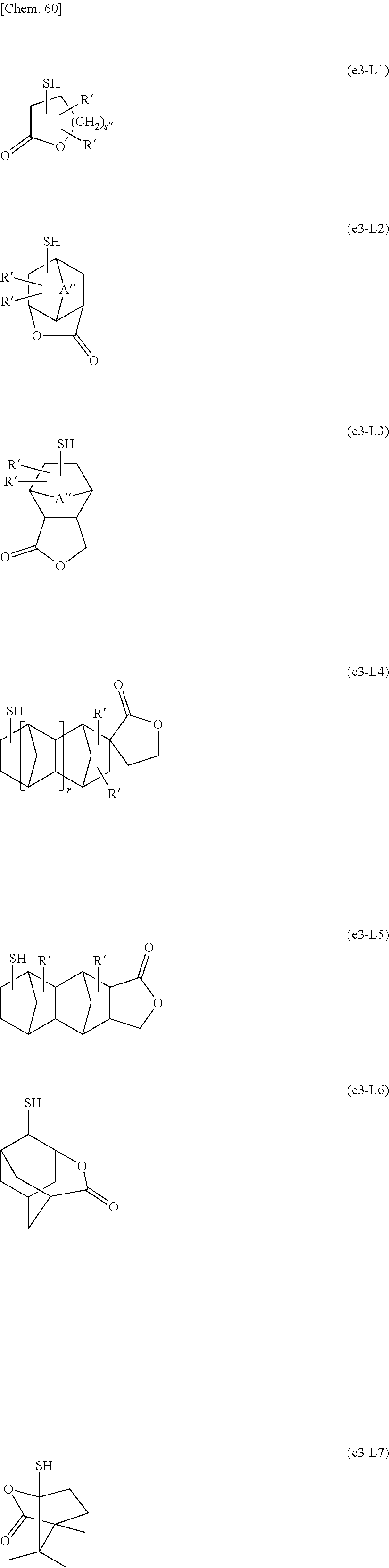

(in the formulae (e3-L1) to (e3-L7), R′, s″, A″ and r are the same as in the formulae (b-L1) to (b-L7) described on the acrylic resin (B3)).

Suitable specific examples of the mercapto compound represented by the above formulae (e3-L1) to (e3-L7) include the following compounds.

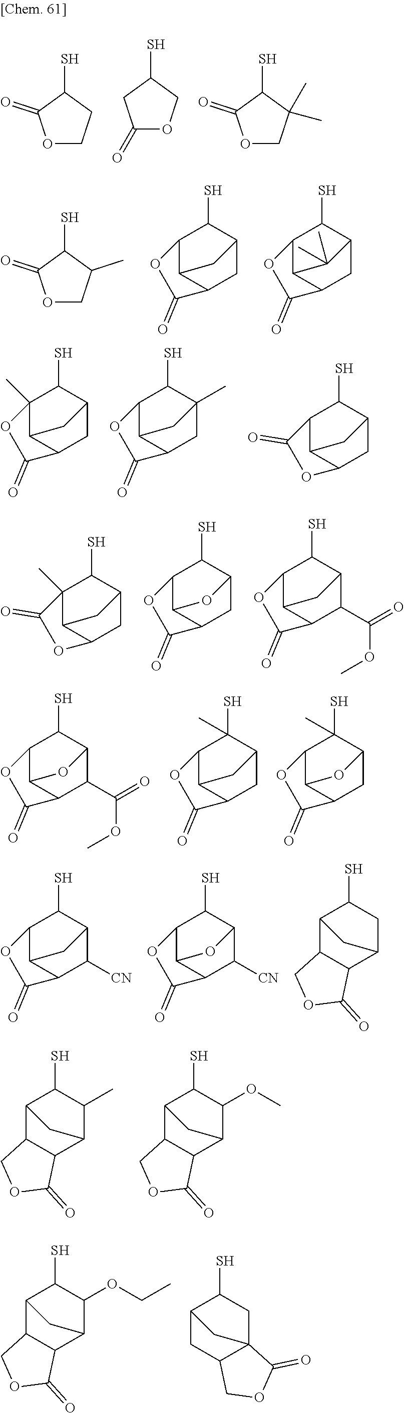

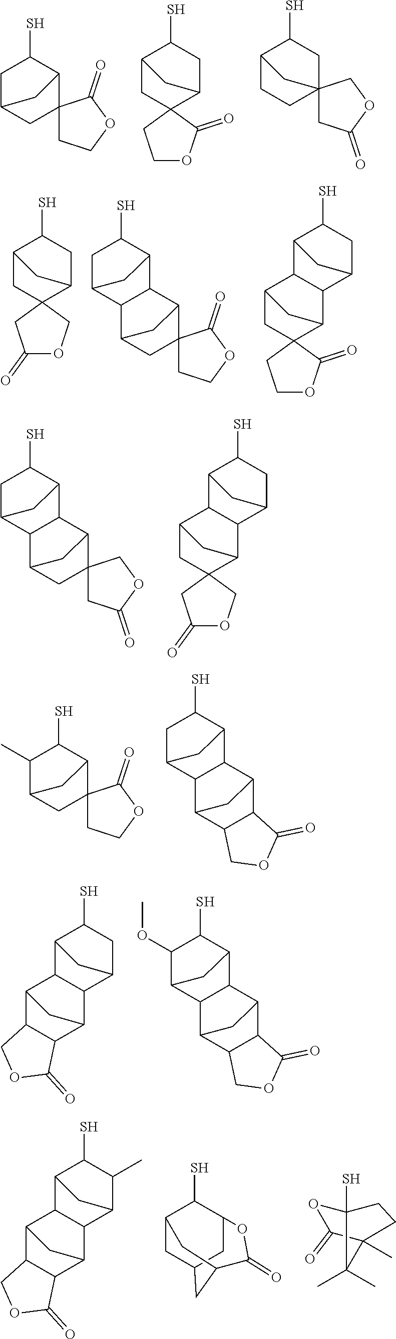

Compounds represented by the following formulae (e3-1) to (e3-4) are also preferred examples of the sulfur-containing compound having a mercapto group.

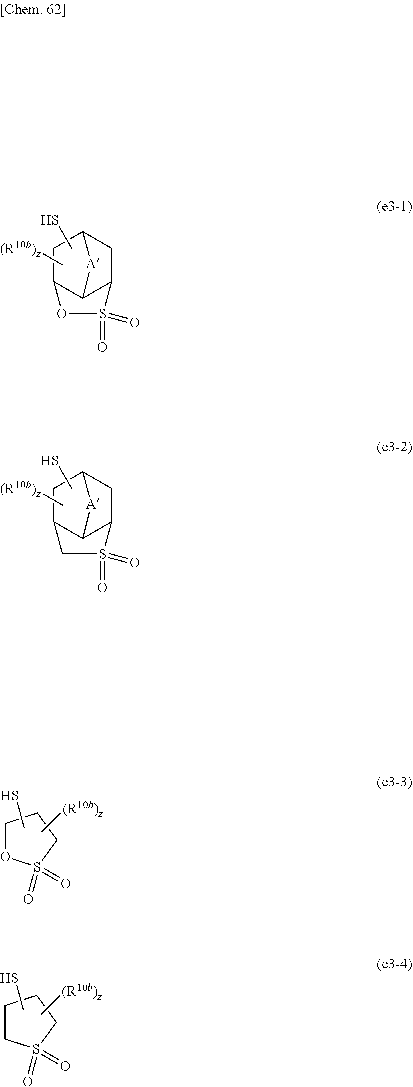

(in the formulae (e3-1) to (e3-4), the definitions of symbols are the same as mentioned for the formulae (3-1) to (3-4) described on acrylic resin (B3)).

Suitable specific examples of the mercapto compound represented by the above formulae (e3-1) to (e3-4) include the following compounds.

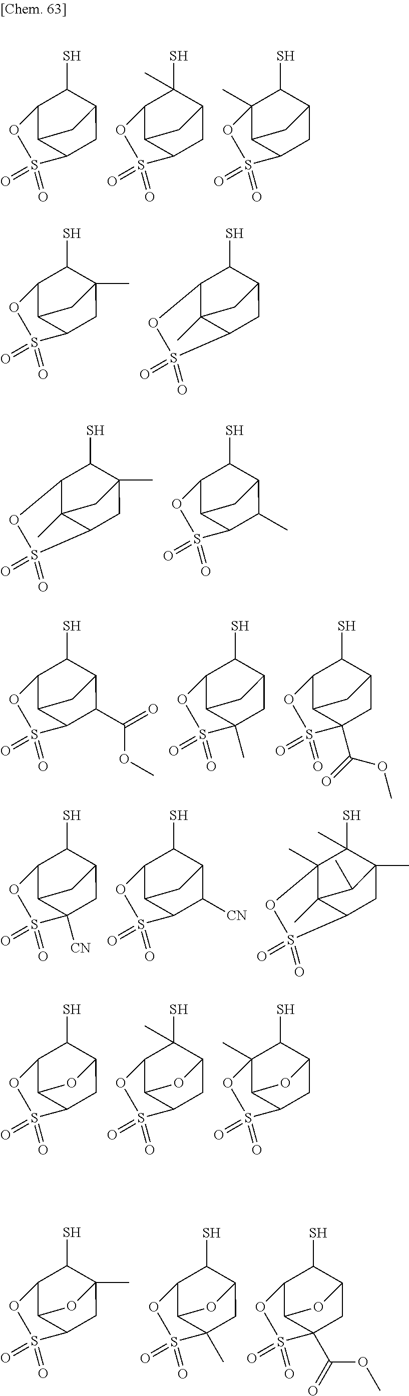

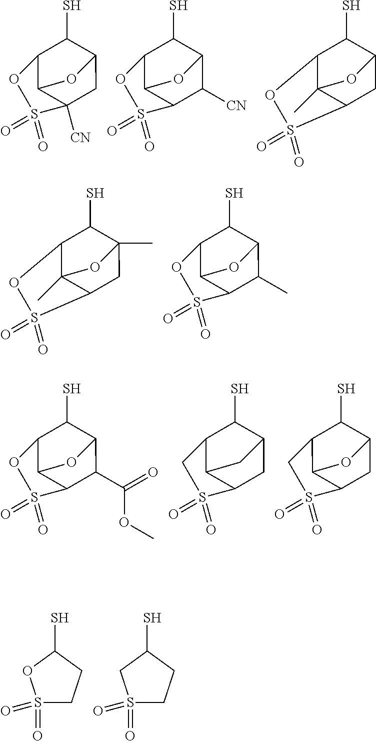

Preferable examples of the compound having a mercapto group include a compound represented by the following formula (e4):

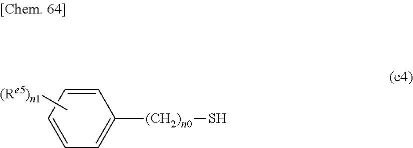

(in the formula (e4), R^{e5} is a group selected from the group consisting of a hydroxyl group, an alkyl group having 1 or more 4 or less carbon atoms, an alkoxy group having 1 or more 4 or less carbon atoms, an alkylthio group having 1 or more and 4 or less carbon atoms, a hydroxyalkyl group having 1 or more and 4 or less carbon atoms, a mercapto alkyl group having 1 or more and 4 or less carbon atoms, a halogenated alkyl group having 1 or more and 4 or less carbon atoms and a halogen atom, n1 is an integer of 0 or more and 3 or less, n0 is an integer of 0 or more and 3 or less and when n1 is 2 or 3, R^{e5} may be the same as or different from each other).

Specific examples when R^{e5} is an alkyl group which may have a hydroxyl group having 1 or more and 4 or less carbon atoms include a methyl group, an ethyl group, an n-propyl group, an isopropyl group, an n-butyl group, an isobutyl group, a sec-butyl group, and a tert-butyl group. Among these alkyl groups, a methyl group, a hydroxymethyl group and an ethyl group are preferable.

Specific examples when R^{e5} is an alkoxy group having 1 or more and 4 or less carbon atoms include a methoxy group, an ethoxy group, an n-propyloxy group, an isopropyloxy group, an n-butyloxy group, an isobutyloxy group, a sec-butyloxy group, and a tert-butyloxy group. Among these alkoxy groups, a methoxy group and an ethoxy group are preferable, and a methoxy group is more preferable.

Specific examples when R^{e5} is an alkylthio group having 1 or more and 4 or less carbon atoms include a methylthio group, an ethylthio group, an n-propylthio group, an isopropylthio group, an n-butylthio group, an isobutylthio, a sec-butylthio group and a tert-butylthio group. Among these alkylthio groups, a methylthio group, and an ethylthio group are preferable, and a methylthio group is more preferable.

Specific examples when R^{e5} is a hydroxyalkyl group having 1 or more and 4 or less carbon atoms include a hydroxymethyl group, a 2-hydroxyethyl group, a 1-hydroxyethyl group, a 3-hydroxy-n-propyl group and a 4-hydroxy-n-butyl group, and the like. Among these hydroxyalkyl groups, a hydroxymethyl group, a 2-hydroxyethyl group and a 1-hydroxyethyl group are preferable, and a hydroxymethyl group is more preferable.

Specific examples when R^{e5} is a mercapto alkyl group having 1 or more and 4 or less carbon atoms include a mercapto methyl group, a 2-mercapto ethyl group, a 1-mercapto ethyl group, a 3-mercapto-n-propyl group, a 4-mercapto-n-butyl group, and the like. Among these mercapto alkyl groups, a mercapto methyl group, a 2-mercapto ethyl group and 1-mercapto ethyl group are preferable, and a mercapto methyl group is more preferable.

When R^{e5} is an alkyl halide group having 1 or more and 4 or less carbon atoms, examples of the halogen atom included in the alkyl halide group include fluorine, chlorine, bromine, iodine, and the like. Specific examples when R^{e5} is an alkyl halide group having 1 or more and 4 or less carbon atoms include a chloromethyl group, a bromomethyl group, an iodomethyl group, a fluoromethyl group, a dichloromethyl group, a dibromomethyl group, a difluoromethyl group, a trichloromethyl group, a tribromomethyl group, a trifluoromethyl group, a 2-chloroethyl group, a 2-bromoethyl group, a 2-fluoroethyl group, a 1,2-dichloroethyl group, a 2,2-difluoroethyl group, a 1-chloro-2-fluoroethyl group, 3-chloro-n-propyl group, a 3-bromon-propyl group, a 3-fluoro-n-propyl group, 4-chloro-n-butyl group, and the like. Among these alkyl halide groups, a chloromethyl group, a bromomethyl group, an iodomethyl group, a fluoromethyl group, a dichloromethyl group, a dibromomethyl group, a difluoromethyl group, a trichloromethyl group, a tribromomethyl group and a trifluoromethyl group are preferable, and a chloromethyl group, a dichloromethyl group, a trichloromethyl group and a trifluoromethyl group are more preferable.

Specific examples when R^{e5} is a halogen atom include fluorine, chlorine, bromine, and iodine.

In the formula (e4), n1 is an integer of 0 or more and 3 or less, and 1 is more preferable. When n1 is 2 or 3, a plurality of R^{e5}s may be the same as or different from each other.

In the compound represented by the formula (e4), the substituted position of R^{e5} on a benzene ring is not particularly limited. The substituted position of R^{e5} on a benzene ring is preferably a meta position or a para position with respect to the bond position of —(CH₂)ₙ₀—SH.

The compound represented by the formula (e4) is preferably a compound having at least one group selected from the group consisting of an alkyl group, a hydroxyalkyl group, and a mercapto alkyl group serving as R^{e5}, and more preferably a compound having one group selected from the group consisting of an alkyl group, a hydroxyalkyl group, and a mercapto alkyl group serving as R^{e5}. When the compound represented by the formula (e4) has one group selected from the group consisting of an alkyl group, a hydroxyalkyl group and a mercapto alkyl group serving as R^{e5}, the substituted position on the benzene ring of the alkyl group, the hydroxyalkyl group or the mercapto alkyl group is preferably a meta position or a para position with respect to the bond position of —(CH₂)ₙ₀—SH, and more preferably a para position.

In the formula (e4), n0 is an integer of 0 or more and 3 or less. In terms of ease of the preparation or availability of the compound, n0 is preferably 0 or 1 and more preferably 0.

Specific examples of the compound represented by the formula (e4) include p-mercaptophenol, p-thiocresol, m-thiocresol, 4-(methylthio)benzenethiol, 4-methoxybenzenethiol, 3-methoxybenzenethiol, 4-ethoxybenzenethiol, 4-isopropyloxy benzenethiol, 4-tert-butoxybenzenethiol, 3,4-dimethoxy benzenethiol, 3,4,5-trimethoxybenzenethiol, 4-ethylbenzenethiol, 4-isopropyl benzenethiol, 4-n-butylbenzenethiol, 4-tert-butylbenzenethiol, 3-ethylbenzenethiol, 3-isopropyl benzenethiol, 3-n-butylbenzenethiol, 3-tert-butylbenzenethiol, 3,5-dimethyl benzenethiol, 3,4-dimethyl benzenethiol, 3-tert-butyl-4-methylbenzenethiol, 3-tert-4-methylbenzenethiol, 3-tert-butyl-5-methylbenzenethiol, 4-tert-butyl-3-methylbenzenethiol, 4-mercaptobenzyl alcohol, 3-mercaptobenzyl alcohol, 4-(mercaptomethyl)phenol, 3-(mercaptomethyl)phenol, 1,4-di(mercaptomethyl)phenol, 1,3-di(mercaptomethyl)phenol, 4-fluorobenzenethiol, 3-fluorobenzenethiol, 4-chlorobenzenethiol, 3-chlorobenzenethiol, 4-bromobenzenethiol, 4-iodobenzenethiol, 3-bromobenzenethiol, 3,4-dichlorobenzenethiol, 3,5-dichlorobenzenethiol, 3,4-difluorobenzenethiol, 3,5-difluorobenzenethiol, 4-mercaptocatechol, 2,6-di-tert-butyl-4-mercaptophenol, 3,5-di-tert-butyl-4-methoxybenzenethiol, 4-bromo-3-methylbenzenethiol, 4-(trifluoromethyl)benzenethiol, 3-(trifluoromethyl)benzenethiol, 3,5-bis(trifluoromethyl)benzenethiol, 4-methylthiobenzenethiol, 4-ethylthiobenzenethiol, 4-n-butylthiobenzenethiol, 4-tert-butylthiobenzenethiol, and the like.

Examples of the sulfur-containing compound having a mercapto group include a compound including a nitrogen-containing aromatic heterocycle substituted with a mercapto group and a tautomer of a compound including a nitrogen-containing aromatic heterocycle substituted with a mercapto group. Preferred specific examples of the nitrogen-containing aromatic heterocycle include imidazole, pyrazole, 1,2,3-triazol, 1,2,4-triazol, oxazole, thiazole, pyridine, pyrimidine, pyridazine, pyrazine, 1,2,3-triazine, 1,2,4-triazine, 1,3,5-triazine, indole, indazole, benzimidazole, benzoxazole, benzothiazole, 1H-benzotriazole, quinoline, isoquinoline, cinnoline, phthalazine, quinazoline, quinoxaline, and 1,8-naphthyridine.

Suitable specific examples of a nitrogen-containing heterocyclic compound suitable as a sulfur-containing compound and the tautomer of a nitrogen-containing heterocyclic compound include the following compounds.

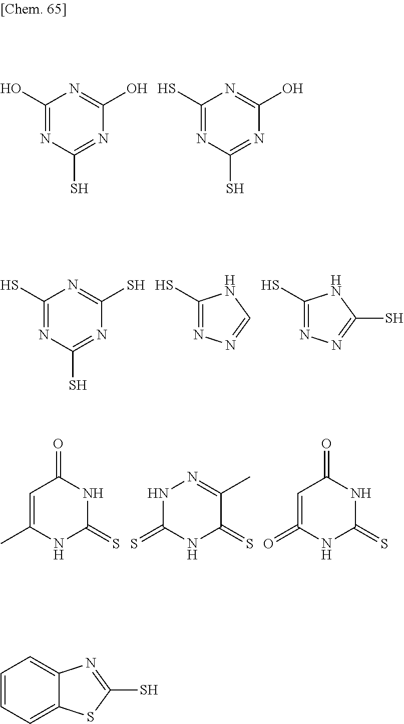

When the photosensitive composition includes the sulfur-containing compound (E), the amount used thereof is preferably 0.01 parts by mass or more and 5 parts by mass or less, more preferably 0.02 parts by mass or more and 3 parts by mass or less and particularly preferably 0.05 parts by mass or more and 2 parts by mass or less with respect to 100 parts by mass which is the total mass of the resin (B) and the alkali-soluble resin (D) described above.

### <Organic Solvent (S)>

The photosensitive composition contains the organic solvent (S). There is no particular limitation on the type of organic solvent (S) as long as the object of the present invention is not impaired, and an organic solvent can be appropriately selected from organic solvents conventionally used for photosensitive compositions so as to be used.

Specific examples of the organic solvent (S) include: ketones such as acetone, methyl ethyl ketone, cyclohexanone, methyl isoamyl ketone and 2-heptanone; polyhydric alcohols and derivatives thereof such as ethylene glycol, ethylene glycol monoacetate, diethylene glycol, diethylene glycol monoacetate, propylene glycol, propylene glycol monoacetate, dipropylene glycol, and a monomethyl ether, a monoethyl ether, a monopropyl ether, a monobutyl ether and a monophenyl ether of dipropylene glycol monoacetate; cyclic ethers such as dioxane; esters such as ethyl formate, methyl lactate, ethyl lactate, methyl acetate, ethyl acetate, butyl acetate, methyl pyruvate, methyl acetoacetate, ethyl acetoacetate, ethyl pyruvate, ethylethoxy acetate, methyl methoxypropionate, ethyl ethoxypropionate, methyl 2-hydroxypropionate, ethyl 2-hydroxypropionate, ethyl 2-hydroxy-2-methylpropionate, methyl 2-hydroxy-3-methylbutanate, 3-methoxybutyl acetate and 3-methyl-3-methoxybutyl acetate; aromatic hydrocarbons such as toluene and xylene; and the like. These may be used alone or as a mixture of two or more thereof.

There is no particular limitation on the content of the organic solvent (S) as long as the object of the present invention is not impaired. When a photosensitive composition is used for such an application of a thick film that a photosensitive layer obtained by a spin coat method or the like has a film thickness of 5 μm or more, the organic solvent (S) is preferably used such that the solid content concentration of the photosensitive composition falls within a range of 30% by mass or more and 55% by mass or less.

### <Other Components>

The photosensitive composition may further contain a polyvinyl resin in order to enhance plasticity. Specific examples of the polyvinyl resin include polyvinyl chloride, polystyrene, polyhydroxystyrene, polyvinyl acetate, polyvinylbenzoic acid, polyvinyl methyl ether, polyvinyl ethyl ether, polyvinyl alcohol, polyvinyl pyrrolidone, polyvinyl phenol, copolymers thereof, and the like. The polyvinyl resin is preferably polyvinyl methyl ether because it has a low glass transition temperature.

The photosensitive composition preferably contains a Lewis acidic compound. When the photosensitive composition includes a Lewis acidic compound, a photosensitive composition with high sensitivity is easily obtained, and a resist pattern having a rectangular cross-sectional shape is more easily formed using the photosensitive composition. In a case where a pattern is formed using the photosensitive composition, when the time required for each step during pattern formation or the time required between steps is long, it is possible that a pattern having the desired shape and dimensions cannot be easily formed, or developability is degraded. However, a Lewis acidic compound is mixed with the photosensitive composition, and thus it is possible to reduce the adverse effects of the pattern shape and developability described above so as to increase the process margin.

The Lewis acidic compound here means a “compound which acts as an electron-pair receptor having an empty orbital capable of receiving at least one electron pair”. The Lewis acidic compound is not particularly limited as long as it corresponds to the definition described above and is recognized as a Lewis acidic compound by a person skilled in the art. As the Lewis acidic compound, a compound which does not correspond to a Bronsted acid (proton acid) is preferably used. Specific examples of the Lewis acidic compound include boron fluoride, ether complexes of boron fluoride (for example, BF₃.Et₂O, BF₃.Me₂O, BF₃.THF, and the like). Et represents an ethyl group, Me represents a methyl group and THF represents tetrahydrofuran), organic boron compounds (for example, tri-n-octyl borate, tri-n-butyl borate, triphenyl borate, triphenylboron, and the like), titanium chloride, aluminum chloride, aluminum bromide, gallium chloride, gallium bromide, indium chloride, thallium trifluoroacetate, tin chloride, zinc chloride, zinc bromide, zinc iodide, zinc trifluoromethanesulfonate, zinc acetate, zinc nitrate, zinc tetrafluoroborate, manganese chloride, manganese bromide, nickel chloride, nickel bromide, nickel cyanide, nickel acetylacetonate, cadmium chloride, cadmium bromide, stannous chloride, stannous bromide, stannous sulfate, stannous tartrate, and the like. Furthermore, other specific examples of the Lewis acidic compound include chloride, bromide, sulfate, nitrate, carboxylate, or trifluoromethanesulfonate, of the rare earth metals, and cobalt chloride, ferrous chloride, yttrium chloride, and the like. Here, examples of the rare earth metal include lanthanum, cerium, praseodymium, neodymium, samarium, europium, gadolinium, terbium, dysprosium, holmium, erbium, thulium, ytterbium and lutetium.

The Lewis acidic compound preferably contains a group 13 element of the periodic table because it is easily available and effects caused by the addition thereof are satisfactory. Here, examples of the group 13 element of the periodic table include boron, aluminum, gallium, indium, and thallium. Among the group 13 elements of the periodic table described above, boron is preferable because the Lewis acidic compound is easily available and effects caused by the addition thereof are particularly excellent. In other words, the Lewis acidic compound preferably contains a Lewis acidic compound including boron.

Examples of the Lewis acidic compound containing boron include boron fluoride, ether complexes of boron fluoride, boron halides such as boron chloride and boron bromide, and various organic boron compounds. As the Lewis acidic compound including boron, an organic boron compound is preferable because the content of halogen atoms in the Lewis acidic compound is low and the photosensitive composition is easily applied to an application requiring a low halogen content.

Preferred examples of the organic boron compound include a boron compound represented by the following formula (f1):

B(R^{f1})ₜ₁(OR^{f2})₍₃₋ₜ₁₎ (f1)

(in the formula (f1), R^{f1} and R^{f2} each independently represent a hydrocarbon group having 1 or more and 20 or less carbon atoms; the hydrocarbon group may have one or more substituents; t1 is an integer of 0 or more and 3 or less; when a plurality of R^{f1}s are present, two of the plurality of R^{f1}s may be bonded to each other to form a ring; and when a plurality of OR^{f2}s are present, two of the plurality of OR^{f2}s may be bonded to each other to form a ring). The photosensitive composition preferably includes one or more types of boron compounds represented by the above formula (f1) as the Lewis acidic compound described above.

In the formula (f1), R^{f1} and R^{f2} are a hydrocarbon group, the number of carbon atoms of the hydrocarbon group is 1 or more and 20 or less. The hydrocarbon group having 1 or more and 20 or less carbon atoms may be an aliphatic hydrocarbon group, an aromatic hydrocarbon group or a hydrocarbon group having a combination of an aliphatic group, and an aromatic group. As the hydrocarbon group having 1 or more and 20 or less carbon atoms, a saturated aliphatic hydrocarbon group or an aromatic hydrocarbon group is preferable. The number of carbon atoms of the hydrocarbon group serving as R^{f1} and R^{f2} is preferably 1 or more and 10 or less. When the hydrocarbon group is an aliphatic hydrocarbon group, the number of carbon atoms thereof is preferably 1 or more and 6 or less and particularly preferably 1 or more and 4 or less. The hydrocarbon group serving as R^{f1} and R^{f2} may be a saturated hydrocarbon group or an unsaturated hydrocarbon group, and a saturated hydrocarbon group is preferable. When the hydrocarbon group serving as R^{f1} and R^{f2} is an aliphatic hydrocarbon group, the aliphatic hydrocarbon group may be linear, branched, cyclic or a combination of structures thereof.

Suitable specific examples of the aromatic hydrocarbon group include a phenyl group, a naphthalene-1-yl group, a naphthalene-2-yl group, a 4-phenylphenyl, 3-phenylphenyl and 2-phenylphenyl. Among them, a phenyl group is preferable.

The saturated aliphatic hydrocarbon group is preferably an alkyl group. Preferred examples of the alkyl group include a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, a 2-ethyl hexyl group, an n-nonyl group, and an n-decyl group.

The hydrocarbon group serving as R^{f1} and R^{f2} may have one or more substituents. Examples of the substituent include a halogen atom, a hydroxyl group, an alkyl group, an aralkyl group, an alkoxy group, a cycloalkyloxy group, an aryloxy group, an aralkyloxy group, an alkylthio group, a cycloalkylthio group, an arylthio group, an aralkylthio group, an acyl group, an acyloxy group, an acylthio group, an alkoxycarbonyl group, a cycloalkyloxycarbonyl group, an aryloxycarbonyl group, an amino group, an N-monosubstituted amino group, an N,N-disubstituted amino group, a carbamoyl group (—CO—NH₂), an N-monosubstituted carbamoyl group, an N,N-disubstituted carbamoyl group, a nitro group, a cyano group, and the like. Although the number of carbon atoms in the substituent is not particularly limited as long as the object of the present invention is not impaired, the number of carbon atoms is preferably 1 or more and 10 or less and more preferably 1 or more and 6 or less.

Suitable specific examples of the organic boron compound represented by the above formula (f1) include the following compounds. In the following formulae, Pen represents a pentyl group, Hex represents a hexyl group, Hep represents a heptyl group, Oct represents an octyl group, Non represents a nonyl group and Dec represents a decyl group.

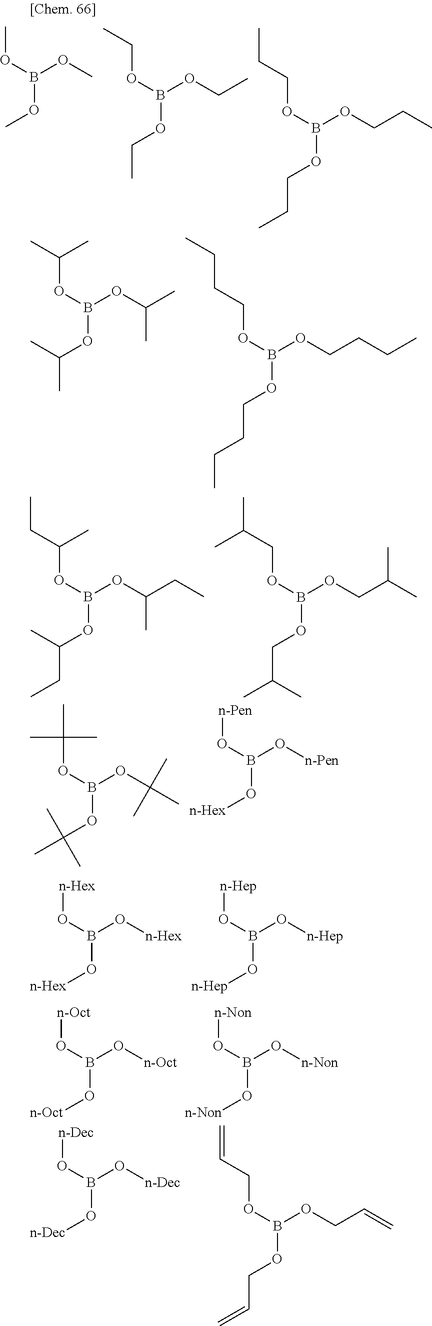

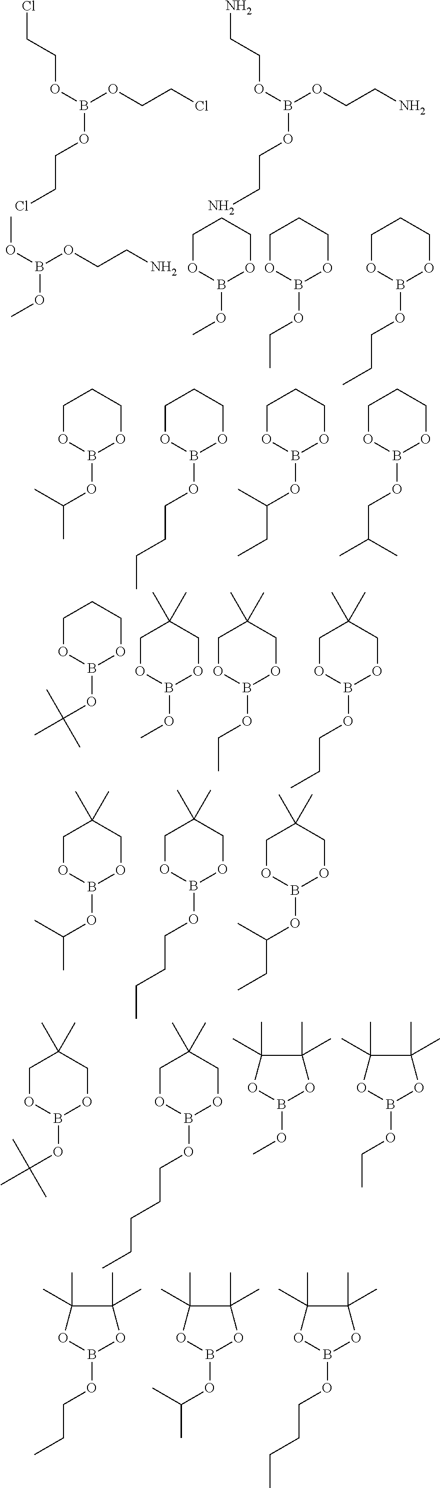

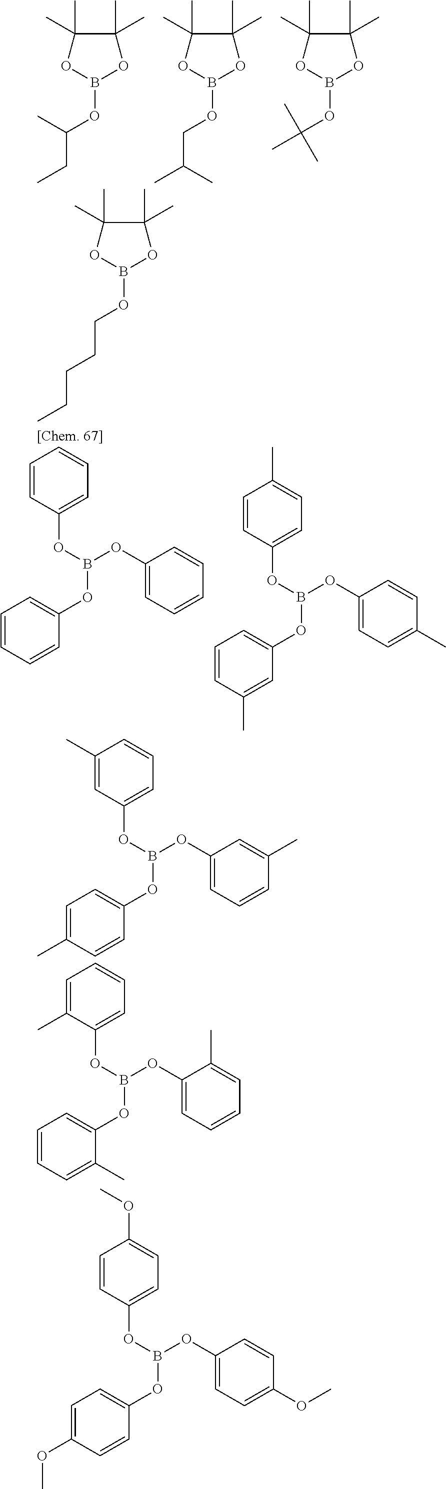

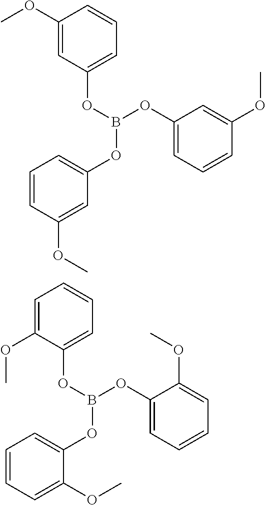

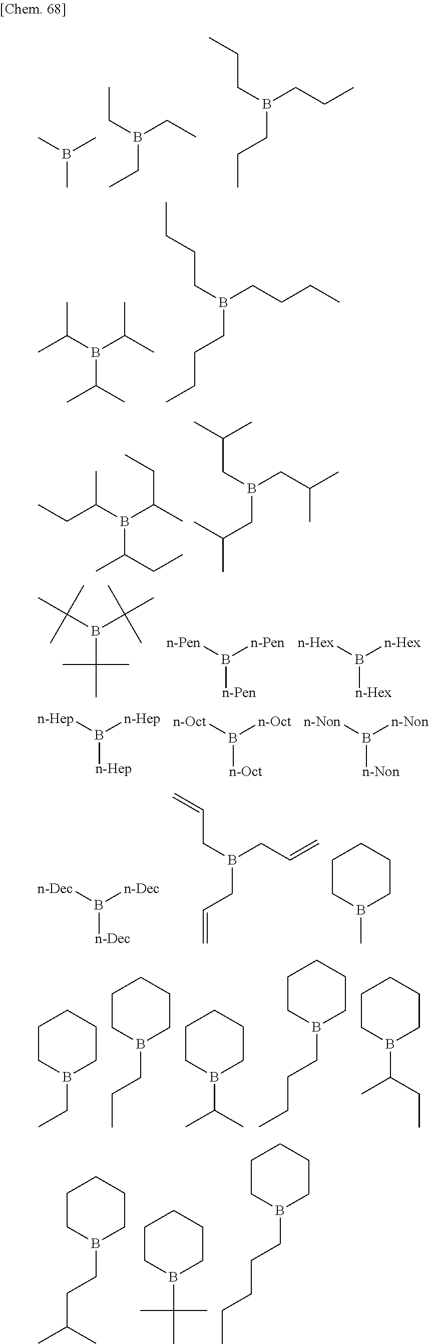

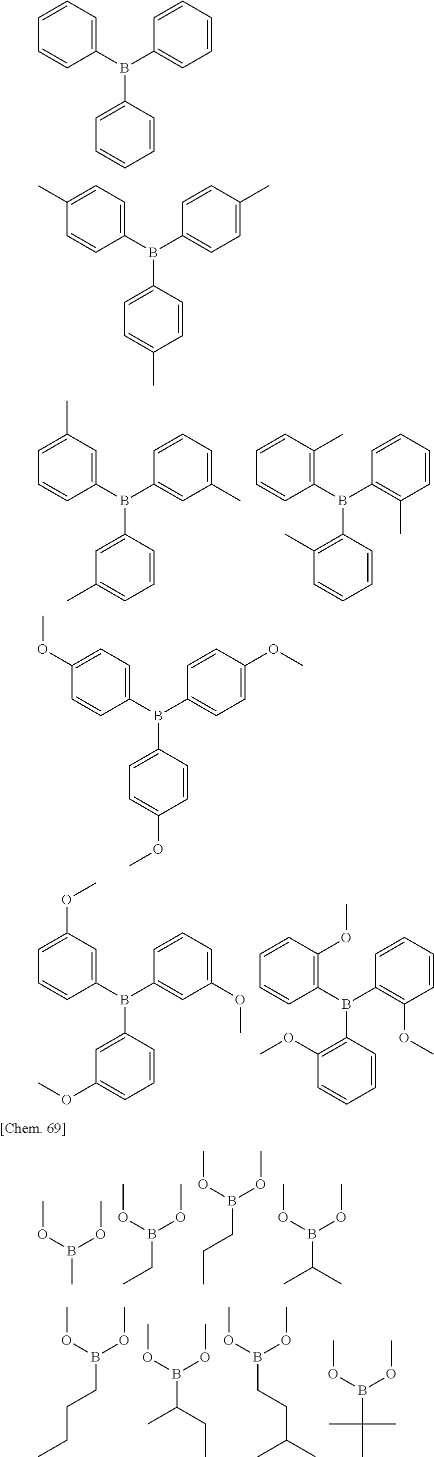

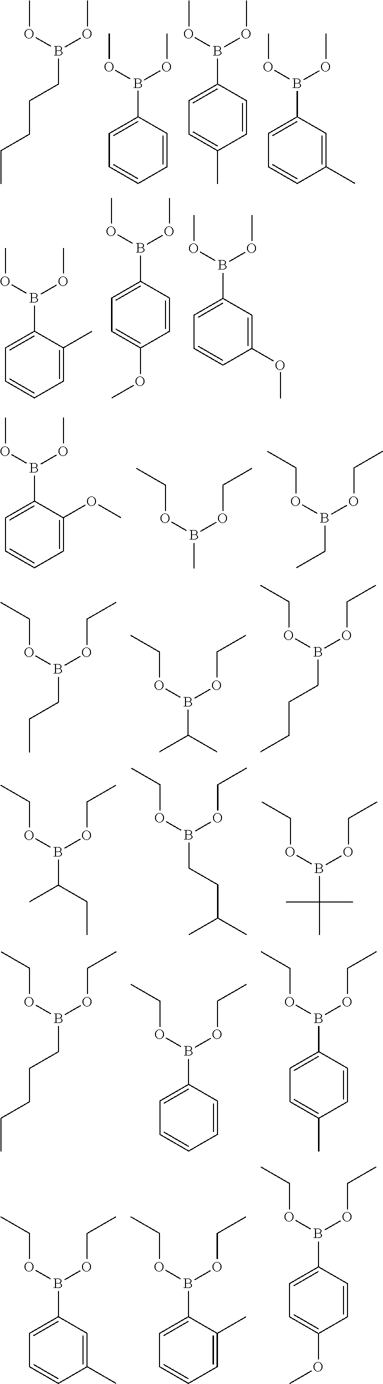

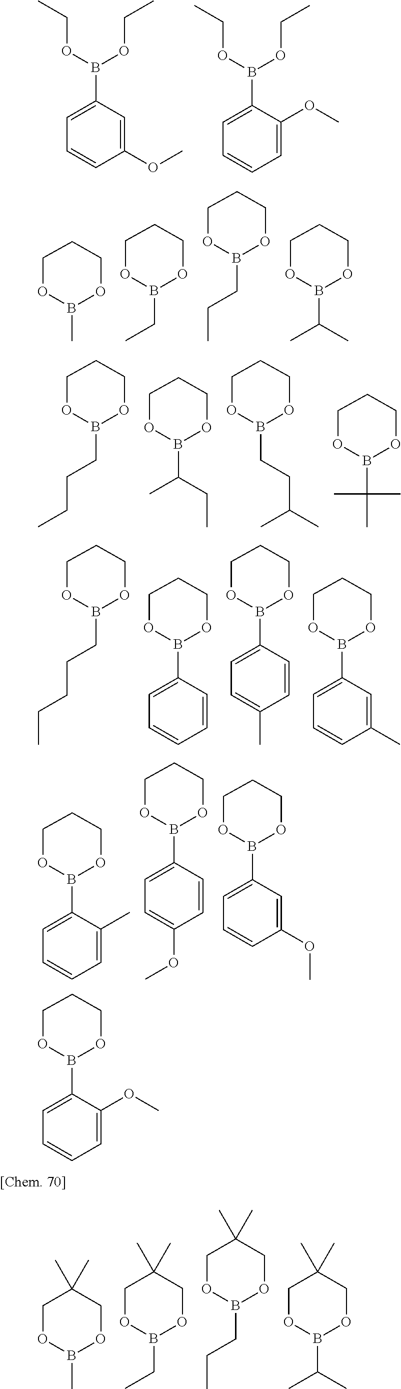

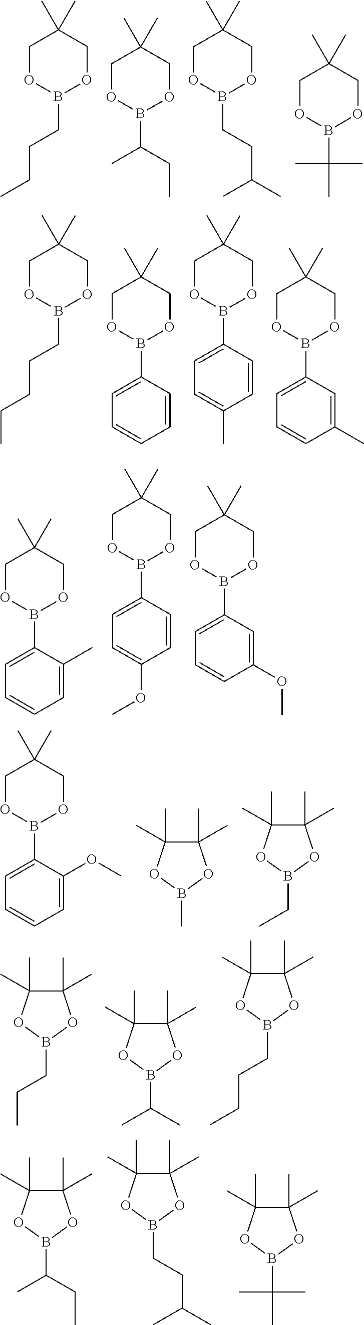

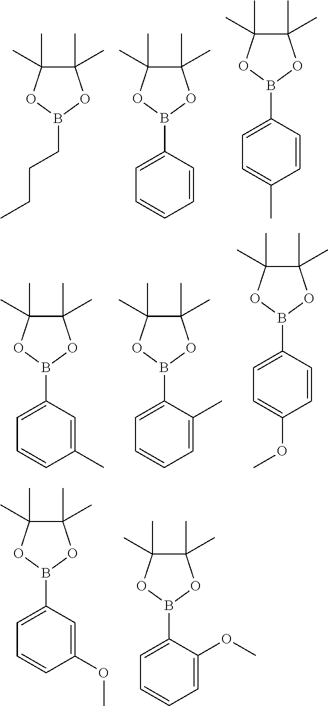

The amount of Lewis acidic compound is used so as to preferably fall within a range of 0.01 parts by mass or more and 5 parts by mass or less, more preferably fall within a range of 0.01 parts by mass or more and 3 parts by mass or less and further preferably fall within a range of 0.05 part by mass or more and 2 parts by mass or less relative to the total mass of 100 parts by mass of the resin (B) and the alkali-soluble resin (D) described above.

When the photosensitive composition is used for forming a pattern serving as a template for forming a plated article, the photosensitive composition may further contain an adhesive auxiliary agent in order to enhance the adhesiveness between a template formed with the photosensitive composition and a metal substrate.

The photosensitive composition may further contain a surfactant in order to enhance the coating property, the defoaming property, the leveling property, and the like. As the surfactant, for example, a fluorine-based surfactant or a silicone-based surfactant is preferably used. Specific examples of the fluorine-based surfactant include commercially available fluorine-based surfactants such as BM-1000 and BM-1100 (both manufactured by B.M-Chemie Co., Ltd.), Megafac F142D, Megafac F172, Megafac F173 and Megafac F183 (all manufactured by DIC Corporation), Flolade FC-135, Flolade FC-170C, Flolade FC-430 and Flolade FC-431 (all manufactured by Sumitomo 3M Ltd.), Surflon S-112, Surflon S-113, Surflon S-131, Surflon S-141 and Surflon S-145 (all manufactured by Asahi Glass Co., Ltd.), SH-28PA, SH-190, SH-193, SZ-6032 and SF-8428 (all manufactured by Toray Silicone Co., Ltd.), and the like, but the fluorine-based surfactant is not limited thereto. As the silicone-based surfactant, an unmodified silicone-based surfactant, a polyether modified silicone-based surfactant, a polyester modified silicone-based surfactant, an alkyl modified silicone-based surfactant, an aralkyl modified silicone-based surfactant, a reactive silicone-based surfactant, and the like can be preferably used. As the silicone-based surfactant, commercially available silicone-based surfactant can be used. Specific examples of the commercially available silicone-based surfactant include Paintad M (manufactured by Dow Corning Toray Co., Ltd.), Topica K1000, Topica K2000, and Topica K5000 (all manufactured by Takachiho Industry Co., Ltd.), XL-121 (polyether modified silicone-based surfactant manufactured by Clariant Co.), BYK-310 (polyester modified silicone-based surfactant made by BYK), and the like.

In order to finely adjust solubility in a developing solution, the photosensitive composition may further contain an acid, an acid anhydride or a solvent having a high boiling point.

Specific examples of the acid and the acid anhydride include: monocarboxylic acids such as acetic acid, propionic acid, n-butyric acid, isobutyric acid, n-valeric acid, isovaleric acid, benzoic acid and cinnamic acid; hydroxymonocarboxylic acids such as lactic acid, 2-hydroxybutyric acid, 3-hydroxybutyric acid, salicylic acid, m-hydroxybenzoic acid, p-hydroxybenzoic acid, 2-hydroxycinnamic acid, 3-hydroxycinnamic acid, 4-hydroxycinnamic acid, 5-hydroxyisophthalic acid and syringic acid; polyvalent carboxylic acids such as oxalic acid, succinic acid, glutaric acid, adipic acid, maleic acid, itaconic acid, hexahydrophthalic acid, phthalic acid, isophthalic acid, terephthalic acid, 1,2-cyclohexanedicarboxylic acid, 1,2,4-cyclohexanetricarboxylic acid, butanetetracarboxylic acid, trimellitic acid, pyromellitic acid, cyclopentanetetracarboxylic acid, butanetetracarboxylic acid and 1,2,5,8-naphthalenetetracarboxylic acid; acid anhydrides such as itaconic anhydride, succinic anhydride, citraconic anhydride, dodecenylsuccinic anhydride, tricarbanilic anhydride, maleic anhydride, hexahydrophthalic anhydride, methyltetrahydrophthalic anhydride, himic anhydride, 1,2,3,4-butanetetracarboxylic anhydride, cyclopentanetetracarboxylic dianhydride, phthalic anhydride, pyromellitic anhydride, trimellitic anhydride, benzophenonetetracarboxylic anhydride, ethylene glycol bis anhydrous trimellitate and glycerin tris anhydrous trimellitate; and the like.

Specific examples of the solvent having a high boiling point include N-methylformamide, N,N-dimethylformamide, N-methylformanilide, N-methylacetamide, N,N-dimethlyacetamide, N-methylpyrrolidone, dimethyl sulfoxide, benzyl ethyl ether, dihexyl ether, acetonyl acetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, phenyl cellosolve acetate, and the like.

The photosensitive composition may further contain a known sensitizer in order to enhance the sensitivity.

### <<Method of Preparing Chemically Amplified Positive-Type Photosensitive Composition>>

The chemically amplified positive-type photosensitive composition is prepared by mixing and stirring the constituent components of the composition by a common method. Examples of devices which can be used for mixing and stirring the above components include a dissolver, a homogenizer, a 3-roll mill, and the like. After uniformly mixing the above components, the resulting mixture may be filtered through a mesh, a membrane filter or the like.

### <<Photosensitive Dry Film>>

A photosensitive dry film includes a substrate film and a photosensitive layer formed on the surface of the substrate film. In the photosensitive dry film, the photosensitive layer includes the photosensitive composition described above.

As the substrate film, a film having optical transparency is preferable. Although a polyethylene terephthalate (PET) film, a polypropylene (PP) film, a polyethylene (PE) film, and the like are specifically mentioned, in terms of excellent balance between the optical transparency and the breaking strength, a polyethylene terephthalate (PET) film is preferable.

The photosensitive composition described above is applied on the substrate film to form the photosensitive layer, and thus the photosensitive dry film is manufactured. When the photosensitive layer is formed on the substrate film, the photosensitive composition is applied and dried on the substrate film using an applicator, a bar coater, a wire bar coater, a roller coater, a curtain flow coater, or the like such that the film thickness of the photosensitive composition after drying is preferably 0.5 μm or more and 300 μm or less, more preferably 1 μm or more and 300 μm or less and particularly preferably 3 μm or more and 100 μm or less.

The photosensitive dry film may further have a protective film on the photosensitive layer. Examples of the protective film include a polyethylene terephthalate (PET) film, a polypropylene (PP) film, a polyethylene (PE) film, and the like.

### <<Patterned Resist Film>>

There is no particular limitation on a method of forming a patterned resist film on a substrate using the photosensitive composition described above. Such a patterned resist film is suitably used as an insulating film, an etching mask, a template for forming a plated article, and the like. A suitable method includes a method of manufacturing a patterned resist film, including: laminating a photosensitive layer including a photosensitive composition on a substrate; exposing the photosensitive layer by irradiation with active rays or radiation in a position-selective manner; and developing the exposed photosensitive layer. A method of forming a substrate with a template for forming a plated article is the same as the method of manufacturing a patterned resist film except that the method includes laminating a photosensitive layer on a metal surface of the substrate having a metal surface, and a template for forming a plated article is produced by development in the development process.

The substrate on which the photosensitive layer is laminated is not particularly limited, and a conventionally known substrate can be used, and examples thereof include a substrate for an electronic component, the substrate on which a predetermined wiring pattern is formed and the like. As the substrate, a silicon substrate, a glass substrate, or the like can also be used. When a substrate with a template for forming a plated article is manufactured, as the substrate, a substrate having a metal surface is used. As the type of metal constituting the metal surface, copper, gold and aluminum are preferable, and copper is more preferable.

For example, the photosensitive layer is laminated on the substrate as follows. In other words, a liquid photosensitive composition is applied onto a substrate, a solvent is removed by heating and thus a photosensitive layer having a desired thickness is formed. The thickness of the photosensitive layer is not particularly limited as long as it is possible to form a resist pattern which has a desired thickness. Although the thickness of the photosensitive layer is not particularly limited, the thickness of the photosensitive layer is preferably 0.5 μm or more, more preferably 0.5 μm or more and 300 μm or less, further preferably 0.5 μm or more and 200 μm or less and particularly preferably 0.5 μm or more and 150 μm or less.

As a method of applying the photosensitive composition onto the substrate, methods such as a spin coat method, a slit coat method, a roll coat method, a screen printing method, and an applicator method can be adopted. Pre-baking is preferably performed on the photosensitive layer. Although the conditions of the pre-baking may differ depending on the types of components in the photosensitive composition, a mixing ratio, the thickness of a coating film, and the like, the conditions are generally about 2 minutes or more and 120 minutes or less at 70° C. or more and 200° C. or less and preferably 80° C. or more and 150° C. or less.

Active rays or radiation, for example, ultraviolet rays or visible light of a wavelength of 300 nm or more and 500 nm or less is selectively applied (exposed) through a mask having a predetermined pattern to the photosensitive layer formed as described above.

A low pressure mercury lamp, a high pressure mercury lamp, a super high pressure mercury lamp, a metal halide lamp, an argon gas laser, and the like can be used for the light source of the radiation. The radiation may include micro waves, infrared rays, visible light, ultraviolet rays, X-rays, γ-rays, electron beams, proton beams, neutron beams, ion beams, and the like. Although the dose of the radiation may differ depending on the composition of the photosensitive composition, the film thickness of the photosensitive layer, and the like, for example, when a super high pressure mercury lamp is used, the dose is 100 mJ/cm² or more and 10000 mJ/cm² or less. The radiation includes light rays for activating the acid generating agent (A) in order to generate an acid.

After the exposure, the diffusion of the acid is promoted by heating the photosensitive layer using a known method to change solubility in a developing solution such as an alkali developing solution for the photosensitive layer in the exposed portion of the photosensitive layer.

Then, the exposed photosensitive layer is developed according to a conventionally known method, and the unnecessary portion is dissolved and removed to form a predetermined resist pattern or a template for forming a plated article. Here, an alkaline aqueous solution is used as the developing solution.

Examples of the developing solution which can be used include an aqueous solution of an alkali such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, 1,8-diazabicyclo[5,4,0]-7-undecene and 1,5-diazabicyclo[4,3,0]-5-nonane. An aqueous solution prepared by adding an adequate amount of water-soluble organic solvent such as methanol or ethanol, or an adequate amount of surfactant to the above aqueous solution of the alkali can be used as the developing solution. Depending on the composition of the photosensitive composition, it is possible to apply development using an organic solvent.

Although the development time differs depending on the composition of the photosensitive composition, the film thickness of the photosensitive layer, and the like, the development time is 1 minute or more and 30 minutes or less. The development method may be any one of a liquid-filling method, a dipping method, a paddle method, a spray developing method, and the like.

After the development, the photosensitive layer is washed with running water for 30 seconds or more and 90 seconds or less, and is then dried with an air gun, an oven, and the like. In this way, it is possible to form a resist film which is patterned in a desired shape on the surface of a substrate. In this way, it is possible to form a substrate with a template having a resist pattern which serves as a template on the metal surface of a substrate.

The photosensitive composition described above has a high resolution and high dimensional controllability. In the photosensitive composition described above, a resist pattern which has satisfactory cross-sectional rectangularity is easily formed. Hence, it is possible to form a resist pattern which has a desired shape with a high resolution and a rectangular cross-sectional shape.

A conductor such as a metal is embedded by plating into a non-resist portion (a portion removed with the developing solution) in the template of the substrate with a template formed by the above method to form, for example, a contact terminal such as a bump and a metal post, and a plated article such as Cu rewiring. There is no particular limitation on the method for plate processing, and various conventionally known methods can be adopted. As a plating liquid, in particular, a solder plating liquid, a copper plating liquid, a gold plating liquid and a nickel plating liquid are suitably used. The remaining template is finally removed with a stripping liquid and the like in accordance with a conventional method.

When a plated article is manufactured, it may be preferable that an exposed metal surface in a non-patterned portion of a resist pattern serving as a template for forming a plated article is subjected to ashing treatment. Specific examples include a case where a pattern formed of the photosensitive composition including the sulfur-containing compound (E) is used as a template to form a plated article. In this case, adhesiveness of the plated article to a metal surface may easily be damaged. This problem is remarkable in a case where the sulfur-containing compound (E) represented by the above-mentioned formula (e1), and the sulfur-containing compound (E) represented by the formula (e4) are used. However, when the ashing treatment described above is performed, even if a pattern formed of the photosensitive composition including the sulfur-containing compound (E) is used as a template, a plated article which is satisfactorily adhered to the metal surface is easily formed. When a compound including a nitrogen-containing aromatic heterocycle substituted with a mercapto group is used as the sulfur-containing compound (E), the problem for the adhesiveness of a plated article hardly occurs or slightly occurs. Hence, when a compound including a nitrogen-containing aromatic heterocycle substituted with a mercapto group is used as the sulfur-containing compound (E), a plated article having satisfactory adhesiveness to the metal surface is easily formed without ashing treatment being performed.

The ashing treatment is not particularly limited as long as long as it does not damage a resist pattern serving as a template for forming the plated article to such an extent that the plated article having a desired shape cannot be formed. As the preferred ashing treatment method, a method using an oxygen plasma is mentioned. In order to perform ashing on the metal surface of the substrate using an oxygen plasma, it is preferable to generate an oxygen plasma using a known oxygen plasma generator to apply the oxygen plasma to the metal surface on the substrate.

Various gases which are conventionally used for plasma treatment together with oxygen can be mixed with a gas used for generating the oxygen plasma as long as the object of the present invention is not impaired. Examples of such gases include nitrogen gas, hydrogen gas, CF₄ gas, and the like. Although conditions of the ashing using the oxygen plasma are not particularly limited as long as the object of the present invention is not impaired, a treatment time is, for example, in a range of 10 seconds or more and 20 minutes or less, preferably in a range of 20 seconds or more and 18 minutes or less and more preferably in a range of 30 seconds or more and 15 minutes or less. By setting the treatment time using the oxygen plasma to the range described above, the effect of improving the adhesiveness of the plated article can be easily achieved without the shape of the resist pattern being changed.

The photosensitive composition described above is used, and thus it is possible to form a resist pattern which has a desired shape with a high resolution and a rectangular cross-sectional shape, and since the resist pattern described above can be used as a template for forming a plated article, it is possible to realize further increases in the density and precision of a protruding electrode, a metal post, and the like.

### EXAMPLES

Although the present invention will be described in more detail below using Examples, the present invention is not limited to these Examples.

### Preparation Example 1

### (Synthesis of Mercapto Compound T2)

In Preparation Example 1, a mercapto compound T2 having the following structure was synthesized as a sulfur-containing compound (E).

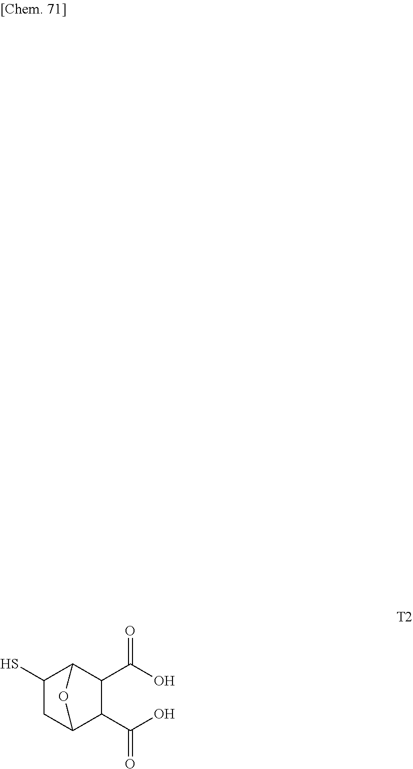 [SMILES: O=C(O)C1C2CC(S)C(O2)C1C(=O)O]

15.00 g of 7-oxanorborna-5-ene-2,3-dicarboxylic anhydride and 150.00 g of tetrahydrofuran were added into a flask, and were stirred. Then, 7.64 g of thioacetic acid (AcSH) was added into the flask, and the resulting mixture was stirred at room temperature for 3.5 hours. Thereafter, the reaction solution was concentrated to obtain 22.11 g of 5-acetyl thio-7-oxanorbornane-2,3-dicarboxylic anhydride. 22.11 g of 5-acetylthio-7-oxanorbornane-2,3-dicarboxylic anhydride and 30.11 g of an aqueous sodium hydroxide solution having a concentration of 10% by mass were added into a flask, and then contents in the flask were stirred at room temperature for 2 hours. Then, hydrochloric acid (80.00 g) having a concentration of 20% by mass was added into the flask to acidify the reaction solution. Thereafter, extraction using 200 g of ethyl acetate was performed four times to obtain an extraction liquid including a mercapto compound T2. The extraction liquid was concentrated and the collected residue was dissolved by adding 25.11 g of tetrahydrofuran (THF). Heptane was dropped on the obtained THF solution to precipitate the mercapto compound T2, and the precipitated mercapto compound T2 was collected by filtration. The measurement results of the mercapto compound T2 using ¹H-NMR are shown below.

¹H-NMR (DMSO-d6): δ12.10 (s, 2H), 4.72 (d, 1H), 4.43 (s, 1H), 3.10 (t, 1H), 3.01 (d, 1H), 2.85 (d, 1H), 2.75 (d, 1H), 2.10 (t, 1H), 1.40 (m, 1H)

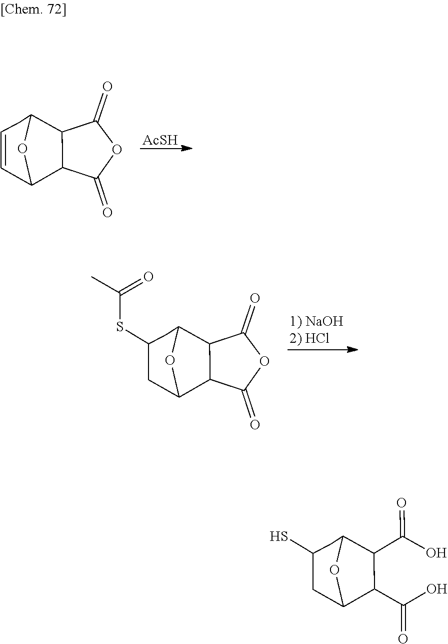

### Examples 1 to 5 and Comparative Examples 1 to 4

In Examples 1 to 5 and Comparative Examples 1 to 4, as the acid generating agent (A), PAG1 of the following formula was used.

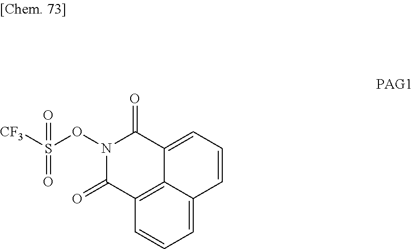 [SMILES: O=C1c2cccc3cccc(c23)C(=O)N1OS(=O)(=O)C(F)(F)F]

In Examples 1 to 5 and Comparative Examples 1 to 4, the following Resin A1 was used as the resin (resin (B)) having alkali solubility that increases under action of acid. The number at the lower right of parentheses in each constituent unit in the following structural formula represents the content (percent by mass) of the constituent unit in the resin. The Resin A1 has a mass average molecular weight Mw of 42000.

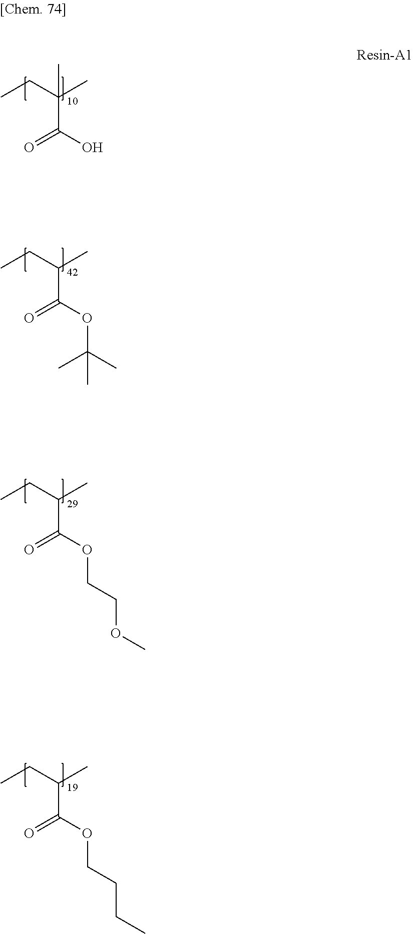

In Examples 1 to 5 and Comparative Examples 1 to 4, the following Resin B1 (polyhydroxystyrene resin) and Resin C (novolak resin (m-cresol single condensate)) were used as the alkali-soluble resin (D). The number at the lower right of parentheses in each constituent unit in the following structural formula represents the content (percent by mass) of the constituent unit in each resin. The Resin B1 has a mass average molecular weight (Mw) of 2500, and a dispersivity (Mw/Mn) of 2.4. The Resin C has a mass average molecular weight (Mw) of 8000.

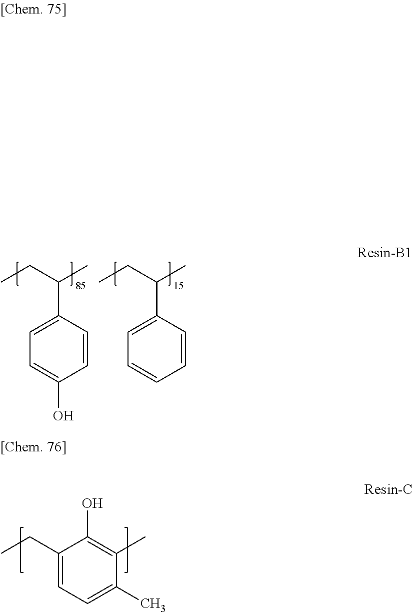

As the acid diffusion suppressing agent (C), C1 to C7 below were used. In C4, each of n1 and n2 is 1. C2 represents a reaction product of benzeneamine, N-phenyl and 2,4,4-trimethylpentene.

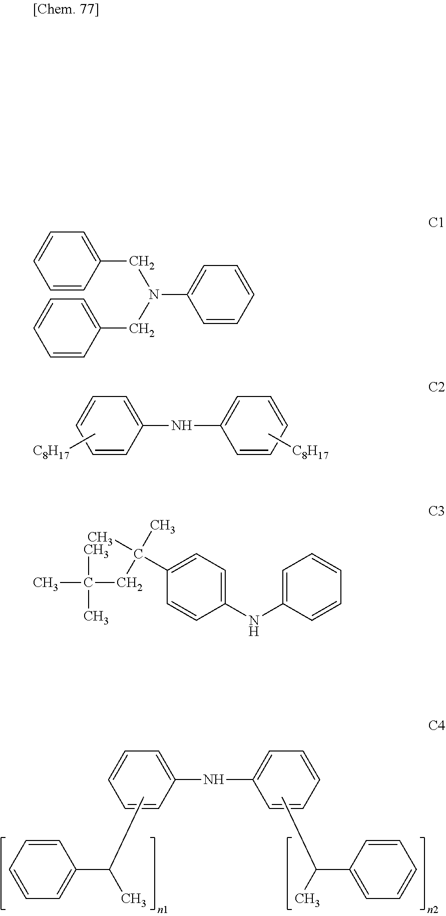

### C5: Triphenylamine

### C6: Tripentylamine

### C7: Aniline

As the sulfur-containing compound (E), the following sulfur-containing compounds T1 and T2 were used.

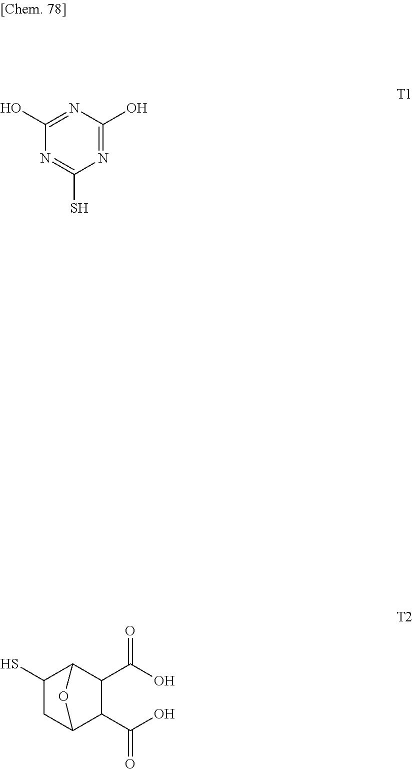 [SMILES: Oc1nc(O)nc(S)n1 ; O=C(O)C1C2CC(S)C(O2)C1C(=O)O]

Parts by mass of the types of acid generating agent (A), resin (B), acid diffusion suppressing agent (C), alkali-soluble resin (D) and sulfur-containing compound (E) shown in Table 1, and 0.05 parts by mass of a surfactant (BYK310, made by BYK) were dissolved in 3-methoxybutyl acetate (MA) such that the solid content concentration was 51% by mass, with the result that the photosensitive compositions of the Examples and the Comparative Examples were obtained. The unit in Table 1 is parts by mass, and, only for the amount of acid diffusion suppressing agent (C), the value of parts by mass with respect to 100 parts by mass of the resin (B) is shown.

The photosensitive compositions obtained were used, and thus the resolution, the dimensional controllability, the cross-sectional verticality and the cross-sectional interface shape thereof were evaluated according to the following methods. The results of the evaluations are shown in Table 1.

### [Evaluation of Resolution]

A substrate was prepared in which a copper film having a thickness of 200 nm was provided by sputtering on the surface of a Si substrate, each of the photosensitive compositions of the Examples and the Comparative Examples was applied on the copper layer of this substrate and was dried on a hot plate at 145° C. for 5 minutes and thus a photosensitive layer (coating film of the photosensitive composition) having a film thickness of 65 μm was formed. Then, a mask having a hole pattern of 10 μm and the projection exposure device of Prisma GHI5452 (made by Ultratech, Inc. NA=0.16) were used, and thus pattern exposure was performed using a ghi line with an exposure amount of 500 mJ/cm². Then, the substrate was placed on the hot plate, and heating after exposure (PEB) was performed at 100° C. for 3 minutes. Thereafter, an operation of dropping a 2.38 wt % aqueous solution of tetramethylammonium hydroxide (TMAH) (developer, NMD-3, made by TOKYO OHKA KOGYO CO., LTD.) on the exposed photosensitive layer and then leaving it to stand (paddle development) at 23° C. for 60 seconds was performed a total of five times. Thereafter, the surface of a resist pattern was washed with running water (rinsed) for 60 seconds and was then spin-dried, with the result that a resist pattern was obtained. The resist pattern (hole pattern) obtained was observed with an optical microscope and a scanning electron microscope (SEM), and thus a case where a pattern of 10 μm was formed was evaluated to be good (indicated by circle symbol (∘)) and a case where a pattern of 10 μm was not formed was evaluated to be poor (indicated by cross symbol (x)).

### [Evaluation of Dimensional Controllability]

The same operation as in [Evaluation of resolution] was performed except that, as the mask, a mask having a hole pattern of 30 μm was used, and thus a resist pattern was obtained. For the resist pattern (hole pattern) obtained, a scanning electron microscope was used to measure the diameter (hole dimension) of a surface (bottom) of the resist pattern in contact with the substrate, and a case where the hole dimension fell within 30 μm±10% was evaluated to be very good (indicated by bullseye symbol (⊙), a case where the hole dimension fell outside 30 μm±10% and fell within 30 μm±30% was evaluated to be good (indicated by circle symbol (∘)), a case where the hole dimension fell outside 30 μm±30% and fell within 30 μm±50% was evaluated to be fair (indicated by triangle symbol (Δ)) and a case where the hole dimension fell outside 30 μm±50% was evaluated to be poor (indicated by cross symbol (x)).

### [Evaluation of Cross-Sectional Verticality (Evaluation of Cross-Sectional Rectangularity)]

A cross-sectional shape of the resist pattern (hole pattern) obtained in [Evaluation of dimensional controllability] was observed with the scanning electron microscope, and thus the width Wb of the surface (bottom) of the resist pattern in contact with the substrate, the pattern width Wm of a middle part in the direction of thickness of the cross section of the resist pattern and the width Wt of the surface (top) of the resist pattern opposite to the surface in contact with the substrate were measured. The standard deviation (σ) of Wb, Wm and Wt was calculated, and a case where the value thereof was less than 1 was evaluated to be very good (indicated by bullseye symbol (⊙)), a case where the value was 1 or more and less than 2 was evaluated to be good (indicated by circle symbol (∘)), a case where the value was 2 or more and less than 3 was evaluated to be fair (indicated by triangle symbol (Δ)) and a case where the value was 3 or more was evaluated to be poor (indicated by cross symbol (x)).

### [Evaluation of Cross-Sectional Interface Shape (Evaluation of Rectangularity of Substrate Interface Shape)]

An interface between the substrate and the resist pattern obtained in obtained in [Evaluation of dimensional controllability] was observed with the scanning electron microscope, and thus a case where skirting (footing) was not observed or a case where skirting was observed but the length of the skirt was 0.5 μm or less was evaluated to be very good (indicated by bullseye symbol (⊙)), a case where the length of the skirt was 0.5 μm or more and less than 1 μm was evaluated to be good (indicated by circle symbol (∘)), a case where the length of the skirt was 1 μm or more and less than 2 μm was evaluated to be fair (indicated by triangle symbol (Δ)), a case where the length of the skirt was 2 μm or more was evaluated to be poor (indicated by cross symbol (x)) and a case where a biting shape was formed was evaluated to be very poor (indicated by two cross symbols (xx)).

TABLE 1

| | | | Acid diffusion | | | | | |
|---|---|---|---|---|---|---|---|---|
| | | | suppressing | | | | | |
| | | | agent (C) | | | | | |
| | | | Type/parts | Sulfur- | | | | |
| | Acid | Resin (B) and | by mass | containing | Evaluations | | | |
| | generating | alkali soluble | relative to | compound | | | | Cross- |
| | agent (A) | resin (D) | 100 parts by | (E) | | | Cross- | sectional |
| | Type/parts | Type/parts | mass of | Type/parts | | Dimensional | sectional | interface |
| | by mass | by mass | resin (B) | by mass | Resolution | controllability | verticality | shape |
| Example 1 | PAG1/1.0 | A1/35 | C1/0.11 | T1/0.03 | ◯ | ⊙ | ◯ | ◯ |
| Example 2 | | B1/10 | C2/0.15 | T2/0.03 | ◯ | Δ | ◯ | ⊙ |
| Example 3 | | C/55 | C2/0.23 | | ◯ | ◯ | ⊙ | ⊙ |
| Example 4 | | | C3/0.11 | | ◯ | Δ | Δ | ⊙ |
| Example 5 | | | C4/0.15 | | ◯ | Δ | Δ | ⊙ |
| Comparative | | | None | | X | X | X | XX |
| Example 1 | | | | | | | | |
| Comparative | | | C5/0.10 | | X | X | X | X |
| Example 2 | | | | | | | | |
| Comparative | | | C6/0.09 | | X | X | X | XX |
| Example 3 | | | | | | | | |
| Comparative | | | C7/0.04 | | X | X | X | XX |
| Example 4 | | | | | | | | |

It is found from Examples 1 to 5 that the photosensitive compositions obtained by mixing the compound serving as the acid diffusion suppressing agent (C) and represented by the formula (C1) with the chemically amplified positive-type photosensitive composition including the acid generating agent (A) to generate an acid by irradiation with an active ray or radiation and the resin (B) having alkali solubility that increases under action of acid, can form a resist pattern having satisfactory cross-sectional verticality, a satisfactory cross-sectional interface shape and satisfactory rectangularity and have a high resolution and high dimensional controllability.

On the other hand, it is found from Comparative Examples 1 to 4 that when the acid diffusion suppressing agents of C5 to C7 which do not correspond to the compound represented by the formula (C1) are contained instead of the compound represented by the formula (C1), the resolution, the dimensional controllability, the cross-sectional verticality and the cross-sectional interface shape are poor.

1. A chemically amplified positive-type photosensitive composition comprising: an acid generating agent (A) to generate an acid by irradiation with an active ray or radiation; a resin (B) having alkali solubility that increases under action of acid; and an acid diffusion suppressing agent (C),
wherein the acid diffusion suppressing agent (C) comprises a compound represented by a formula (C1) below: 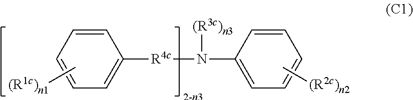
wherein R^{1c} is an alkyl group or an aralkyl group,
R^{2c} is an alkyl group or an aralkyl group,
R^{3c} is a hydrogen atom or an alkyl group,
R^{4c} is a single bond or an alkylene group,
n1 is an integer of 0 or more and 5 or less,
n2 is an integer of 0 or more and 5 or less,
n3 is 0 or 1 and
when n3 is 1, n1 and n2 cannot simultaneously be 0.

2. The chemically amplified positive-type photosensitive composition according to claim 1, wherein the n3 is 1, and the R^{4c} is a single bond.

3. The chemically amplified positive-type photosensitive composition according to claim 2, wherein the alkyl group or the aralkyl group serving as the R^{1c} has 6 or more and 10 or less carbon atoms, and the alkyl group or the aralkyl group serving as the R^{2c} has 6 or more and 10 or less carbon atoms.

4. The chemically amplified positive-type photosensitive composition according to claim 1, wherein the n3 is 0, and the R^{4c} is an alkylene group.

5. The chemically amplified positive-type photosensitive composition according to claim 1, wherein a content of the acid diffusion suppressing agent (C) is 0.01 parts by mass or more and 20 parts by mass or less relative to 100 parts by mass of the resin (B).

6. The chemically amplified positive-type photosensitive composition according to claim 1, further comprising an alkali soluble resin (D).

7. The chemically amplified positive-type photosensitive composition according to claim 6, wherein the alkali soluble resin (D) comprises at least one type of resin selected from the group consisting of a novolak resin (D1), a polyhydroxystyrene resin (D2) and an acrylic resin (D3).

8. A photosensitive dry film comprising: a base material film; and a photosensitive layer formed on a surface of the substrate film, wherein the photosensitive layer comprises the chemically amplified positive-type photosensitive composition according to claim 1.

9. A method of manufacturing a photosensitive dry film, the method comprising: applying, on a base material film, the chemically amplified positive-type photosensitive composition according to claim 1 to form a photosensitive layer.

10. A method of manufacturing a patterned resist film, the method comprising:
laminating a photosensitive layer on a substrate, the photosensitive layer including the chemically amplified positive-type photosensitive composition according to claim 1;
exposing the photosensitive layer through irradiation with an active ray or radiation in a position-selective manner; and
developing the exposed photosensitive layer.

11. An acid diffusion suppressing agent to be mixed with a chemically amplified positive-type photosensitive composition comprising an acid generating agent (A) to generate an acid by irradiation with an active ray or radiation and a resin (B) having alkali solubility that increases under action of acid, wherein the acid diffusion suppressing agent comprises a compound represented by the formula (C1) below: 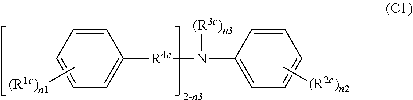
wherein R^{1c} is an alkyl group or an aralkyl group,
R^{2c} is an alkyl group or an aralkyl group,
R^{3c} is a hydrogen atom or an alkyl group,
R^{4c} is a single bond or an alkylene group,
n1 is an integer of 0 or more and 5 or less,
n2 is an integer of 0 or more and 5 or less,
n3 is 0 or 1 and
when n3 is 1, n1 and n2 cannot simultaneously be 0.
